(19) United States
(12) Patent Application Publication
(10) Pub. No.: US 2025/0143163 A1
(43) Pub. Date: May 1, 2025

(54) ORGANIC LIGHT EMITTING DIODE COMPRISING ORGANOMETALLIC COMPOUND AND VARIOUS TYPES OF HOST MATERIALS

(71) Applicant: LG Display Co., Ltd., Seoul (KR)

(72) Inventors: Hansol Park, Goyang-si (KR); Taeryang Hong, Seoul (KR); Kusun Choung, Seoul (KR)

(73) Assignee: LG Display Co., Ltd., Seoul (KR)

(21) Appl. No.: 18/811,168

(22) Filed: Aug. 21, 2024

(30) Foreign Application Priority Data
Oct. 25, 2023 (KR) 10-2023-0144050

(51) Int. Cl. H10K 85/30; C09K 11/02; C09K 11/06; H10K 50/12; H10K 85/60

(52) U.S. Cl. CPC H10K 85/342; C09K 11/02; C09K 11/06; H10K 50/12; H10K 85/622; H10K 85/654; H10K 85/6572; H10K 85/6574; H10K 85/6576

(57) ABSTRACT

An organic light emitting diode includes a first electrode, a second electrode facing the first electrode, and an intermediate layer disposed between the first electrode and the second electrode. The intermediate layer includes an emission layer including: a dopant material including an organometallic compound represented by Chemical Formula 1, and a host material including a mixture including a compound represented by Chemical Formula 2 and a compound represented by Chemical Formula 3.

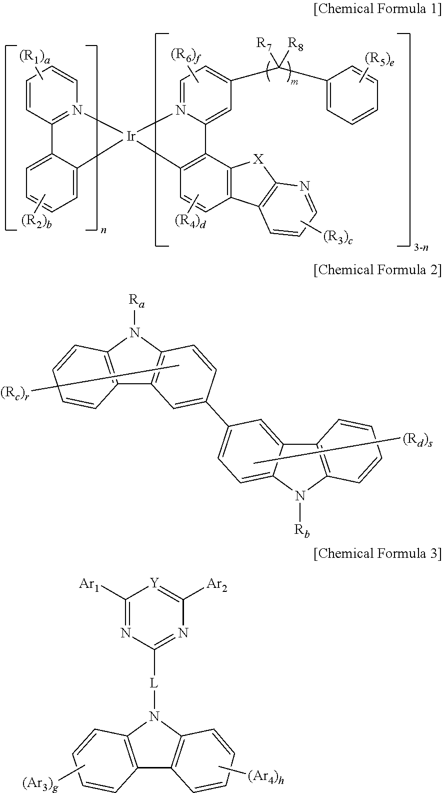

### CROSS REFERENCE TO RELATED APPLICATION

The present application claims the benefit of and the priority to Korean Patent Application No. 10-2023-0144050 filed on Oct. 25, 2023 in the Korean Intellectual Property Office, the disclosure of which is hereby incorporated by reference in its entirety.

### BACKGROUND

### 1. Technical Field

The present disclosure relates to an organic light emitting diode including an organometallic compound and various types of host materials.

### 2. Description of the Related Art

Interest in display devices is increasing due to wide-ranging applications in various fields. As one of the display devices, the technology of organic light emitting display devices including an organic light emitting diode (OLED) is developing rapidly.

The OLED is an element for emitting energies of excitons as light after forming electrons and holes in pair to form excitons when charges are injected into an emission layer formed between an anode and a cathode. Compared to display technologies in related art, the OLED may implement a low voltage, consume relatively less power, have desirable colors, may be applied to a flexible substrate to be used variously, and may allow a display device to be freely adjusted in size.

The OLED may have a wide viewing angle and a high contrast ratio compared to liquid crystal display (LCD) devices and may not require a backlight, making it lightweight and ultra-thin. The OLED is formed by arranging a plurality of intermediate layers, such as a hole injection layer, a hole transport layer, a hole transport auxiliary layer, an electron blocking layer, an electron transport layer, an electron injection layer, and the like between the cathode (electron injection electrode) and the anode (hole injection electrode).

In the structure of the OLED, when a voltage is applied between two electrodes, electrons and holes are injected from the cathode and the anode, respectively, and excitons generated from the emission layer fall to a ground state to emit light.

Organic materials used in the OLED may be largely classified into a light emitting material and a charge transport material. The light emitting material may be an important factor in determining the luminous efficiency of the OLED, and the light emitting material may have high quantum efficiency, excellent mobility of electrons and holes, and be uniformly and stably present in the emission layer. The light emitting material is classified into light emitting materials, such as blue, red, and green, depending on colored light and is used as hosts and dopants to increase color purity and increase luminous efficiency through energy transfer as color materials.

In the case of fluorescent materials, while only a singlet of about 25% of the excitons formed in the emission layer is used to generate light, and a triplet of 75% is mostly lost as heat, phosphorescent materials has a luminous mechanism that converts both the singlet and the triplet into light.

So far, organic metal compounds have been used as phosphorescent materials used in the OLED. There may still be a technical need to improve the performance of the OLED by deriving high-efficiency phosphorescent dopant materials and applying hosts with optimal photophysical characteristics to improve the efficiency and lifetime of the element compared to OLEDs in related art.

### SUMMARY

Therefore, the present disclosure is directed to providing an organic light emitting diode in which an organometallic compound and various types of host materials, which are capable of increasing a driving voltage, efficiency, and a lifetime, are applied to an organic emission layer.

The objects of the present disclosure are not limited to the above-described object, and other objects and advantages of the present disclosure which are not mentioned may be understood by the following description and more clearly understood by embodiments of the present disclosure. In addition, it may be easily seen that the objects and advantages of the present disclosure may be achieved by means and combinations thereof which are described in the claims.

To achieve these and other advantages and in accordance with objects of the disclosure, as embodied and broadly described herein, an organic light emitting diode includes a first electrode, a second electrode facing the first electrode, and an intermediate layer disposed between the first electrode and the second electrode, the intermediate layer including an emission layer including a dopant material including an organometallic compound represented by Chemical Formula 1, and a host material including a mixture including a compound represented by Chemical Formula 2 and a compound represented by Chemical Formula 3:

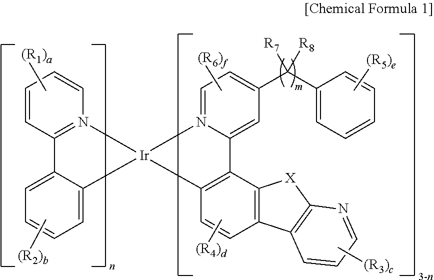

wherein in Chemical Formula 1,
X is one selected from oxygen (O), sulfur(S), and selenium (Se),
each R₁ to R₆ is independently one selected from deuterium, halogen, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a a carboxylic acid group, a nitrile group, an isonitrile group, a sulfanyl group, and a phosphino group, and combinations thereof, where the alkyl group, the cycloalkyl group, the heteroalkyl group, the arylalkyl group, the alkoxy group, the aryloxy group, the amino group, the silyl group, the alkenyl group, the cycloalkenyl group, the heteroalkenyl group, the alkynyl group, the aryl group, the heteroaryl group, the acyl group, and the phosphino group are optionally partially deuterated or optionally entirely deuterated, each R₇ and R₈ is independently one selected from hydrogen, deuterium, a C₁-C₆ linear
alkyl group, a C₃-C₆ branched alkyl group, and a C₃-C₆ cycloalkyl group, where the C₁-C₆ linear alkyl group, the C₃-C₆ branched alkyl group, and the C₃-C₆ cycloalkyl group are optionally partially deuterated or optionally entirely deuterated,
a and b are, each independently, an integer from 0 to 4, and when a and b are each independently an integer from 2 to 4, a plurality of R₁ or a plurality of R₂ are the same or different from each other,
c and f are, each independently, an integer from 0 to 3, and when c and f are each independently an integer of 2 or 3, a plurality of R₃ or a plurality of R₆ are the same or different from each other,
d is an integer from 0 to 2, and when d is an integer of 2, a plurality of R₄ are the same or different from each other,
e is an integer from 0 to 5, and when e is an integer from 2 to 5, a plurality of R₅ are the same or different from each other, and
m is an integer selected from 1 to 8, and n is an integer selected from 0 to 2,

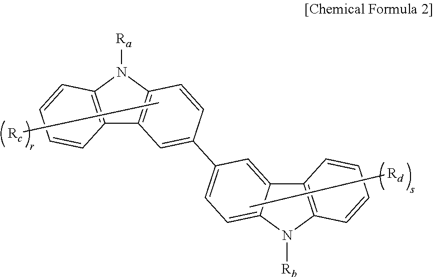

in Chemical Formula 2,
Rₐ and R_{b} are each independently one selected from an aryl group and a heteroaryl group, where the aryl group and the heteroaryl group are optionally substituted with one or more substituents selected from an alkyl group, an aryl group, a nitrile group, an alkylsilyl group, and an arylsilyl group, and Rₐ and R_{b} are optionally partially deuterated or optionally entirely deuterated,
each R_{c} and Rₐ is independently one selected from hydrogen, deuterium, halogen, nitrile group, and alkyl group, and R_{c} and Rₐ are optionally partially deuterated or optionally entirely deuterated, and
r and s each independently denotes an integer selected from 0 to 7, and when r is an integer selected from 2 to 7, each R_{c} is the same as or different from each other, and when s is an integer selected from 2 to 7, each Rₐ is the same as or different from each other,

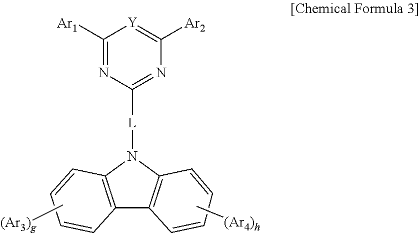

in Chemical Formula 3,
L is one selected from a single bond, a C6-C50 arylene group, and a C5-C50 heteroarylene group,
Y is N or CH,
each Ar₁, Ar₂, Ar₃, and Ar₄ is independently one selected from hydrogen, deuterium, halogen, a C1-C30 alkyl group, a C6-C50 aryl group, a C3-C50 heteroaryl group, and a C3-C30 cycloalkyl group,
g and h are each independently an integer selected from 1 to 4,
when g is an integer selected from 2 to 4, any two adjacent Ar₃ are optionally bonded to form a fused ring structure including a C6-C30 monocyclic or polycyclic aromatic group, or a C3-C30 heteroaromatic group, and one or more of hydrogens attached to the fused ring structure are optionally substituted by a substituent selected from deuterium, a C1-C10 alkyl group, a C6-C20 aryl group, and a C3-C20 heteroaryl group, and
when h is an integer selected from 2 to 4, any two adjacent Ar₄ are optionally bonded to form a fused ring structure including a C6-C30 monocyclic or polycyclic aromatic group, or a C3-C30 heteroaromatic group, and one or more of hydrogens attached to the fused ring structure are optionally substituted by a substituent selected from deuterium, a C1-C10 alkyl group, a C6-C20 aryl group, and a C3-C20 heteroaryl group.

In some example embodiments of the present disclosure, n in Chemical Formula 1 is 2.

In some example embodiments of the present disclosure, X in Chemical Formula 1 is oxygen (O).

In some example embodiments of the present disclosure, m is an integer of 1 to 3.

In some example embodiments of the present disclosure, the organometallic compound represented by Chemical Formula 1 includes one of Compounds GD1 to GD20.

In some example embodiments of the present disclosure, Rₐ and R_{b} in Chemical Formula 2 are each independently one selected from a phenyl group, a biphenyl group, a terphenyl group, a naphthyl group, an anthracene group, a chrysene group, a pyrene group, a phenanthrene group, a triphenylene group, a fluorene group, a 9,9′-dimethylfluorene group, a 9,9′-diphenylfluorene group, and a 9,9′-spirofluorene group.

In some example embodiments of the present disclosure, the compound represented by Chemical Formula 2 includes one of Compounds GHH1 to GHH30.

In some example embodiments of the present disclosure, Y in Chemical Formula 3 is N.

In some example embodiments of the present disclosure, Ar₁ and Ar₂ in Chemical Formula 3 are each independently one selected from a C6-C50 aryl group and a C3-C50 heteroaryl group.

In some example embodiments of the present disclosure, Ar₁ and Ar₂ in Chemical Formula 3 are each independently one selected from a phenyl group, a biphenyl group, a naphthyl group, a dibenzofuran group, a carbazole group, an indole group, a dibenzothiophene group, a chrysene group, a benzochrysene group, a phenanthrene group, a benzophenanthrene group, a benzonaphthothiophene group, and a benzonaphthofuran group.

In some example embodiments of the present disclosure, the compound represented by Chemical Formula 3 includes one of Compounds GEH1 to GEH30.

In some example embodiments of the present disclosure, the intermediate layer further includes any one or more selected from a hole injection layer, a hole transport layer, an electron transport layer, and an electron injection layer.

In another aspect of the present disclosure, an organic light emitting diode includes a first electrode, a second electrode facing the first electrode, and one or more light emitting parts positioned between the first electrode and the second electrode, at least one of one or more the light emitting parts including a green phosphorescent light emission layer, the green phosphorescent light emission layer including a dopant material including an organometallic compound represented by Chemical Formula 1, and a host material including a compound represented by Chemical Formula 2 and a compound represented by Chemical Formula 3, and the definition of Chemical Formulas 1 to 3 are the same as those defined in one aspect of the present disclosure.

In some example embodiments of the present disclosure, the organometallic compound represented by Chemical Formula 1 includes one of Compounds GD1 to GD20.

In some example embodiments of the present disclosure, the compound represented by Chemical Formula 2 includes one of Compounds GHH1 to GHH30.

In some example embodiments of the present disclosure, the compound represented by Chemical Formula 3 includes one of Compounds GEH1 to GEH30.

In some example embodiments of the present disclosure, the organic light emitting diode further includes a charge generation layer, wherein a plurality of light emitting parts are present between the first electrode and the second electrode, wherein the charge generation layer is disposed between the plurality of light emitting parts.

In another aspect of the present disclosure, an organic light emitting diode display device includes a substrate; a driving element positioned on the substrate; and the organic light emitting diode according to an aspect of the present disclosure positioned on the substrate and connected to the driving element.

In yet another aspect of the present disclosure, an organic light emitting diode includes a first electrode, a second electrode facing the first electrode, and an intermediate layer disposed between the first electrode and the second electrode, the intermediate layer including an emission layer including a dopant material including an organometallic compound represented by Chemical Formula 1, and a host material including a mixture including a compound represented by Chemical Formula 2 and a compound represented by Chemical Formula 3:

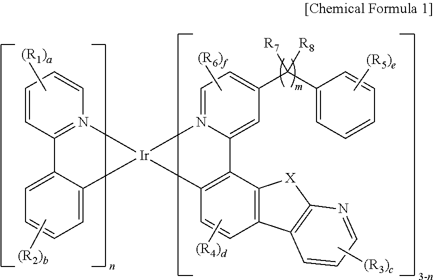

wherein in Chemical Formula 1,
X may be oxygen (O),
each R₁ to R₆ is independently one selected from alkyl and aryl, where alkyl and aryl are optionally partially deuterated or optionally entirely deuterated,
each R₇ and R₈ is independently one selected from hydrogen, deuterium, and a C₁-C₆ linear alkyl group, where the C₁-C₆ linear alkyl group is optionally partially deuterated or optionally entirely deuterated,
a and b are, each independently, an integer from 0 to 4, and when a and b are each independently an integer from 2 to 4, a plurality of R₁ or a plurality of R₂ are the same or different from each other,
c and f are, each independently, an integer from 0 to 3, and when c and f are each independently an integer of 2 or 3, a plurality of R₃ or a plurality of R₆ are the same or different from each other,
d is an integer from 0 to 2, and when d is an integer of 2, a plurality of R₄ are the same or different from each other,
e is an integer from 0 to 5, and when e is an integer from 2 to 5, a plurality of R₅ are the same or different from each other, and
m is an integer selected from 1 to 8, and n is an integer selected from 0 to 2,

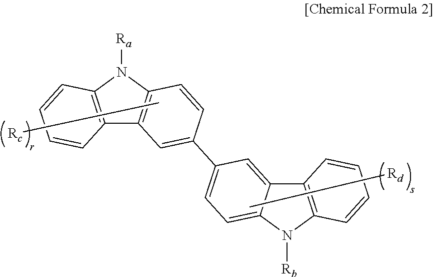

in Chemical Formula 2,
Rₐ and R_{b} are each independently one selected from an aryl group that is optionally substituted with one or more substituents selected from an alkyl group, an aryl group, a nitrile group, an alkylsilyl group, and an arylsilyl group, and Rₐ and R_{b} are optionally partially deuterated or optionally entirely deuterated,
each R_{c} and Rₐ is hydrogen or deuterium, and
r and s are each an integer of 7,

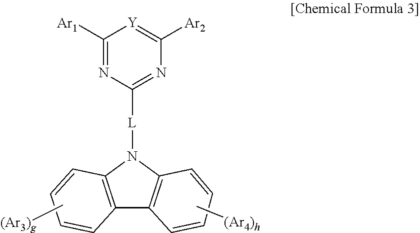

in Chemical Formula 3,
L is one selected from a single bond, a C6-C50 arylene group, and a C5-C50 heteroarylene group,
Y is N or CH,
each Ar₁, Ar₂, Ar₃, and Ar₄ is independently one selected from hydrogen, deuterium, halogen, a C1-C30 alkyl group, a C6-C50 aryl group, a C3-C50 heteroaryl group, and a C3-C30 cycloalkyl group,
g and h are each independently an integer selected from 1 to 4,
when g is an integer selected from 2 to 4, any two adjacent Ar₃ are optionally bonded to form a fused ring structure including a C6-C30 monocyclic or polycyclic aromatic group, or a C3-C30 heteroaromatic group, and one or more of hydrogens attached to the fused ring structure are optionally substituted by a substituent selected from deuterium, a C1-C10 alkyl group, a C6-C20 aryl group, and a C3-C20 heteroaryl group, and
when h is an integer selected from 2 to 4, any two adjacent Ar₄ are optionally bonded to form a fused ring structure including a C6-C30 monocyclic or polycyclic aromatic group, or a C3-C30 heteroaromatic group, and one or more of hydrogens attached to the fused ring structure are optionally substituted by a substituent selected from deuterium, a C1-C10 alkyl group, a C6-C20 aryl group, and a C3-C20 heteroaryl group.

In some example embodiments of the present disclosure, the organometallic compound represented by Chemical Formula 1 includes one of Compounds GD1 to GD5, the compound represented by Chemical Formula 2 includes one of Compounds GHH1 to GHH10, and the compound represented by Chemical Formula 3 includes one of Compounds GEH1 to GEH10.

It is to be understood that both the foregoing general description and the following detailed description of the present disclosure are merely by way of example and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure.

FIG. 1 is a cross-sectional view schematically showing an organic light emitting diode according to one example embodiment of the present disclosure.

FIG. 2 is a cross-sectional view schematically showing the organic light emitting diode with a tandem structure having two light emitting parts according to one example embodiment of the present disclosure.

FIG. 3 is a cross-sectional view schematically showing the organic light emitting diode with a tandem structure having three light emitting parts according to one example embodiment of the present disclosure.

FIG. 4 is a cross-sectional view schematically showing an organic light emitting diode display device to which the organic light emitting diode according to an example embodiment of the present disclosure is applied.

### DETAILED DESCRIPTION

Reference will now be made in detail to some of the examples and embodiments of the disclosure illustrated in the accompanying drawings. Wherever possible, the same reference numbers will be used throughout the drawings to refer to the same or like parts.

Advantages and features of the present disclosure, and a method of achieving the advantages and features will become apparent with reference to the example embodiments described herein in detail together with the accompanying drawings. The present disclosure should not be construed as limited to the example embodiments as disclosed below, and may be embodied in various different forms. Thus, these example embodiments are set forth to make the present disclosure sufficiently complete, and to assist those skilled in the art to fully understand the scope of the present disclosure. The protected scope of the present disclosure is defined by claims and their equivalents.

For convenience of description, a scale in which each of elements is illustrated in the accompanying drawings may differ from an actual scale. Thus, the illustrated elements are not limited to the specific scale in which they are illustrated in the drawings. The same reference numbers in different drawings represent the same or similar elements, which may perform similar functionality.

The shapes, sizes, ratios, angles, numbers, and the like, which are illustrated in the drawings to describe various example embodiments of the present disclosure, are merely given by way of example. Therefore, the present disclosure is not limited to the illustrations in the drawings. The same or similar elements are designated by the same reference numerals throughout the specification unless otherwise specified. Further, where the detailed description of the relevant known steps and elements may obscure an important point of the present disclosure, a detailed description of such known steps and elements may be omitted. Furthermore, in the following detailed description of the present disclosure, numerous specific details are set forth to provide a sufficiently thorough understanding of the present disclosure. However, it will be understood that the present disclosure may be practiced without these specific details. In other instances, known methods, procedures, components, and circuits have not been described in detail so as not to unnecessarily obscure aspects of the present disclosure.

Although example embodiments of the present disclosure are described in detail with reference to the accompanying drawings, the present disclosure is not limited thereto.

Therefore, example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In the present specification, where the terms “comprise”, “have”, “include”, and the like are used, one or more other elements may be added unless the term, such as “only” is used. As used herein, the term “and/or” includes a single associated listed item and any and all of the combinations of two or more of the associated listed items. An expression such as “at least one of” when preceding a list of elements may modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

In construing an element or numerical value, the element or the numerical value is to be construed as including an error or tolerance range even where no explicit description of such an error or tolerance range is provided.

It will be understood that when a first element or layer is referred to as being present “on” a second element or layer, the first element may be disposed directly on the second element or may be disposed indirectly on the second element with a third element or layer being disposed between the first and second elements or layers. It will be understood that when an element or layer is referred to as being “connected to”, or “coupled to” another element or layer, it may be directly connected to or coupled to the other element or layer, or one or more intervening elements or layers may be present. In addition, it will also be understood that when an element or layer is referred to as being “between” two elements or layers, it may be the only element or layer between the two elements or layers, or one or more intervening elements or layers may also be present. In the description of the various embodiments of the present disclosure, where positional relationships are described, for example, where the positional relationship between two parts is described using “on”, “over”, “under”, “above”, “below”, “beside”, “next”, or the like, one or more other parts may be located between the two parts unless a more limiting term, such as “immediate(ly)”, “direct(ly)”, or “close(ly)” is used.

Further, as used herein, when a layer, film, region, plate, or the like may be disposed “on” or “on a top” of another layer, film, region, plate, or the like, the former may directly contact the latter or another layer, film, region, plate, or the like may be disposed between the former and the latter. As used herein, when a layer, film, region, plate, or the like is directly disposed “on” or “on a top” of another layer, film, region, plate, or the like, the former directly contacts the latter and another layer, film, region, plate, or the like is not disposed between the former and the latter. Further, as used herein, when a layer, film, region, plate, or the like may be disposed “below” or “under” another layer, film, region, plate, or the like, the former may directly contact the latter or another layer, film, region, plate, or the like may be disposed between the former and the latter. As used herein, when a layer, film, region, plate, or the like is directly disposed “below” or “under” another layer, film, region, plate, or the like, the former directly contacts the latter and another layer, film, region, plate, or the like is not disposed between the former and the latter.

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

The features of the various embodiments of the present disclosure may be partially or overall combined with each other, and may be variously inter-operated with each other and driven technically as those skilled in the art can sufficiently understand. The embodiments may be implemented independently of each other and may be implemented together in a co-dependent relationship.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, “embodiments,” “examples,” “aspects,” and the like should not be construed such that any aspect or design as described is superior to or advantageous over other aspects or designs.

Further, the term “or” means “inclusive or” rather than “exclusive or”. That is, unless otherwise stated or clear from the context, the expression that “x uses a or b” means any one of natural inclusive permutations.

The terms used in the description below may be general and universal in the relevant art. However, there may be other terms depending on the development and/or change of technology, convention, preference of technicians, etc. Therefore, the terms used in the description below should not be understood as limiting the disclosure, and should be understood as examples of the terms for describing embodiments.

Further, in some example embodiments, a term may be arbitrarily selected by the applicant, and in this case, the detailed meaning thereof will be described in a corresponding description section. Therefore, such terms used in the description below may be understood based on the name of the terms, and the meaning of the terms and the contents throughout the detailed description.

The term “halo” or “halogen” used herein includes fluorine, chlorine, bromine, and iodine.

The term “alkyl group” used herein indicates both linear alkyl radicals and branched alkyl radicals. Unless otherwise stated, the linear alkyl group contains 1 to 20 carbon atoms, the branched alkyl group contains 3 to 20 carbon atoms, and may include methyl, ethyl, propyl, isopropyl, butyl, isobutyl, tert-butyl, and the like, and, the alkyl group may be optionally substituted.

The term “cycloalkyl group” used herein indicates cyclic alkyl radicals. Unless otherwise stated, the cycloalkyl group contains 3 to 20 carbon atoms, and may include cyclopropyl, cyclopentyl, cyclohexyl, and the like, and, the cycloalkyl group may be optionally substituted.

The term “alkenyl group” used herein indicates both linear alkenyl radicals and branched alkenyl radicals. Unless otherwise stated, the alkenyl group contains 2 to 20 carbon atoms, and, the alkenyl group may be optionally substituted.

The term “cycloalkenyl group” used herein indicates cyclic alkenyl radicals. Unless otherwise stated, the cycloalkenyl group contains 3 to 20 carbon atoms, and, the cycloalkenyl group may be optionally substituted.

The term “alkynyl group” used herein indicates both linear alkynyl radicals and branched alkynyl radicals. Unless otherwise stated, the alkynyl group contains 2 to 20 carbon atoms. Additionally, the alkynyl group may be optionally substituted.

The term “cycloalkynyl group” used herein indicates cyclic alkynyl radicals. Unless otherwise stated, the cycloalkynyl group contains 3 to 20 carbon atoms or 8 to 20 carbons, and, the cycloalkynyl group may be optionally substituted.

The terms “aralkyl group” and “arylalkyl group” used herein are used interchangeably and indicate an alkyl group having an aromatic group as a substituent, and unless otherwise stated, the aralkyl group contains 7 to 60 carbon atoms, and, the aralkyl group (arylalkyl group) may be optionally substituted.

The terms “aryl group” and “aromatic group” used herein may include conjugated structures and may include a single ring group and a polycyclic ring group. The polycyclic ring may include a “condensed ring,” which are two or more rings where two carbons are shared by two adjacent rings. Unless otherwise stated, the aryl group contains 6 to 60 carbon atoms, and, the aryl group may be optionally substituted.

The term “heterocyclic ring group” used herein indicates that one or more of the carbon atoms constituting an aryl group, a cycloalkyl group, a cycloalkenyl group, a cycloalkynyl group, an aralkyl group (arylalkyl group), an arylamino group, and the like are substituted by a heteroatom, such as oxygen (O), nitrogen (N), sulfur(S), etc., and with reference to the above definition, includes a heteroaryl group, a heterocycloalkyl group, a heterocycloalkenyl group, a heterocycloalkynyl group, a heteroarylalkyl group (heteroaralkyl group), a heteroarylamino group, and the like, and unless otherwise stated, the heterocyclic ring group contains 2 to 60 carbon atoms, 3 to 60 carbon atoms, or 7 to 60 carbon atoms and, the heterocyclic ring group may be optionally substituted.

Unless otherwise stated, the term “carbocyclic ring” used herein may be used as the term including all of “cycloalkyl group,” “cycloalkenyl group,” and “cycloalkynyl group,” which are alicyclic ring groups, and “aryl group” (aromatic group), which is an aromatic ring group.

The terms “heteroalkyl group,” “heteroalkenyl group,” “heteroalkynyl group,” and “heteroaralkyl group (heteroarylalkyl group)” used herein indicate that one or more of the carbon atoms constituting the corresponding “alkyl group,” “alkenyl group,” “alkynyl group,” and “aralkyl group (arylalkyl group)” are substituted by heteroatoms, such as oxygen (O), nitrogen (N), and sulfur(S), and, the heteroalkyl group, the heteroalkenyl group, the heteroalkynyl group, and heteroaralkyl group (heteroarylalkyl group) may be optionally substituted.

The terms “alkylamino group,” “aralkyl amino group,” “arylamino group,” and “heteroarylamino group” used herein indicate that the alkyl group, the aralkyl group, the aryl group, and the heteroaryl group that is a hetero ring are substituted with the amine group and include all of primary, secondary, and tertiary amines, and, the alkylamino group, the aralkylamino group, the arylamino group, and the heteroarylamino group may be optionally substituted.

The terms “alkylsilyl group,” “alkoxy group,” or “alkylthio group,” indicate that the alkyl group is substituted with the silyl group (e.g., —SiR₃, where R may be a substituted or unsubstituted C₁ to C20 alkyl group), the oxy group, or the thio group, respectively. The terms “arylsilyl group”, “aryloxy group”, or “arylthio group” indicate that the aryl group is substituted with the silyl group, the oxy group, or the thio group, respectively. And, the alkylsilyl group, the arylsilyl group, the alkoxy group, the aryloxy group, the alkylthio group, and the arylthio group may be optionally substituted.

As used herein, the term “amino” refers to a functional group represented by —NR₂, where each R is independently hydrogen, deuterium, an alkyl group, or an aryl group.

As used herein, the term “acyl” refers to a functional group represented by RC(═O)—, where each R is independently hydrogen, deuterium, an alkyl group, or an aryl group.

The term “substituted” used herein indicates that instead of a hydrogen atom (H) being bonded to a carbon atom, another substituent is bonded to the corresponding carbon atom. A substituted group may refer to groups with a single substituent or a plurality of substituents. When a plurality of substituents are present, each substituent may be the same as or different from each other.

Unless otherwise stated herein, the substituent(s) may be selected from the group consisting of deuterium; halogen; alkyl; cycloalkyl; heteroalkyl; arylalkyl; alkoxy; aryloxy; amino; silyl; alkenyl; cycloalkenyl; heteroalkenyl; alkynyl; aryl; heteroaryl; acyl; carbonyl, carboxylic acid; ester; nitrile; isonitrile; sulfanyl; sulfinyl; sulfonyl; phosphino; and combinations thereof, and the substituent may be partially or entirely deuterated.

As used herein, “deuterated” may indicate substitution with deuterium instead of light hydrogen in a compound.

Unless otherwise stated herein, a position at which a substituent is present is not limited as long as it is a position where a hydrogen atom may be substituted, that is, a position where a substituent may be attached, and when two or more substituents are present, each substituent may be the same as or different from each other.

The objects and substituents as defined herein may be the same as or different from each other unless otherwise stated.

Hereinafter, a structure of an organometallic compound and an organic light emitting diode including the same according to some example embodiments of the present disclosure will be described in detail.

Organometallic compounds have been used as dopants in phosphorescent light emission layers, and for example, structures such as 2-phenylpyridine are known as main ligand structures of the organometallic compounds. However, since the light emitting dopants in related art have limitations in increasing the efficiency and lifetime of organic light emitting diodes, it may be beneficial to develop new light emitting dopant materials. The present disclosure was completed by experimentally confirming that by mixing a hole transport type host and an electron transport type host as host materials together with the dopant material, it was possible to further increase the efficiency and lifetime of the organic light emitting diode and decrease the driving voltage, thereby improving the characteristics of the organic light emitting diode.

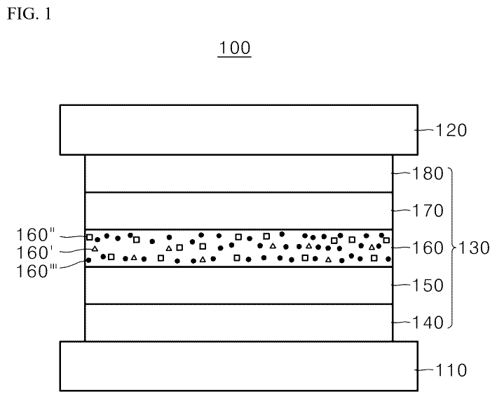

Referring to FIG. 1 according to one example embodiment of the present disclosure, there may be provided an organic light emitting diode 100 including a first electrode 110, a second electrode 120 facing the first electrode 110, and an intermediate layer 130 disposed between the first electrode 110 and the second electrode 120. The intermediate layer 130 may include an emission layer 160, the emission layer 160 may include a dopant material 160′ and host materials 160″ and 160′″ and include the dopant material (organometallic compound) 160′ represented by Chemical Formula 1 below as the dopant material, and the host material may include two types of the compound 160″ represented by Chemical Formula 2 below as the hole transport type host and the compound 160′″ represented by Chemical Formula 3 below as the electron transport type host.

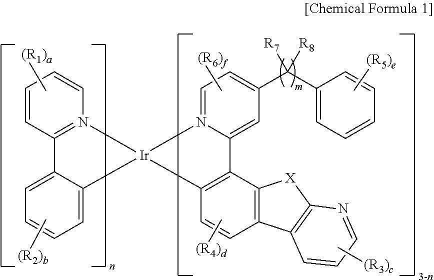

in Chemical Formula 1,
X may be one selected from oxygen (O), sulfur(S), and selenium (Se),
each R₁ to R₆ may independently be one selected from deuterium, halogen, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a a carboxylic acid group, a nitrile group, an isonitrile group, a sulfanyl group, and a phosphino group, and combinations thereof, where the alkyl group, the cycloalkyl group, the heteroalkyl group, the arylalkyl group, the alkoxy group, the aryloxy group, the amino group, the silyl group, the alkenyl group, the cycloalkenyl group, the heteroalkenyl group, the alkynyl group, the aryl group, the heteroaryl group, the acyl group, and the phosphino group are optionally partially deuterated or optionally entirely deuterated,
each R₇ and R₈ may independently be one selected from hydrogen, deuterium, a C1-C6 linear alkyl group, a C3-C6 branched alkyl group, and a C3-C6 cycloalkyl group, where the C1-C6 linear alkyl group, the C3-C6 branched alkyl group, and the C3-C6 cycloalkyl group are optionally partially deuterated or optionally entirely deuterated,
a and b are, each independently, an integer from 0 to 4, and when a and b are each independently an integer from 2 to 4, a plurality of R₁ or a plurality of R₂ are the same or different from each other,
c and f are, each independently, an integer from 0 to 3, and when c and f are each independently an integer of 2 or 3, a plurality of R₃ or a plurality of R₆ are the same or different from each other,
d is an integer from 0 to 2, and when d is an integer of 2, a plurality of R₄ are the same or different from each other,
e is an integer from 0 to 5, and when e is an integer from 2 to 5, a plurality of R₅ are the same or different from each other, and
m is an integer selected from 1 to 8, and n is an integer selected from 0 to 2,

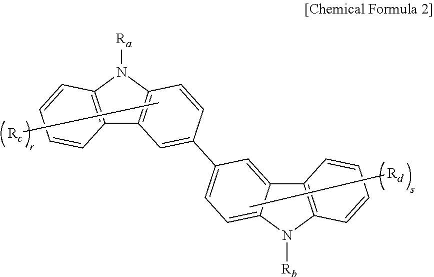

in Chemical Formula 2,
Rₐ and R_{b} may each independently be one selected from an aryl group and a heteroaryl group, where the aryl group and the heteroaryl group are optionally substituted with one or more substituents selected from an alkyl group, an aryl group, a nitrile group, an alkylsilyl group, and an arylsilyl group, and Rₐ and R_{b} may be optionally partially deuterated or optionally entirely deuterated,
each Re and Rₐ may each independently be one selected from hydrogen, deuterium, halogen, nitrile group, and alkyl group, and R_{c} and Rₐ may be optionally partially deuterated or optionally entirely deuterated, and r and s each independently denotes an integer selected from 0 to 7, and when r is an
integer selected from 2 to 7, each R_{c} is the same as or different from each other, and when s is an integer selected from 2 to 7, each Rₐ is the same as or different from each other.

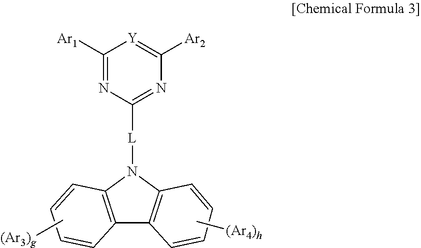

in Chemical Formula 3,
L may be one selected from a single bond, a C6-C50 arylene group, and a C5-C50 heteroarylene group,
Y may be N or CH,
each Ar₁, Ar₂, Ar₃, and Ar₄ may independently be one selected from hydrogen, deuterium, halogen, a C1-C30 alkyl group, a C6-C50 aryl group, a C3-C50 heteroaryl group, and a C3-C30 cycloalkyl group,
g and h are each independently an integer selected from 1 to 4,
when g is an integer selected from 2 to 4, any two adjacent Ar₃ may be optionally bonded to form a fused ring structure including a C6-C30 monocyclic or polycyclic aromatic group, or a C3-C30 heteroaromatic group, and one or more of hydrogens attached to the fused ring structure may be optionally substituted by a substituent selected from deuterium, a C1-C10 alkyl group, a C6-C20 aryl group, and a C3-C20 heteroaryl group, and
when h is an integer selected from 2 to 4, any two adjacent Ar₄ may be optionally bonded to form a fused ring structure including a C6-C30 monocyclic or polycyclic aromatic group, or a C3-C30 heteroaromatic group, and one or more of hydrogens attached to the fused ring structure may be optionally substituted by a substituent selected from deuterium, a C1-C10 alkyl group, a C6-C20 aryl group, and a C3-C20 heteroaryl group.

According to some example embodiments of the present disclosure, the organometallic compound represented by Chemical Formula 1 may have a homoleptic or heteroleptic structure. In some example embodiments, a homoleptic structure is one in which n is 0, a heteroleptic structure is one in which n is 1 or 2., In some example embodiments, n may be, for example, 2.

According to some example embodiments of the present disclosure, n in Chemical Formula 1 may be one of integers selected from 0 to 2. In some example embodiments of the present disclosure, n may be, for example, 2.

According to some example embodiments of the present disclosure, X in Chemical Formula 1 may be oxygen (O) or sulfur(S). In some example embodiments of the present disclosure, and X may be, for example, oxygen (O).

According to some example embodiments of the present disclosure, m in Chemical Formula 1 may be 1 or more, for example, an integer of 1 to 3, and for example, an integer of 1 or 2.

According to some embodiments of the present disclosure, (R₁)ₐ and (R₂)_{b} in Chemical Formula 1 may, each independently, be at least one selected from the group consisting of hydrogen, deuterium, a C1-C10 alkyl group, a C6-C30 aryl group, a C3-C30 heteroaryl group, and a C7-C40 arylalkyl group, and a and b, each independently, may be an integer of 1 or 2.

According to some embodiments of the present disclosure, at least one of R₁ or at least one of R₂ in Chemical Formula 1 may be a C1-C3 alkyl group, and in this case, the C1-C3 alkyl group as R₁ or R₂ may be substituted with deuterium.

According to some embodiments of the present disclosure, at least one R₃ in Chemical Formula 1 may be a C1-C3 linear alkyl group, and in this case, R₃ may be substituted with deuterium.

According to some embodiments of the present disclosure, (R₄) d in Chemical Formula 1 may indicate all hydrogen.

According to some embodiments of the present disclosure, (R₅) e in Chemical Formula 1 may indicate all hydrogen, or otherwise, 1 or 2 of R₅ may not be hydrogen (i.e., e is 1 or 2).

According to some embodiments of the present disclosure, when e is 1 or 2, R₅ may be at least one selected from the group consisting of deuterium, a C1-C10 linear alkyl group, and a C3-C10 branched alkyl group, and R₅ may be substituted with deuterium.

According to some embodiments of the present disclosure, (R₆) f in Chemical Formula 1 may indicate all hydrogen.

According to some example embodiments of the present disclosure, R₇ and R₈ define the alkyl group of an aralkyl group bonded to the pyridine moiety in Chemical Formula 1 and may each independently be hydrogen, deuterium, a C1-C3 linear alkyl group, and a C3-C6 branched alkyl group. Optionally, the C1-C3 linear alkyl group or the C3-C6 branched alkyl group selected as R₇ and R₈ may each independently be substituted with deuterium.

According to some example embodiments of the present disclosure, the organometallic compound represented by Chemical Formula 1 may be one of or may include one of Compounds GD1 to GD20 below, but is not limited thereto as long as it is included in the definition of Chemical Formula 1.

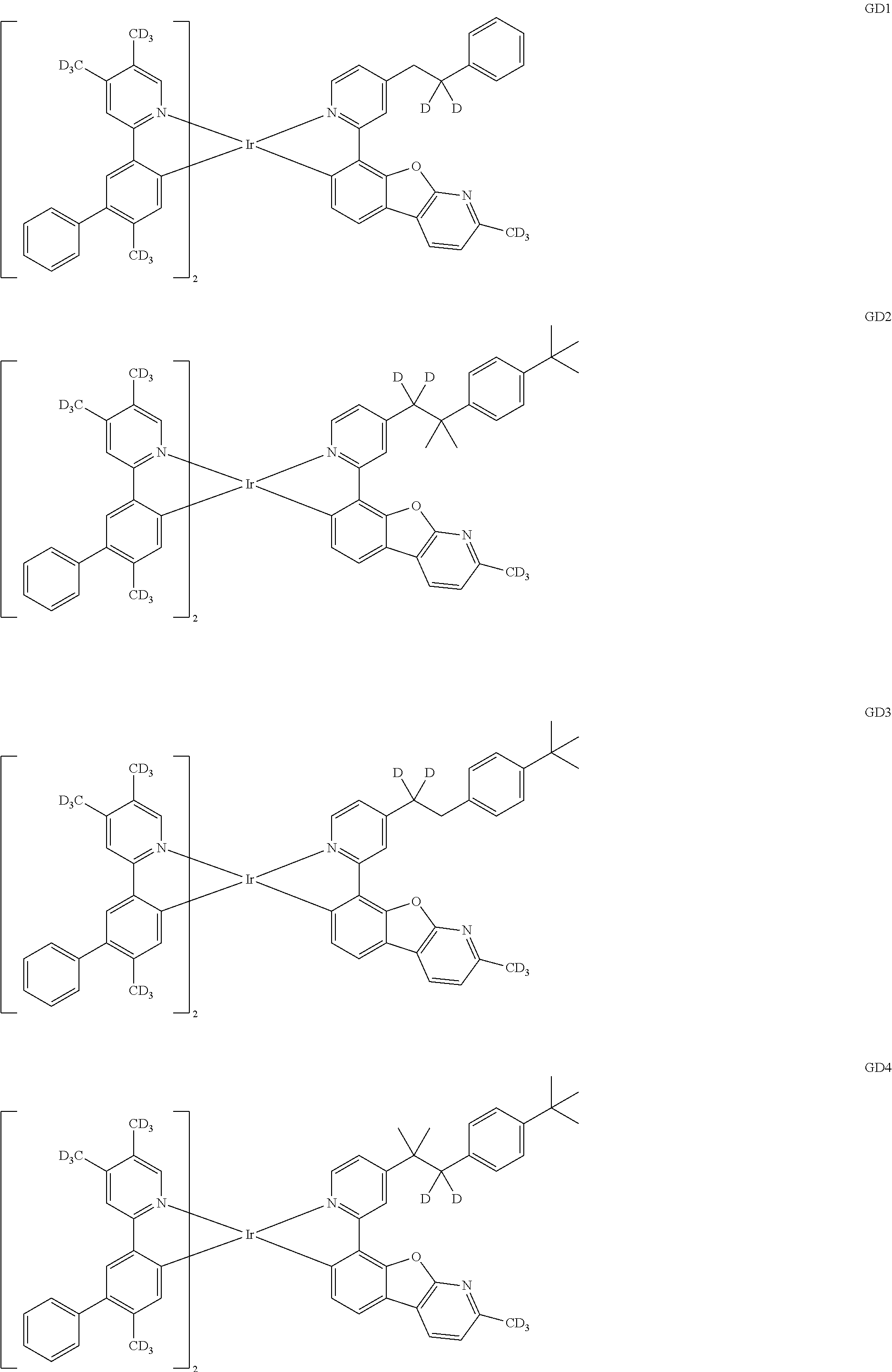

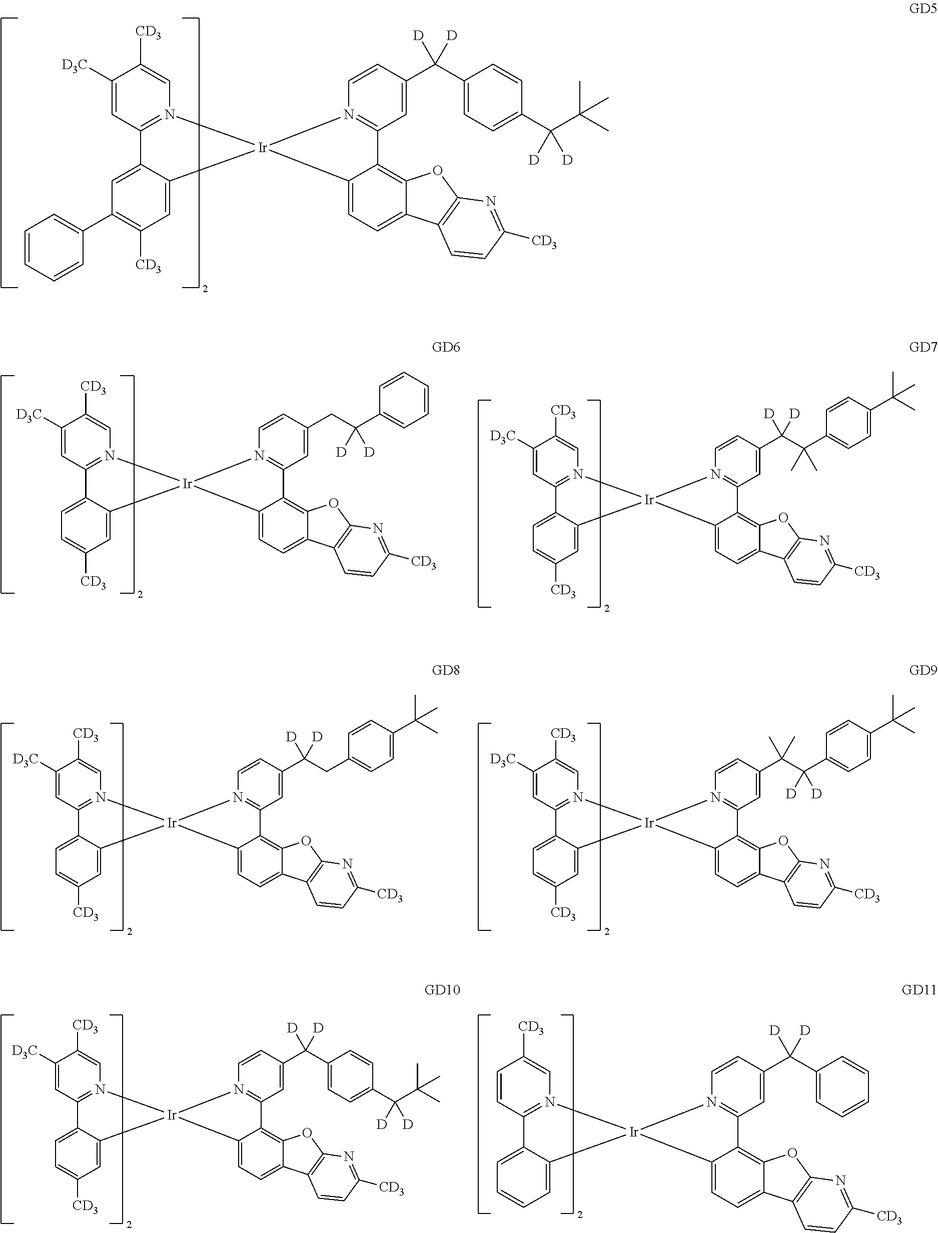

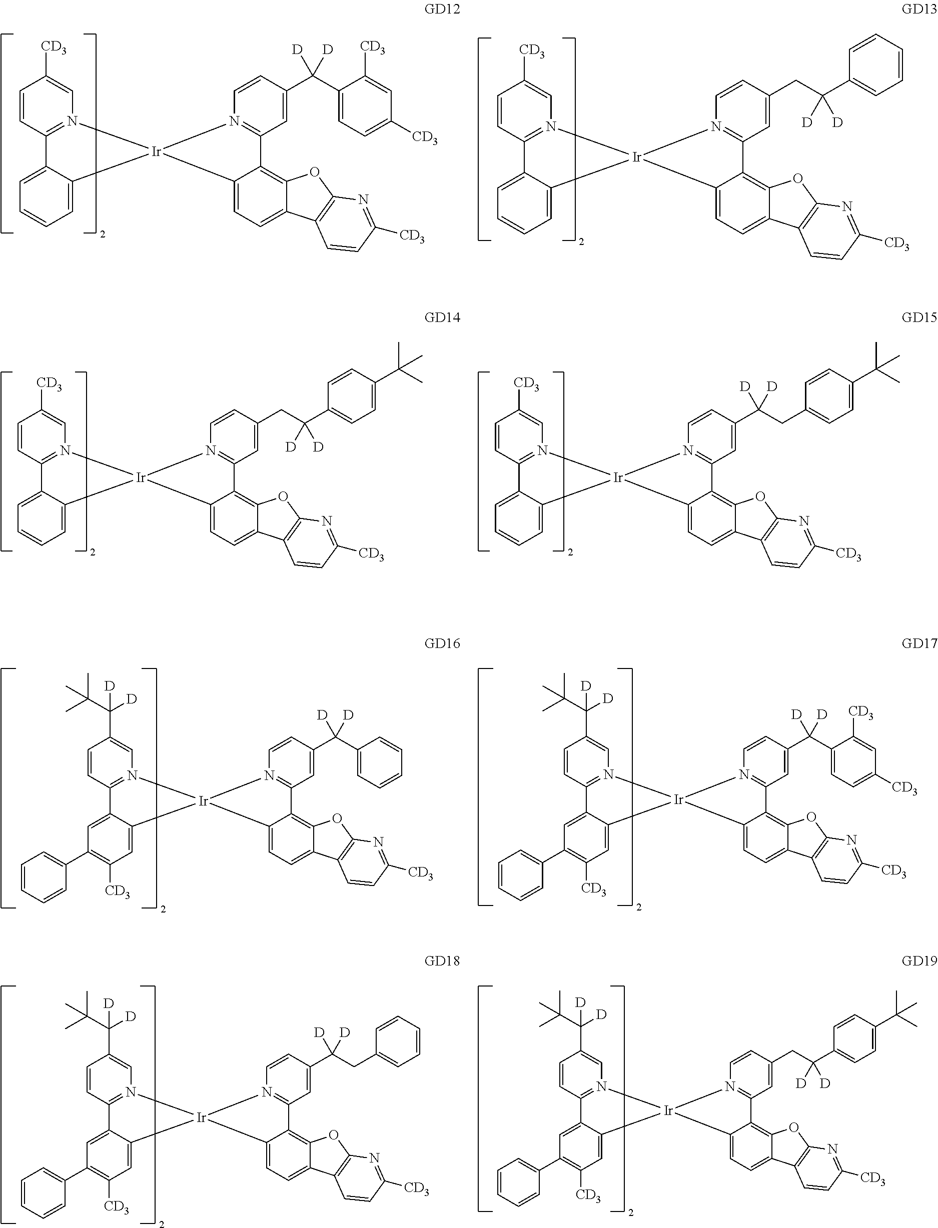

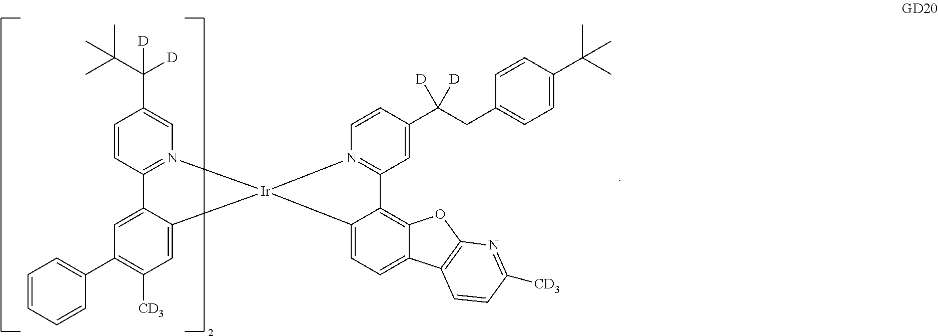

According to some example embodiments of the present disclosure, Rₐ and R_{b} in Chemical Formula 2 may be a C6-C40 monocyclic or polycyclic aryl group or a C2-C30 heteroaryl group, and optionally, the C6-C40 aryl groups that are selected as Rₐ and R_{b} may each independently be substituted with one or more substituents selected from an alkyl group, an aryl group, a nitrile group, an alkylsilyl group, and an arylsilyl group, and when a plurality of substituents are present, each substituent may be the same as or different from each other.

According to some example embodiments of the present disclosure, Rₐ and R_{b} may be a monocyclic or polycyclic aryl group, and for example, the aryl groups that are selected as Rₐ and R_{b} may each independently be one selected from a phenyl group, a biphenyl group, a terphenyl group, a naphthyl group, an anthracene group, a chrysene group, a pyrene group, a phenanthrene group, a triphenylene group, a fluorene group, a 9,9′-dimethylfluorene group, a 9,9′-diphenylfluorene group, and a 9,9′-spirofluorene group, but is not limited thereto.

According to some example embodiments of the present disclosure, R_{c} and Rₐ in Formula 2 may each be one selected from hydrogen, deuterium, halogen, a nitrile group, and an alkyl group. When a plurality of R_{c} and Rₐ are present, the substituents may be the same as or different from each other. In some example embodiments of the present disclosure, R_{c} and Rd may all be hydrogen.

According to some example embodiments of the present disclosure, the compound represented by Chemical Formula 2 may be one of or may include one of Compounds GHH1 to GHH30 below, but is not limited thereto as long as it is included in the definition of Chemical Formula 2.

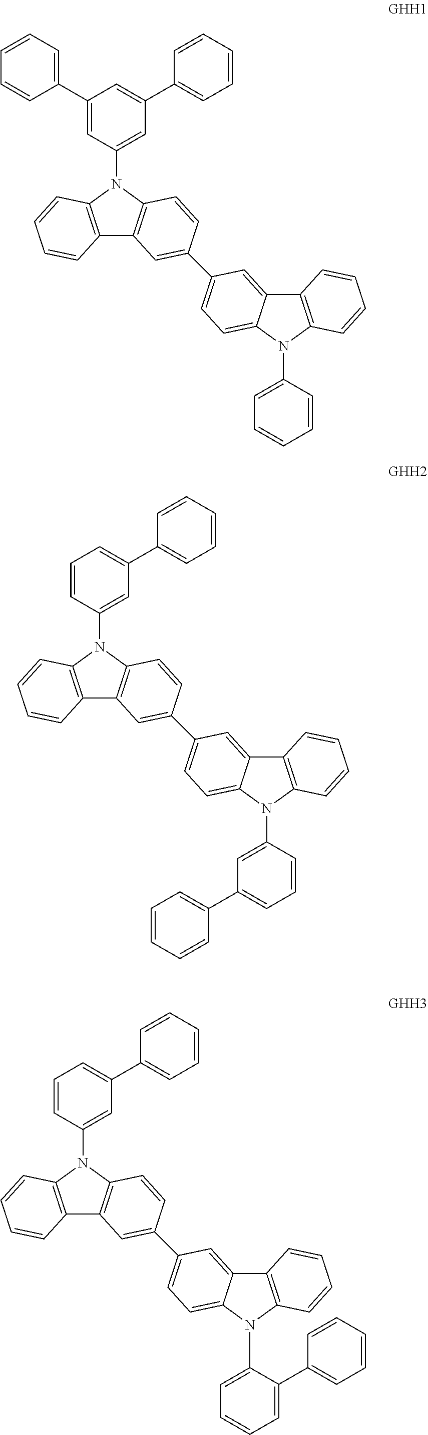 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]

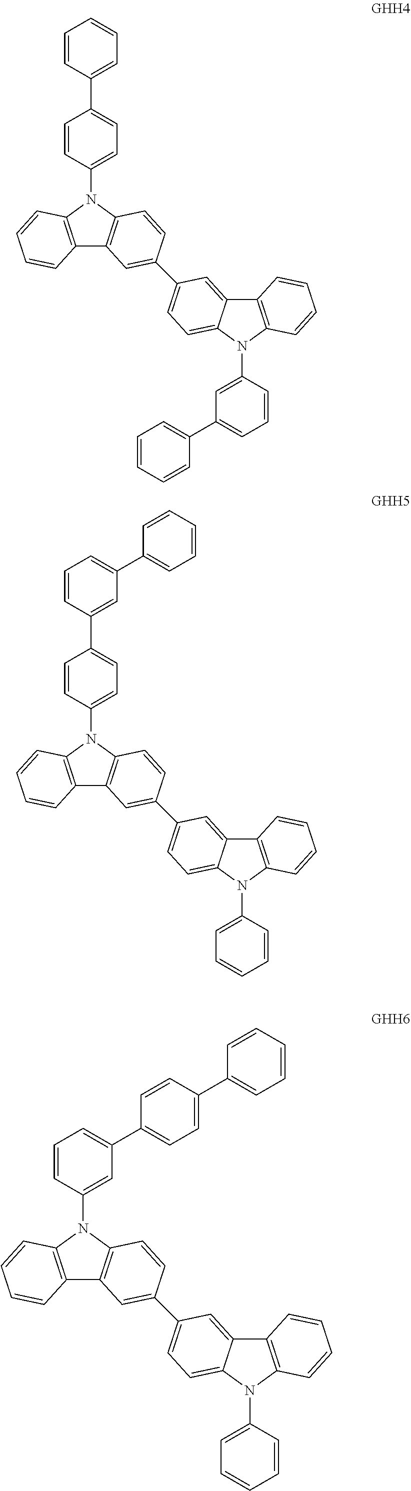

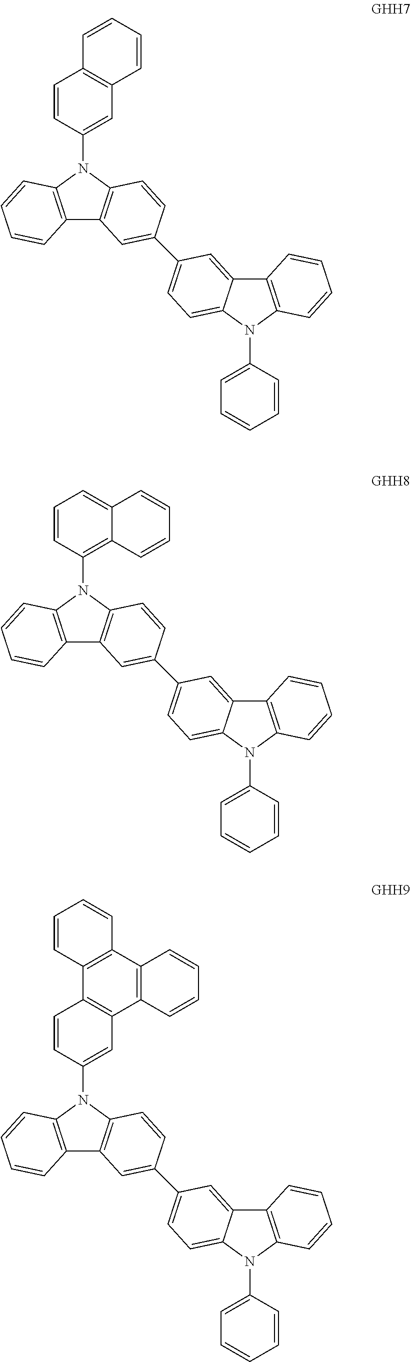 [SMILES: c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1 ; c1ccc(-n2c3ccccc3c3cc(-c4ccc5c(c4)c4ccccc4n5-c4ccc5c6ccccc6c6ccccc6c5c4)ccc32)cc1]

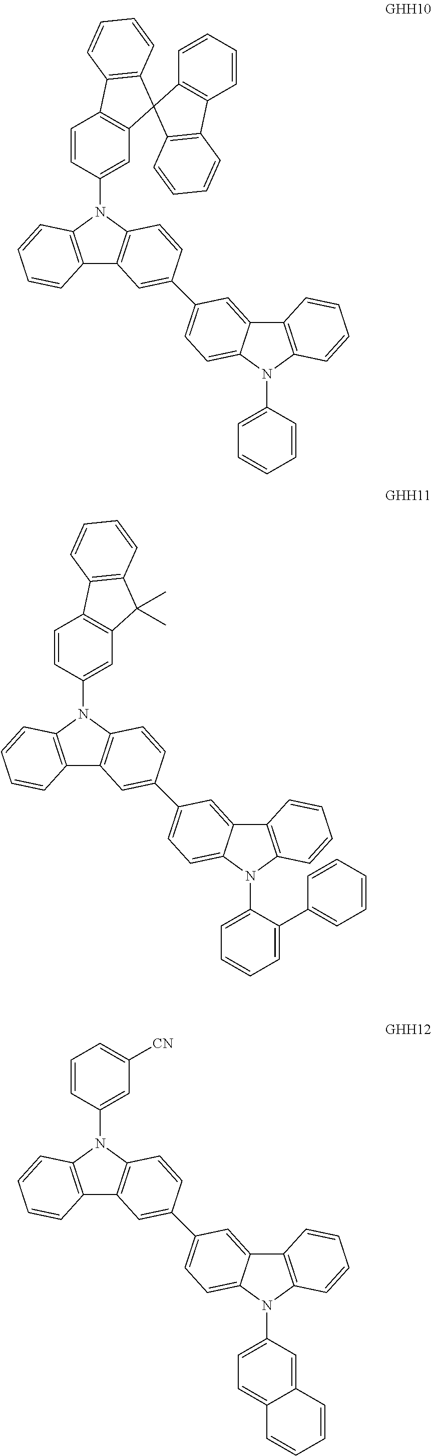 [SMILES: c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1 ; CC1(C)c2ccccc2-c2ccc(-n3c4ccccc4c4cc(-c5ccc6c(c5)c5ccccc5n6-c5ccccc5-c5ccccc5)ccc43)cc21 ; N#Cc1cccc(-n2c3ccccc3c3cc(-c4ccc5c(c4)c4ccccc4n5-c4ccc5ccccc5c4)ccc32)c1]

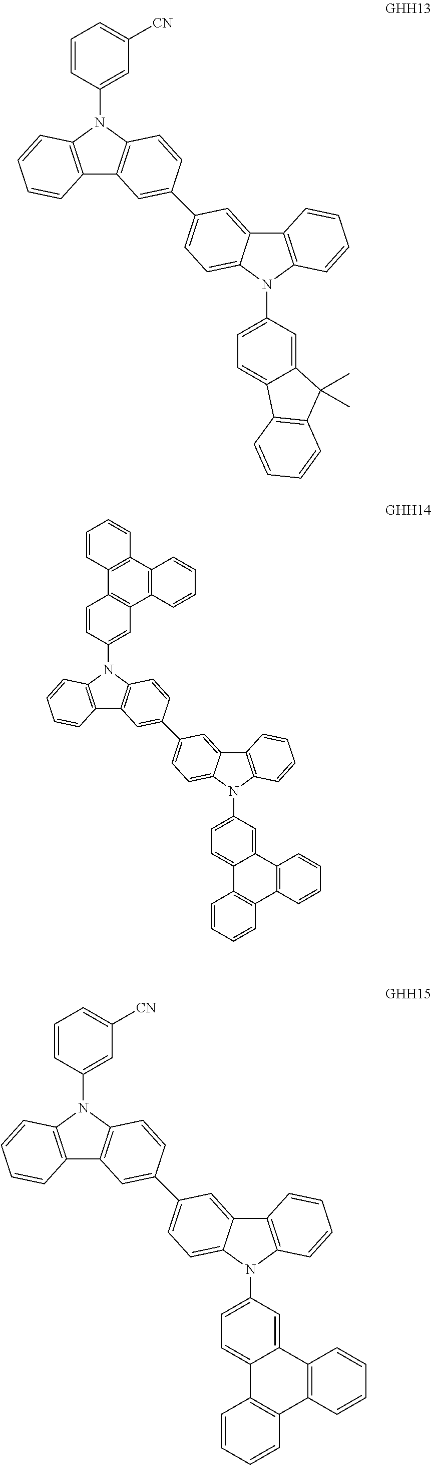 [SMILES: CC1(C)c2ccccc2-c2ccc(-n3c4ccccc4c4cc(-c5ccc6c(c5)c5ccccc5n6-c5cccc(C#N)c5)ccc43)cc21 ; c1ccc2c(c1)c1ccccc1c1cc(-n3c4ccccc4c4cc(-c5ccc6c(c5)c5ccccc5n6-c5ccc6c7ccccc7c7ccccc7c6c5)ccc43)ccc21 ; N#Cc1cccc(-n2c3ccccc3c3cc(-c4ccc5c(c4)c4ccccc4n5-c4ccc5c6ccccc6c6ccccc6c5c4)ccc32)c1]

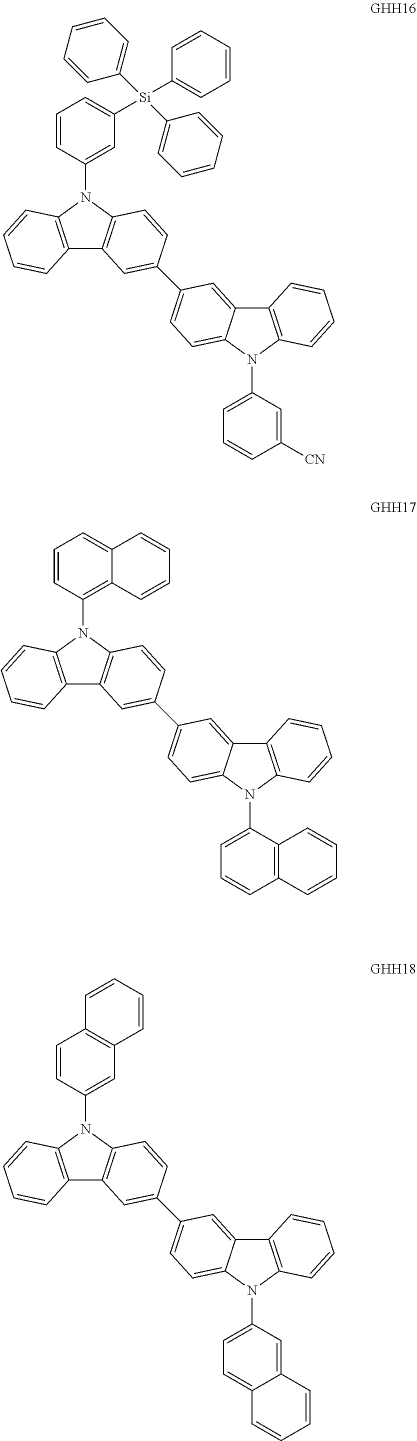 [SMILES: N#Cc1cccc(-n2c3ccccc3c3cc(-c4ccc5c(c4)c4ccccc4n5-c4cccc([Si](c5ccccc5)(c5ccccc5)c5ccccc5)c4)ccc32)c1 ; c1ccc2c(-n3c4ccccc4c4cc(-c5ccc6c(c5)c5ccccc5n6-c5cccc6ccccc56)ccc43)cccc2c1 ; c1ccc2cc(-n3c4ccccc4c4cc(-c5ccc6c(c5)c5ccccc5n6-c5ccc6ccccc6c5)ccc43)ccc2c1]

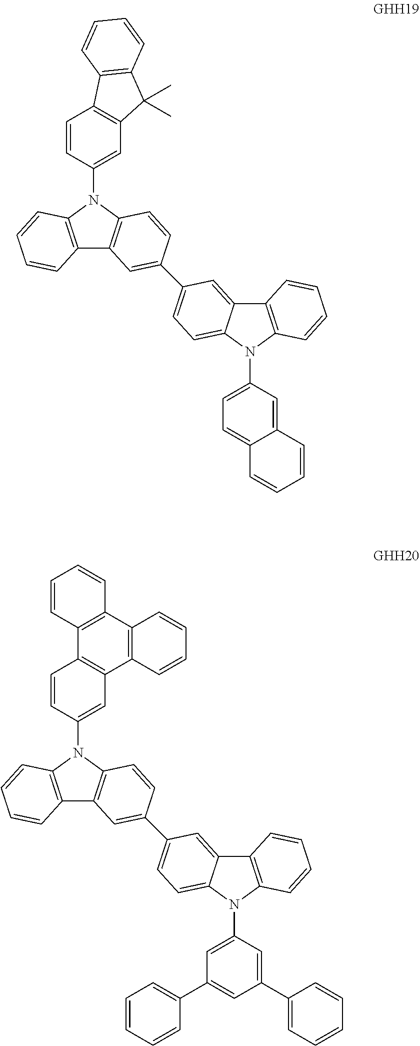 [SMILES: CC1(C)c2ccccc2-c2ccc(-n3c4ccccc4c4cc(-c5ccc6c(c5)c5ccccc5n6-c5ccc6ccccc6c5)ccc43)cc21 ; c1ccc(-c2cc(-c3ccccc3)cc(-n3c4ccccc4c4cc(-c5ccc6c(c5)c5ccccc5n6-c5ccc6c7ccccc7c7ccccc7c6c5)ccc43)c2)cc1]

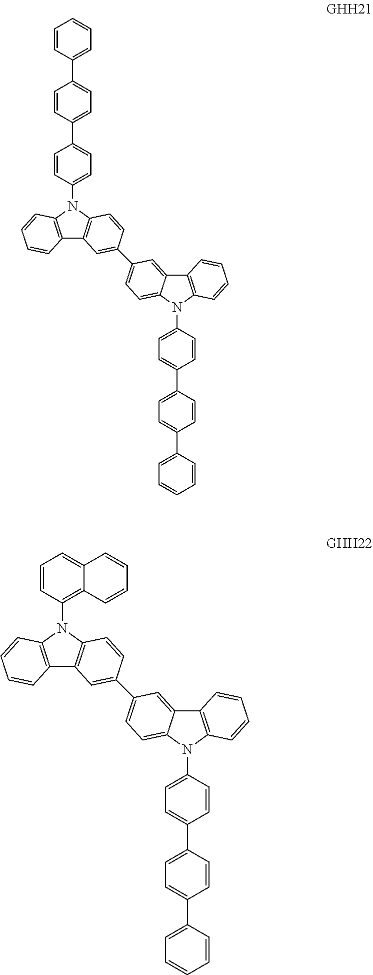 [SMILES: c1ccc(-c2ccc(-c3ccc(-n4c5ccccc5c5cc(-c6ccc7c(c6)c6ccccc6n7-c6ccc(-c7ccc(-c8ccccc8)cc7)cc6)ccc54)cc3)cc2)cc1 ; c1ccc(-c2ccc(-c3ccc(-n4c5ccccc5c5cc(-c6ccc7c(c6)c6ccccc6n7-c6cccc7ccccc67)ccc54)cc3)cc2)cc1]

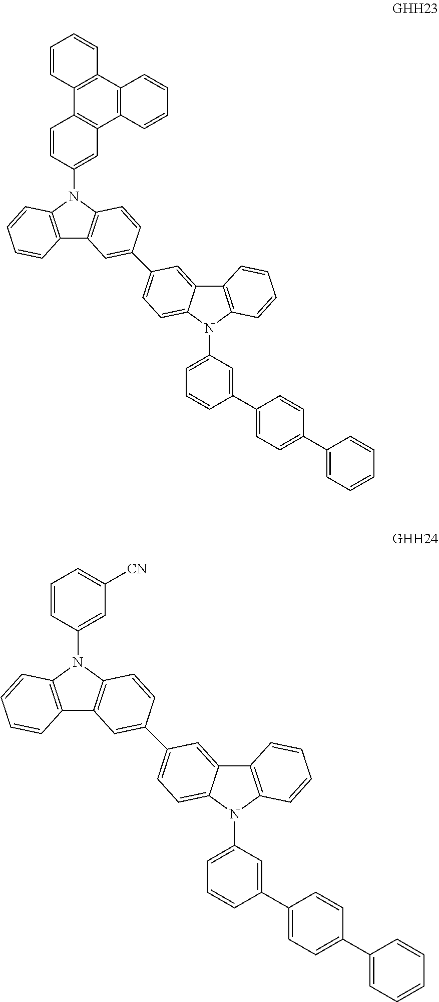 [SMILES: c1ccc(-c2ccc(-c3cccc(-n4c5ccccc5c5cc(-c6ccc7c(c6)c6ccccc6n7-c6ccc7c8ccccc8c8ccccc8c7c6)ccc54)c3)cc2)cc1 ; N#Cc1cccc(-n2c3ccccc3c3cc(-c4ccc5c(c4)c4ccccc4n5-c4cccc(-c5ccc(-c6ccccc6)cc5)c4)ccc32)c1]

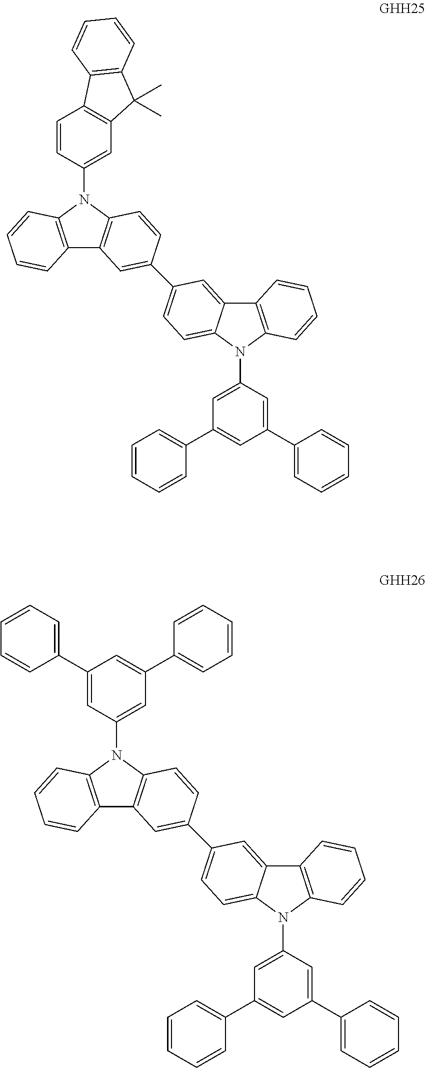 [SMILES: CC1(C)c2ccccc2-c2ccc(-n3c4ccccc4c4cc(-c5ccc6c(c5)c5ccccc5n6-c5cc(-c6ccccc6)cc(-c6ccccc6)c5)ccc43)cc21 ; c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1]

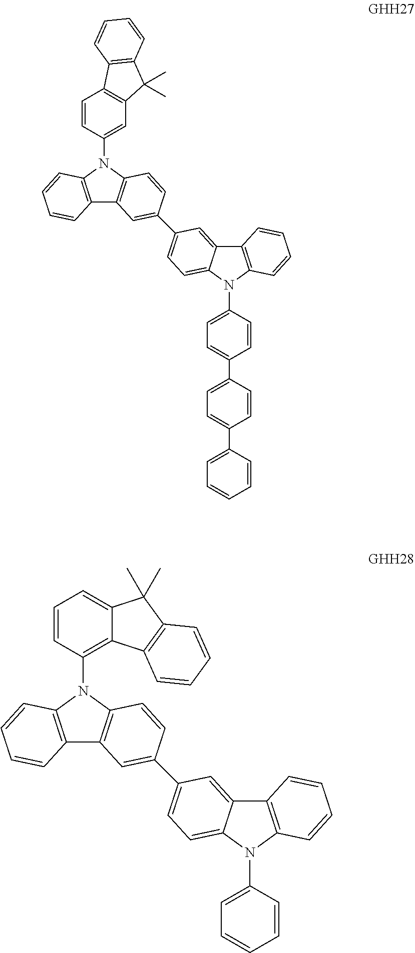 [SMILES: CC1(C)c2ccccc2-c2ccc(-n3c4ccccc4c4cc(-c5ccc6c(c5)c5ccccc5n6-c5ccc(-c6ccc(-c7ccccc7)cc6)cc5)ccc43)cc21 ; CC1(C)c2ccccc2-c2c(-n3c4ccccc4c4cc(-c5ccc6c(c5)c5ccccc5n6-c5ccccc5)ccc43)cccc21]

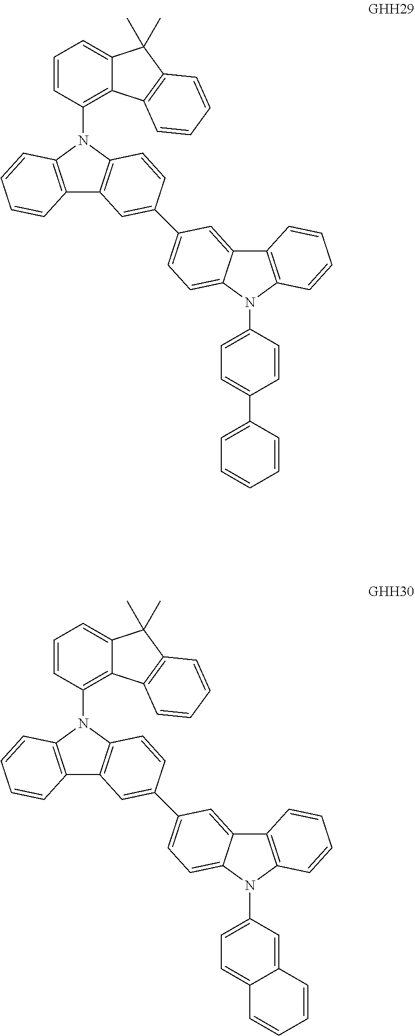 [SMILES: CC1(C)c2ccccc2-c2c(-n3c4ccccc4c4cc(-c5ccc6c(c5)c5ccccc5n6-c5ccc(-c6ccccc6)cc5)ccc43)cccc21 ; CC1(C)c2ccccc2-c2c(-n3c4ccccc4c4cc(-c5ccc6c(c5)c5ccccc5n6-c5ccc6ccccc6c5)ccc43)cccc21]

According to some example embodiments of the present disclosure, Ar₁ and Ar₂ in Chemical Formula 3 may each independently be a C6-C50 aryl group and a C3-C50 heteroaryl group.

According to some example embodiments of the present disclosure, each of Ar₁, Ar₂, Ar₃, and Ar₄ in Chemical Formula 3 may independently be one selected from a phenyl group, a biphenyl group, a naphthyl group, a dibenzofuran group, a carbazole group, an indole group, a dibenzothiophene group, a chrysene group, a benzochrysene group, a phenanthrene group, a benzophenanthrene group, a benzonaphthothiophene group, and a benzonaphthofuran group, but are not limited thereto. In some example embodiments of the present disclosure, each of Ar₁, Ar₂, Ar₃, and Ar₄ may independently be one selected from a phenyl group, a biphenyl group, a dibenzofuran group, a dibenzothiophene group, and a carbazole group.

According to some example embodiments of the present disclosure, when Ar₃ or Ar₄ in Chemical Formula 3 is formed in plural, a ring structure formed by fusing two adjacent Ar₃ or two adjacent Ar₄ may be an aromatic group or a heteroaromatic group.

According to some example embodiments of the present disclosure, the ring structure formed by fusing adjacent Ar₃ or adjacent Ar₄ may be a structure fused to the carbazole group and may be a structure in which 5-membered and 6-membered ring structures are bonded consecutively.

According to some example embodiments of the present disclosure, Y in Chemical Formula 3 may be N.

According to some example embodiments of the present disclosure, L in Chemical Formula 3 may be a single bond or a ring group, and the ring group may be a C6-C50 arylene group or a C5-C50 heteroarylene group.

According to some example embodiments of the present disclosure, when L in Chemical Formula 3 is a ring group, and the ring group is, for example, selected from the group consisting of a phenyl group; a biphenyl group; a naphthalene group; a dibenzofuran group; and a dibenzothiophene group, and preferably, may be one selected from a single bond and a phenyl group, but is not limited thereto. In this case, when L in Chemical Formula 3 is not the single bond, the positional relationship between a triazine portion in the structure of L (e.g., a case in which Y in Chemical Formula 3 is N) and the nitrogen (N) of carbazole is not particularly limited.

According to some example embodiments of the present disclosure, the compound represented by Chemical Formula 3 may be one of or may include one of Compounds GEH1 to GEH30 below, but is not limited thereto as long as it is included in the definition of Chemical Formula 3.

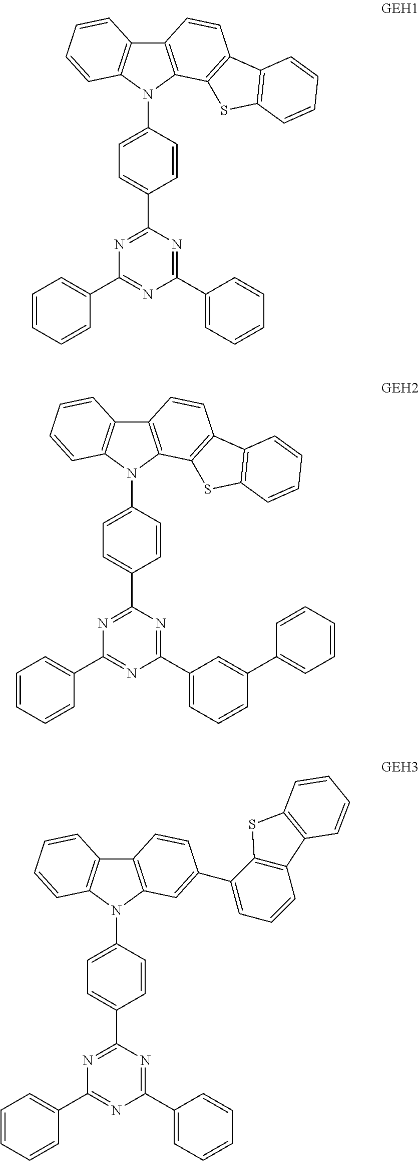 [SMILES: c1ccc(-c2nc(-c3ccccc3)nc(-c3ccc(-n4c5ccccc5c5ccc6c7ccccc7sc6c54)cc3)n2)cc1 ; c1ccc(-c2cccc(-c3nc(-c4ccccc4)nc(-c4ccc(-n5c6ccccc6c6ccc7c8ccccc8sc7c65)cc4)n3)c2)cc1 ; c1ccc(-c2nc(-c3ccccc3)nc(-c3ccc(-n4c5ccccc5c5ccc(-c6cccc7c6sc6ccccc67)cc54)cc3)n2)cc1]

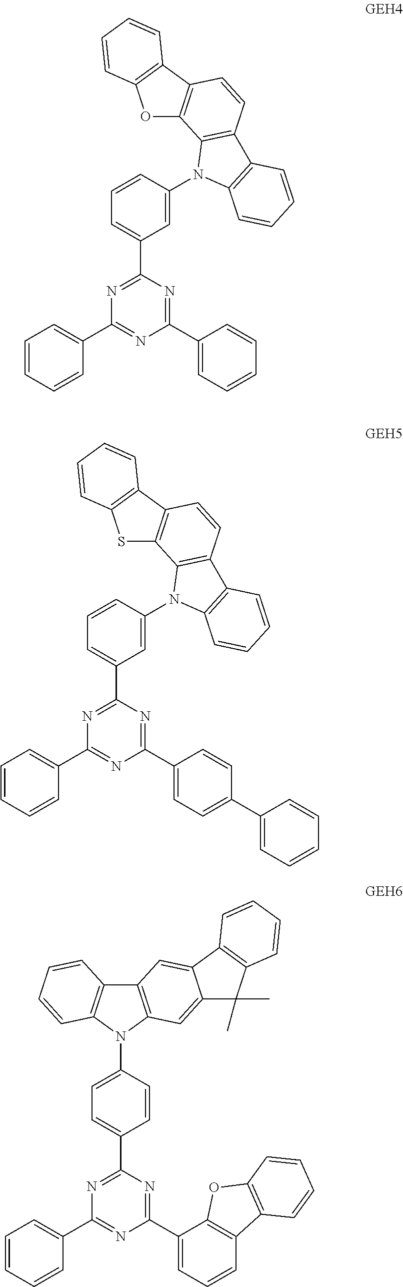 [SMILES: c1ccc(-c2nc(-c3ccccc3)nc(-c3cccc(-n4c5ccccc5c5ccc6c7ccccc7oc6c54)c3)n2)cc1 ; c1ccc(-c2ccc(-c3nc(-c4ccccc4)nc(-c4cccc(-n5c6ccccc6c6ccc7c8ccccc8sc7c65)c4)n3)cc2)cc1 ; CC1(C)c2ccccc2-c2cc3c4ccccc4n(-c4ccc(-c5nc(-c6ccccc6)nc(-c6cccc7c6oc6ccccc67)n5)cc4)c3cc21]

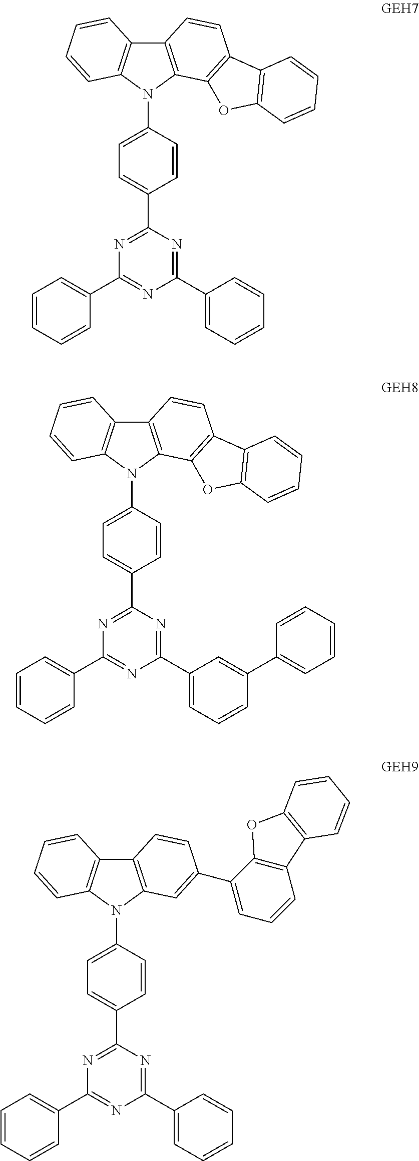 [SMILES: c1ccc(-c2nc(-c3ccccc3)nc(-c3ccc(-n4c5ccccc5c5ccc6c7ccccc7oc6c54)cc3)n2)cc1 ; c1ccc(-c2cccc(-c3nc(-c4ccccc4)nc(-c4ccc(-n5c6ccccc6c6ccc7c8ccccc8oc7c65)cc4)n3)c2)cc1 ; c1ccc(-c2nc(-c3ccccc3)nc(-c3ccc(-n4c5ccccc5c5ccc(-c6cccc7c6oc6ccccc67)cc54)cc3)n2)cc1]

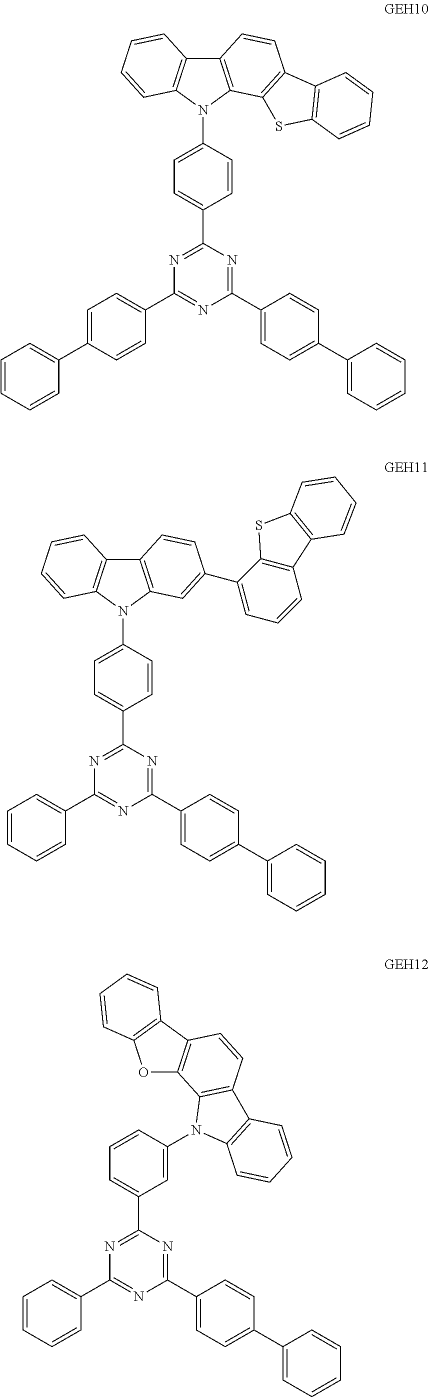 [SMILES: c1ccc(-c2ccc(-c3nc(-c4ccc(-c5ccccc5)cc4)nc(-c4ccc(-n5c6ccccc6c6ccc7c8ccccc8sc7c65)cc4)n3)cc2)cc1 ; c1ccc(-c2ccc(-c3nc(-c4ccccc4)nc(-c4ccc(-n5c6ccccc6c6ccc(-c7cccc8c7sc7ccccc78)cc65)cc4)n3)cc2)cc1 ; c1ccc(-c2ccc(-c3nc(-c4ccccc4)nc(-c4cccc(-n5c6ccccc6c6ccc7c8ccccc8oc7c65)c4)n3)cc2)cc1]

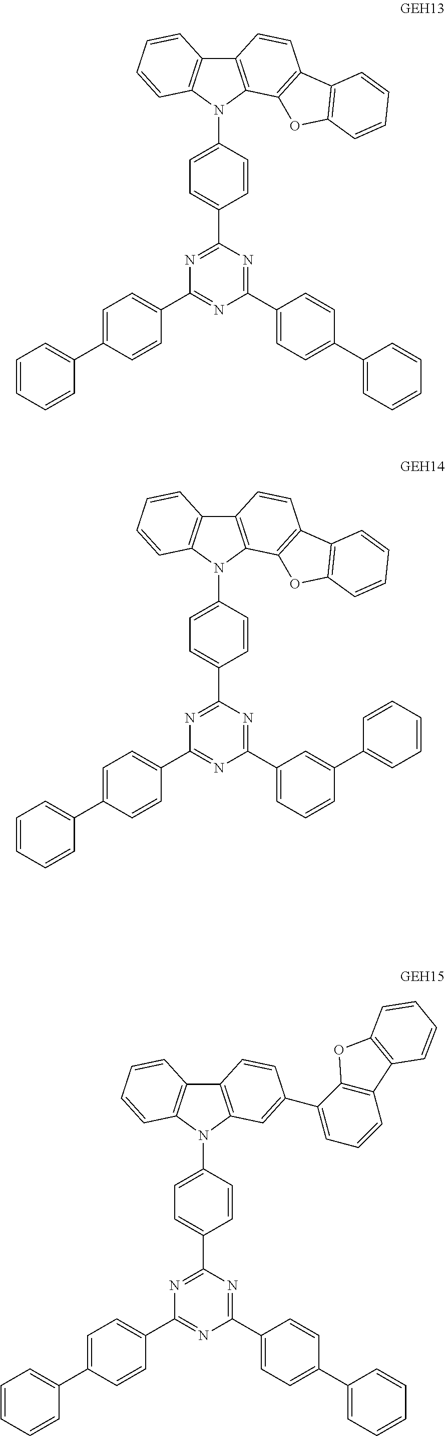 [SMILES: c1ccc(-c2ccc(-c3nc(-c4ccc(-c5ccccc5)cc4)nc(-c4ccc(-n5c6ccccc6c6ccc7c8ccccc8oc7c65)cc4)n3)cc2)cc1 ; c1ccc(-c2ccc(-c3nc(-c4ccc(-n5c6ccccc6c6ccc7c8ccccc8oc7c65)cc4)nc(-c4cccc(-c5ccccc5)c4)n3)cc2)cc1 ; c1ccc(-c2ccc(-c3nc(-c4ccc(-c5ccccc5)cc4)nc(-c4ccc(-n5c6ccccc6c6ccc(-c7cccc8c7oc7ccccc78)cc65)cc4)n3)cc2)cc1]

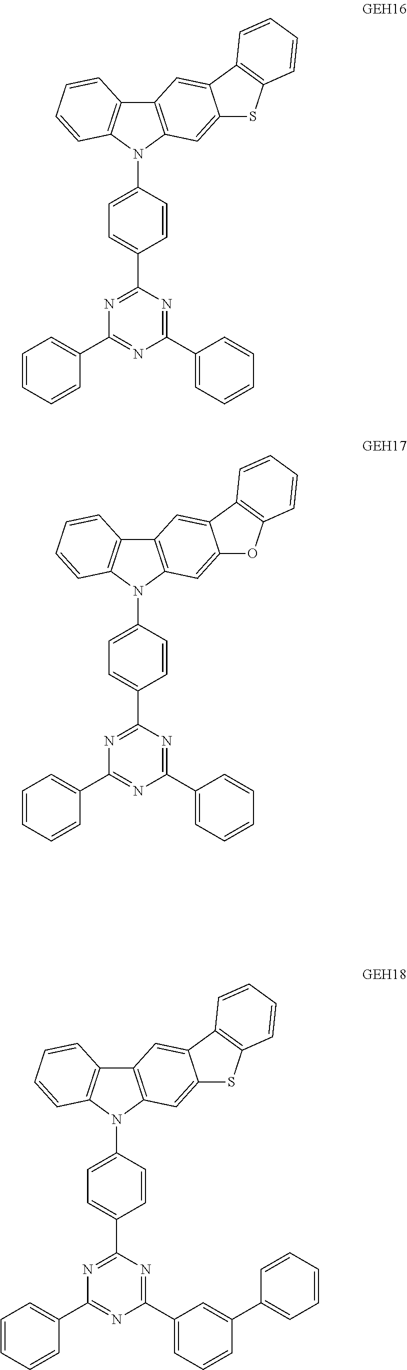 [SMILES: c1ccc(-c2nc(-c3ccccc3)nc(-c3ccc(-n4c5ccccc5c5cc6c(cc54)sc4ccccc46)cc3)n2)cc1 ; c1ccc(-c2nc(-c3ccccc3)nc(-c3ccc(-n4c5ccccc5c5cc6c(cc54)oc4ccccc46)cc3)n2)cc1 ; c1ccc(-c2cccc(-c3nc(-c4ccccc4)nc(-c4ccc(-n5c6ccccc6c6cc7c(cc65)sc5ccccc57)cc4)n3)c2)cc1]

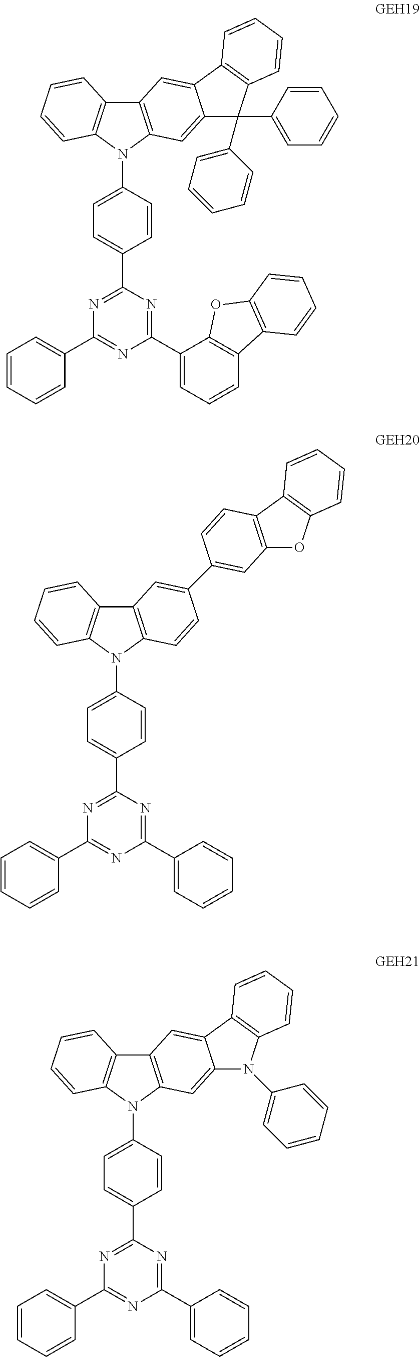 [SMILES: c1ccc(-c2nc(-c3ccc(-n4c5ccccc5c5cc6c(cc54)C(c4ccccc4)(c4ccccc4)c4ccccc4-6)cc3)nc(-c3cccc4c3oc3ccccc34)n2)cc1 ; c1ccc(-c2nc(-c3ccccc3)nc(-c3ccc(-n4c5ccccc5c5cc(-c6ccc7c(c6)oc6ccccc67)ccc54)cc3)n2)cc1 ; c1ccc(-c2nc(-c3ccccc3)nc(-c3ccc(-n4c5ccccc5c5cc6c7ccccc7n(-c7ccccc7)c6cc54)cc3)n2)cc1]

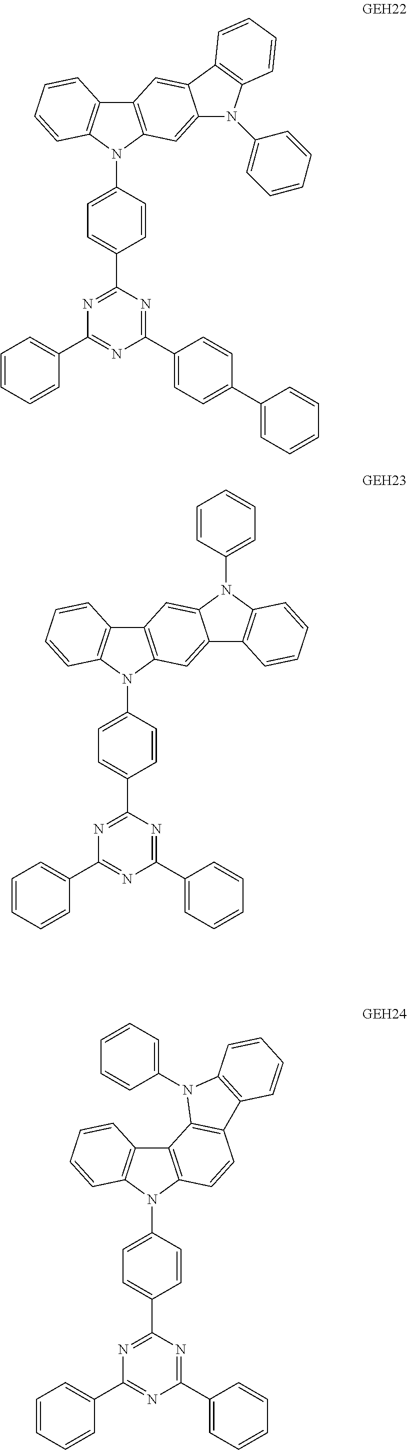 [SMILES: c1ccc(-c2ccc(-c3nc(-c4ccccc4)nc(-c4ccc(-n5c6ccccc6c6cc7c8ccccc8n(-c8ccccc8)c7cc65)cc4)n3)cc2)cc1 ; c1ccc(-c2nc(-c3ccccc3)nc(-c3ccc(-n4c5ccccc5c5cc6c(cc54)c4ccccc4n6-c4ccccc4)cc3)n2)cc1 ; c1ccc(-c2nc(-c3ccccc3)nc(-c3ccc(-n4c5ccccc5c5c4ccc4c6ccccc6n(-c6ccccc6)c45)cc3)n2)cc1]

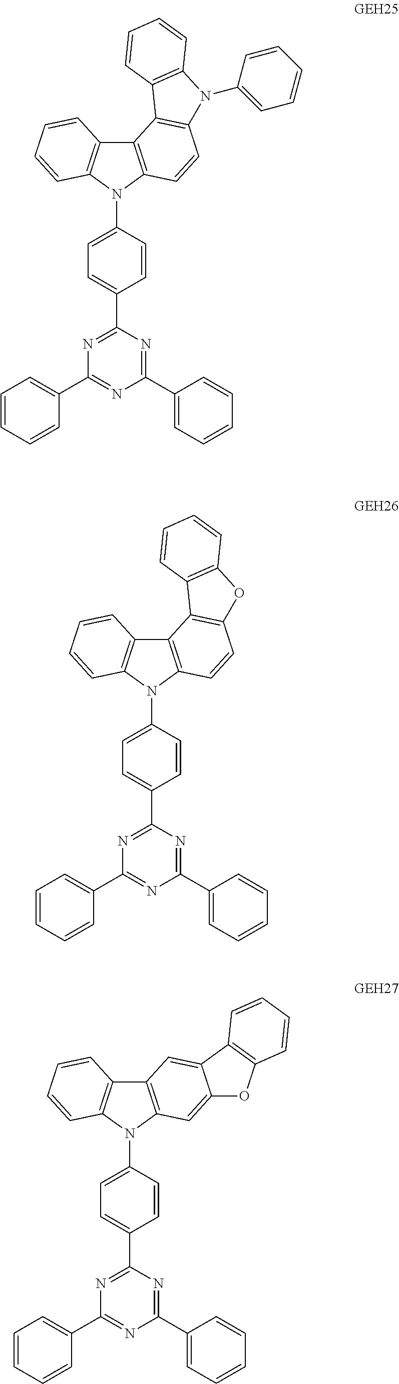 [SMILES: c1ccc(-c2nc(-c3ccccc3)nc(-c3ccc(-n4c5ccccc5c5c6c7ccccc7n(-c7ccccc7)c6ccc54)cc3)n2)cc1 ; c1ccc(-c2nc(-c3ccccc3)nc(-c3ccc(-n4c5ccccc5c5c6c(ccc54)oc4ccccc46)cc3)n2)cc1 ; c1ccc(-c2nc(-c3ccccc3)nc(-c3ccc(-n4c5ccccc5c5cc6c(cc54)oc4ccccc46)cc3)n2)cc1]

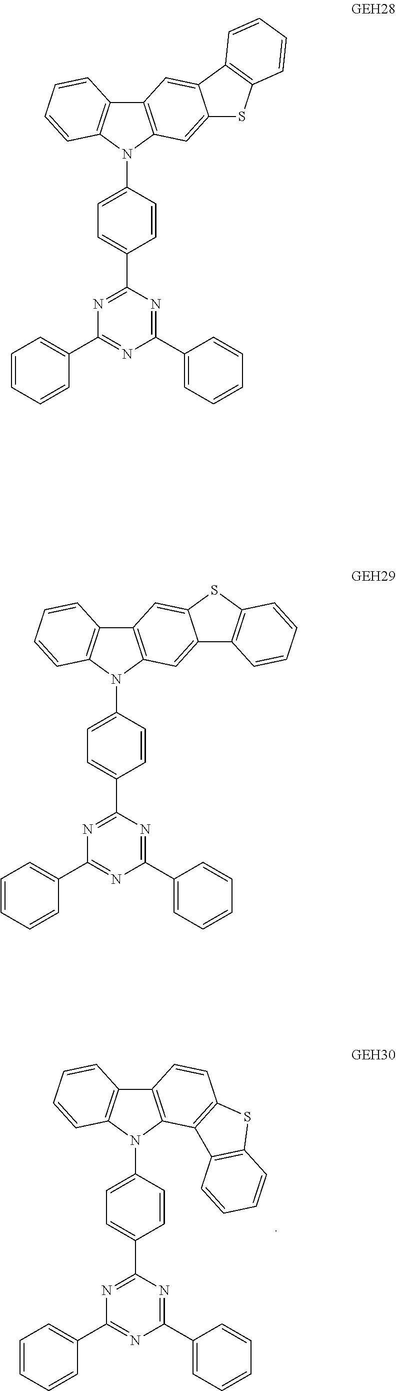 [SMILES: c1ccc(-c2nc(-c3ccccc3)nc(-c3ccc(-n4c5ccccc5c5cc6c(cc54)sc4ccccc46)cc3)n2)cc1 ; c1ccc(-c2nc(-c3ccccc3)nc(-c3ccc(-n4c5ccccc5c5cc6sc7ccccc7c6cc54)cc3)n2)cc1 ; c1ccc(-c2nc(-c3ccccc3)nc(-c3ccc(-n4c5ccccc5c5ccc6sc7ccccc7c6c54)cc3)n2)cc1]

In addition, in the organic light emitting diode 100, the intermediate layer 130 disposed between the first electrode 110 and the second electrode 120 may further include one or more selected from a hole injection layer (HIL) 140, a hole transport layer (HTL) 150, the emission layer (EML) 160, an electron transport layer (ETL) 170, and an electron injection layer (EIL) 180 sequentially from the first electrode 110. The second electrode 120 may be formed on or disposed on the electron injection layer 180, and a protective film (not shown) may be formed on or disposed on the second electrode 120.

In addition, although not shown in FIG. 1, one or more of a hole transport auxiliary layer and an electron blocking layer may be further added between the hole transport layer 150 and the emission layer 160.

The hole transport auxiliary layer may contain a compound with good hole transport characteristics and adjust the hole injection characteristics by reducing an HOMO energy level difference between the hole transport layer 150 and the emission layer 160, thereby reducing the accumulation of holes at an interface between the hole transport auxiliary layer and the emission layer 160. Therefore, it is possible to reduce a quenching phenomenon that excitons are annihilated by polarons at the interface. Therefore, it is possible to reduce a degradation phenomenon of the element, thereby stabilizing the element and increasing efficiency and lifetime thereof.

The electron blocking layer may prevent the introduction of electrons into the hole transport layer by adjusting the movement of electrons and the recombination with holes, thereby increasing the efficiency and lifetime of the organic light emitting diode. A material forming the electron blocking layer may be selected from TCTA, tris [4-(diethylamino)phenyl]amine, N-(biphenyl-4-yl)-9,9-dimethyl-N-(4-(9-phenyl-9H-carbazol-3-yl)phenyl)-9H-fluoren-2-amine, TAPC, MTDATA, mCP, mCBP, CuPC, DNTPD, TDAPB, DCDPA, 2,8-bis(9-phenyl-9H-carbazol-3-yl)dibenzo[b,d]thiophene, and the like. In addition, the electron blocking layer may include an inorganic compound. The inorganic compound may be selected from halide compounds, such as LiF, NaF, KF, RbF, CsF, FrF, MgF₂, CaF₂, SrF₂, BaF₂, LiCI, NaCl, KCl, RbCI, CsCl, and FrCI, and oxides, such as Li₂O, Li₂O₂, Na₂O, K₂O, Rb₂O, Rb₂O₂, Cs₂O, Cs₂O₂, LiA₁O₂, LiBO₂, LiTaO₃, LiNbO₃, LiWO₄, Li₂CO, NaWO₄, KAlO₂, K₂SiO₃, B₂O₅, Al₂O₃, and SiO₂, but is not limited thereto.

The first electrode 110 may be an anode and may be made of or may include ITO, IZO, tin-oxide, or zinc-oxide, which is a conductive material with a relatively high work function value, but is not limited thereto.

The second electrode 120 may be a cathode and may include Al, Mg, Ca, Ag, or an alloy or combination thereof, which is a conductive material with a relatively low work function value, but is not limited thereto.

The hole injection layer 140 may be positioned between the first electrode 110 and the hole transport layer 150. The hole injection layer 140 may have a function of improving the interface characteristics between the first electrode 110 and the hole transport layer 150 and may be selected as a material with appropriate conductivity. The hole injection layer 140 may include a compound, such as MTDATA, CuPc, TCTA, HATCN, TDAPB, PEDOT/PSS, or N1,N1′-([1,1′-biphenyl]-4,4′-diyl)bis(N1,N4,N4-triphenylbenzene-1,4-diamine), but is not limited thereto. In some example embodiments, the hole injection layer 140 may include N1,N1′-([1,1′-biphenyl]-4,4′-diyl)bis(N1,N4,N4-triphenylbenzene-1,4-diamine).

The hole transport layer 150 may be positioned adjacent the emission layer between the first electrode 110 and the emission layer 160. The hole transport layer 150 may include a compound, such as TPD, NPB, CBP, N-(biphenyl-4-yl)-9,9-dimethyl-N-(4-9-phenyl-9H-carbazol-3-yl)phenyl)-9H-fluoren-2-amine, or N-biphenyl-4-yl)-N-4-9-phenyl-9H-carbazol-3-yl)phenyl) biphenyl)-4-amine, but is not limited thereto. In some example embodiments, the hole transport layer 150 may include NPB.

According to some example embodiments the present disclosure, the emission layer 160 may be formed by being doped with the organometallic compound represented by Chemical Formula 1 as the dopant 160′ to increase the luminous efficiency and the like of the hosts 160″ and 160′″ and the element, and the dopant 160′ may be used as a material that emits light of green or red and for example, used as a green phosphorescent material.

According to some example embodiments of the present disclosure, a doping concentration of the dopant 160′ may be adjusted in the range of 1 to 30 wt % based on the total weight of the two types of hosts 160″ and 160′″ and is not limited thereto, but for example, the doping concentration may be 2 to 20 wt %, for example, 3 to 15 wt %, for example, 5 to 10 wt %, for example, 3 to 8 wt %, for example, 2 to 7 wt %, for example, 5 to 7 wt %, and for example, 5 to 6 wt %.

According to some example embodiments of the present disclosure, a mixing ratio of the two types of hosts 160″ and 160′″ is not particularly limited, and the host 160″, which is the compound represented by Chemical Formula 2, may have the hole transport characteristics and the host 160″′, which is the compound represented by Chemical Formula 3, may have the electron transport characteristics. Therefore, when the two types of hosts are mixed, it is possible to increase the lifetime characteristics, and the mixing ratio of the two types of hosts may be adjusted appropriately. Therefore, the mixing ratio of the two hosts in which the compound represented by Chemical Formula 2 and the compound represented by Chemical Formula 3 are mixed is not particularly limited, and the ratio (based on the weight) of the compound represented by Chemical Formula 2 and the compound represented by Chemical Formula 3 may be, for example, in the range of 1:9 to 9:1, for example, 2:8, for example, 3:7, for example, 4:6, for example, 5:5, for example, 6:4, for example 7:3, and for example, 8:2.

In addition, the electron transport layer 170 and the electron injection layer 180 may be sequentially stacked between the emission layer 160 and the second electrode 120. A material of the electron transport layer 170 may exhibit high electron mobility, and electrons may be stably supplied to the emission layer through smooth electron transport.

For example, the material of the electron transport layer 170 is used in the art and may include, for example, a compound, such as Alq₃ (tris(8-hydroxyquinolino)aluminum), Liq (8-hydroxyquinolinolatolithium), PBD (2-(4-biphenylyl)-5-(4-tert-butylphenyl)-1,3,4-oxadiazole), TAZ (3-(4-biphenyl) 4-phenyl-5-tert-butylphenyl-1,2,4-triazole), spiro-PBD, BAlq (bis(2-methyl-8-quinolinolate)-4-(phenylphenolato)aluminium), SAlq, TPBi (2,2′,2-(1,3,5-benzinetriyl)-tris(1-phenyl-1-H-benzimidazole), oxadiazole, triazole, phenanthroline, benzoxazole, benzothiazole, or 2-(4-(9,10-di(naphthalen-2-yl) anthracen-2-yl)phenyl)-1-phenyl-1H-benzo[d]imidazole, but is not limited thereto. In some example embodiments, the material of the electron transport layer 170 may include 2-(4-(9,10-di(naphthalen)-2-yl) anthracen-2-yl)phenyl)-1-phenyl-1H-benzo[d]imidazole,.

The electron injection layer 180 serves to allow electrons to be smoothly injected, and a material of the electron injection layer is used in the art and may include, for example, Alq₃ (tris(8-hydroxyquinolino)aluminum), PBD, TAZ, spiro-PBD, BAlq, SAlq, or the like, but is not limited thereto. Alternatively, the electron injection layer 180 may be made of or may include a metal compound, and the metal compound may include, for example, Liq, LiF, NaF, KF, RbF, CsF, FrF, BeF₂, MgF₂, CaF₂, SrF₂, BaF₂, RaF₂, or the like, but is not limited thereto.

The organic light emitting diode according to some example embodiments of the present disclosure may be a white organic light emitting diode with a tandem structure. In the tandem organic light emitting diode according to some example embodiments of the present disclosure, a single light emitting stack (or a light emitting part) may be included in a structure in which two or more light emitting stacks (or light emitting parts) are connected by the charge generation layer CGL. The organic light emitting diode may include the first and second electrodes facing each other on the substrate and two or more light emitting stacks (light emitting parts) stacked between the first and second electrodes and including an emission layer so as to emit light in a specific wavelength band. The plurality of light emitting stacks (light emitting parts) may be applied to emit the same color or different colors. In addition, one light emitting stack (light emitting part) may include one or more emission layers, and the plurality of light emission layers may be light emission layers of the same color or different colors.

In this case, one or more of the emission layers included in the plurality of light emitting parts may include the organometallic compound represented by Chemical Formula 1 according to the present disclosure as a dopant material. The plurality of light emitting parts in the tandem structure may be connected to the charge generation layer CGL formed of or include an N-type charge generation layer and a P-type charge generation layer.

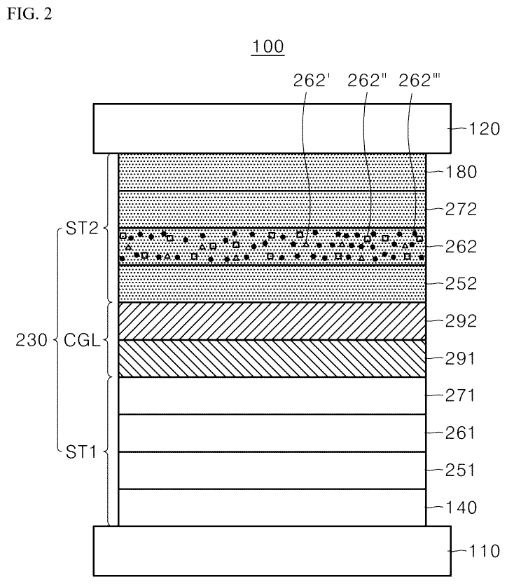

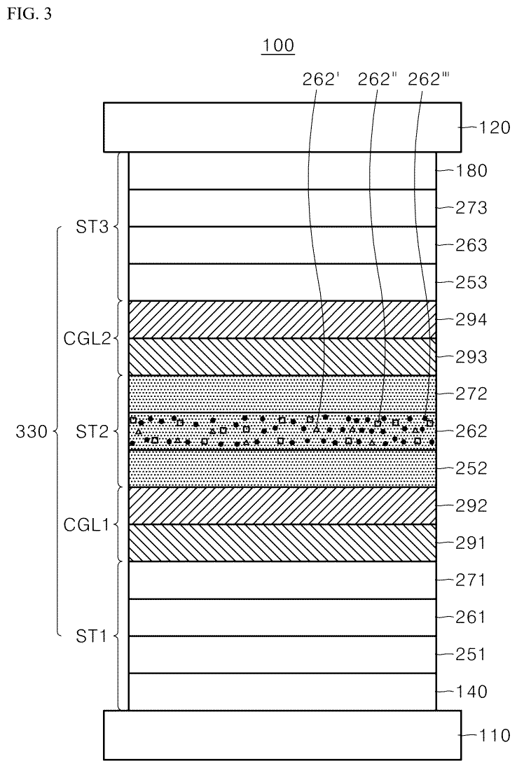

FIGS. 2 and 3, which are example embodiments of the present disclosure, are cross-sectional views schematically showing organic light emitting diodes in tandem structures having two light emitting parts and three light emitting parts, respectively.

As shown in FIG. 2, the organic light emitting diode 100 of the present disclosure includes the first electrode 110 and the second electrode 120 that face each other, and an intermediate layer 230 positioned between the first electrode 110 and the second electrode 120. The intermediate layer 230 includes a first light emitting part ST1 positioned between the first electrode 110 and the second electrode 120 and including a first emission layer 261, a second light emitting part ST2 positioned between the first light emitting part ST1 and the second electrode 120 and including a second emission layer 262, and the charge generation layer CGL positioned between the first and second light emitting parts ST1 and ST2. The charge generation layer CGL may include an N-type charge generation layer 291 and a P-type charge generation layer 292. One or more of the first emission layer 261 and the second emission layer 262 may include the organometallic compound represented by Chemical Formula 1 according to the present disclosure as a dopant 262′. For example, as shown in FIG. 2, the second emission layer 262 of the second light emitting part ST2 may contain the compound 262′ represented by Chemical Formula 1 as the dopant, a compound 262″ represented by Chemical Formula 2 as the hole transport type host, and a compound 262′″ represented by Chemical Formula 3 as an electron transport type host. Although not shown in FIG. 2, each of the first and second light emitting parts ST1 and ST2 may further include an additional emission layer in addition to the first emission layer 261 and the second emission layer 262. The contents described above in relation to the hole transport layer 150 of FIG. 1 may be applied to the first hole transport layer 251 and the second hole transport layer 252 of FIG. 2 in the same or similar manner. In addition, the contents described above in relation to the electron transport layer 170 of FIG. 1 may be applied to the first electron transport layer 271 and the second electron transport layer 272 of FIG. 2 in the same or similar manner.

As shown in FIG. 3, the organic light emitting diode 100 of the present disclosure includes the first electrode 110 and the second electrode 120 that face each other, and an intermediate layer 330 positioned between the first electrode 110 and the second electrode 120. The intermediate layer 330 includes the first light emitting part ST1 positioned between the first electrode 110 and the second electrode 120 and including the first emission layer 261, the second light emitting part ST2 including the second emission layer 262, a third light emitting part ST3 including a third emission layer 263, a first charge generation layer CGL1 positioned between the first and second light emitting parts ST1 and ST2, and a second charge generation layer CGL2 positioned between the second and third light emitting parts ST2 and ST3. The first and second charge generation layers CGL1 and CGL2 may include the N-type charge generation layers 291 and 293 and the P-type charge generation layers 292 and 294, respectively. One or more of the first emission layer 261, the second emission layer 262, and the third emission layer 263 may include the organometallic compound represented by Chemical Formula 1 according to the present disclosure as the dopant. For example, as shown in FIG. 3, the second emission layer 262 of the second light emitting part ST2 may contain the compound 262′ represented by Chemical Formula 1 as the dopant, the compound 262″ represented by Chemical Formula 2 as the hole transport type host, and the compound 262″″ represented by Chemical Formula 3 as the electron transport type host. Although not shown in FIG. 3, in addition to the first emission layer 261, the second emission layer 262, and the third emission layer 263, each of the first, second, and third light emitting parts ST1, ST2, and ST3 may be formed as a plurality of emission layers by including an additional emission layer. The contents described above in relation to the hole transport layer 150 of FIG. 1 may be applied to the first hole transport layer 251, the second hole transport layer 252, and the third hole transport layer 253 of FIG. 3 in the same or similar manner. In addition, the contents described above in relation to the electron transport layer 170 of FIG. 1 may be applied to the first electron transport layer 271, the second electron transport layer 272, and the third electrode transport layer 273 of FIG. 3 in the same or similar manner.

Furthermore, the organic light emitting diode according to some example embodiments of the present disclosure may include a tandem structure in which four or more light emitting parts and three or more charge generation layers are disposed between the first electrode and the second electrode.

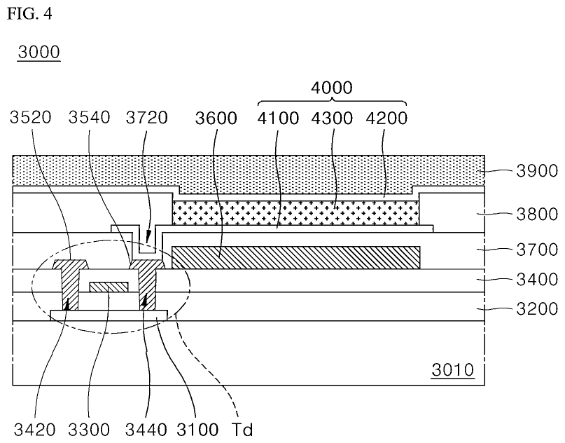

The organic light emitting diode according to some example embodiments of the present disclosure may be used in organic light emitting diode display devices and lighting devices using organic light emitting diodes. In one example embodiment, FIG. 4 is a cross-sectional view schematically showing an organic light emitting diode display device to which the organic light emitting diode according to an example embodiment of the present disclosure is applied.

As shown in FIG. 4, an organic light emitting diode display device 3000 may include a substrate 3010, an organic light emitting diode 4000, and an encapsulation film 3900 covering the organic light emitting diode 4000. On the substrate 3010, a driving thin film transistor Td, which is a driving element, and the organic light emitting diode 4000 connected to the driving thin film transistor Td are positioned.

Although not explicitly shown in FIG. 4, on the substrate 3010, a gate line and a data line that intersect each other to define a pixel area, a power line spaced apart from any one of the gate line and the data line and extending in parallel, a switching thin film transistor connected to the gate line and the data line, and a storage capacitor connected to the power line and one electrode of the switching thin film transistor are further formed.

The driving thin film transistor Td is connected to the switching thin film transistor and includes a semiconductor layer 3100, a gate electrode 3300, a source electrode 3520, and a drain electrode 3540.

The semiconductor layer 3100 may be formed on or disposed on the substrate 3010 and may be made of or may include an oxide semiconductor material or polycrystalline silicon. When the semiconductor layer 3100 is made of or includes the oxide semiconductor material, a light blocking pattern (not shown) may be formed under or disposed under the semiconductor layer 3100, and the light blocking pattern prevents light incident on the semiconductor layer 3100, thereby preventing the degradation of the semiconductor layer 3100 caused by the light. Alternatively, the semiconductor layer 3100 may be made of or may include polycrystalline silicon, and in this case, both edges of the semiconductor layer 3100 may be doped with impurities.

A gate insulating film 3200, which is made of or include an insulating material, is formed on or disposed on the entire surface of the substrate 3010 as well as the semiconductor layer 3100. The gate insulating film 3200 may be made of or may include an inorganic insulating material, such as silicon oxide or silicon nitride.

A gate electrode 3300 made of or including a conductive material, such as a metal, is formed above or disposed above the gate insulating film 3200 to correspond to the center of the semiconductor layer 3100. The gate electrode 3300 is connected to the switching thin film transistor.

An interlayer insulating film 3400, which is made of or includes an insulating material, is formed on or disposed on the entire surface of the substrate 3010 as well as the gate electrode 3300. The interlayer insulating film 3400 may be made of or may include an inorganic insulating material, such as silicon oxide or silicon nitride, or may be made of or may include an organic insulating material, such as benzocyclobutene or photo-acryl.

The interlayer insulating film 3400 has first and second semiconductor layer contact holes 3420 and 3440 that expose both sides of the semiconductor layer 3100. The first and second semiconductor layer contact holes 3420 and 3440 are positioned to be spaced apart from the gate electrode 3300 at both sides of the gate electrode 3300.

The source electrode 3520 and the drain electrode 3540, which are made of or include the conductive material, such as a metal, are formed on or disposed on the interlayer insulating film 3400. The source electrode 3520 and the drain electrode 3540 are positioned to be spaced apart from each other with respect to the gate electrode 3300 and are in contact with both sides of the semiconductor layer 3100 through the first and second semiconductor layer contact holes 3420 and 3440, respectively. The source electrode 3520 is connected to the power line (not shown).

The semiconductor layer 3100, the gate electrode 3300, the source electrode 3520, and the drain electrode 3540 form the driving thin film transistor Td, and the driving thin film transistor Td has a coplanar structure in which the gate electrode 3300, the source electrode 3520, and the drain electrode 3540 are positioned above the semiconductor layer 3100.

Alternatively, the driving thin film transistor Td may have an inverted staggered structure in which the gate electrode is positioned under the semiconductor layer and the source electrode and the drain electrode are positioned above the semiconductor layer. In this case, the semiconductor layer may be made of or may include amorphous silicon. The switching thin film transistor (not shown) may have substantially the same structure as the driving thin film transistor Td.

The organic light emitting diode display device 3000 may include a color filter 3600 that absorbs light generated by the organic light emitting diode 4000. For example, the color filter 3600 may absorb light of red (R), green (G), blue (B), and white (W). In this case, red, green, and blue color filter patterns that absorb light may be formed separately in each pixel area, and each of the color filter patterns may be disposed to overlap each intermediate layer 4300 of the organic light emitting diode 4000 that emits light in a wavelength band to be absorbed. By adopting the color filter 3600, the organic light emitting diode display device 3000 may implement full-color.

For example, when the organic light emitting diode display device 3000 is a bottom-emission type, the color filter 3600 that absorbs light may be positioned above the interlayer insulating film 3400 corresponding to the organic light emitting diode 4000. In an example embodiment, when the organic light emitting diode display device 3000 is a top-emission type, the color filter may be positioned above the organic light emitting diode 4000, that is, above a second electrode 4200. For example, the color filter 3600 may be formed to have a thickness of 2 to 5 μm.

A planarization layer 3700 with a drain contact hole 3720 that exposes the drain electrode 3540 of the driving thin film transistor Td is formed to cover the driving thin film transistor Td.

On the planarization layer 3700, a first electrode 4100 connected to the drain electrode 3540 of the driving thin film transistor Td through the drain contact hole 3720 is formed separately in each pixel area.

The first electrode 4100 may be an anode and may be made of or may include a conductive material with a relatively high work function value. For example, the first electrode 4100 may be made of or may include a transparent conductive material, such as ITO, IZO, or ZnO.

When the organic light emitting diode display device 3000 is a top-emission type, a reflective electrode or a reflective layer may be further formed under or disposed under the first electrode 4100. For example, the reflective electrode or the reflective layer may be made of or may include any one of aluminum (Al), silver (Ag), nickel (Ni), or an aluminum-palladium-copper (APC) alloy.

A bank layer 3800 covering an edge of the first electrode 4100 is formed on or disposed on the planarization layer 3700. The bank layer 3800 exposes the center of the first electrode 4100 corresponding to the pixel area.

The intermediate layer 4300 is formed on or disposed on the first electrode 4100, and optionally, the organic light emitting diode 4000 may have a tandem structure, and regarding the tandem structure, reference is made to FIGS. 2 to 4 showing the example embodiment of the present disclosure and the above description thereof.

The second electrode 4200 is formed above or disposed above the substrate 3010 on which the intermediate layer 4300 is formed or disposed. The second electrode 4200 may be positioned on the entire surface of the display area and may be made of or may include a conductive material with a relatively low work function value to be used as a cathode. For example, the second electrode 4200 may be made of or may include any one of aluminum (Al), magnesium (Mg), and aluminum-magnesium alloy (Al—Mg).

The first electrode 4100, the intermediate layer 4300, and the second electrode 4200 form the organic light emitting diode 4000.

On the second electrode 4200, the encapsulation film 3900 is formed to prevent the permeation of external moisture into the organic light emitting diode 4000. Although not explicitly shown in FIG. 4, the encapsulation film 3900 may have a triple-layer structure in which a first inorganic layer, an intermediate layer, and an inorganic layer are sequentially stacked, but is not limited thereto.

Hereinafter, examples of the present disclosure will be described. However, the following examples are only examples of the present disclosure, and the present disclosure is not limited thereto.

### Example 1

A glass substrate coated with a thin film of ITO in a thickness of 1,000 Å was washed, then ultrasonic cleaned with a solvent, such as isopropyl alcohol, acetone, and methanol, and dried.

After HI-1 as a hole injection material was thermally deposited in vacuum in a thickness of 100 nm above the provided ITO transparent electrode, HT-1 as a hole transport material was thermally deposited in vacuum to a thickness of 350 nm. Then, in an emission layer, GD1 as a dopant and a mixture of GHH1 and GEH1 as hosts (GHH1: GEH1=7:3, based on the weight) were used, a doping concentration of the dopant was 10%, and the thickness of the emission layer was 400 nm. Subsequently, after ET-1 and Liq compounds as materials for an electron transport layer and an electron injection layer, respectively, were thermally deposited in vacuum, aluminum was deposited to a thickness of 100 nm to form a cathode, and thus an organic light emitting diode was manufactured.

The materials used in Example 1 are as follows.

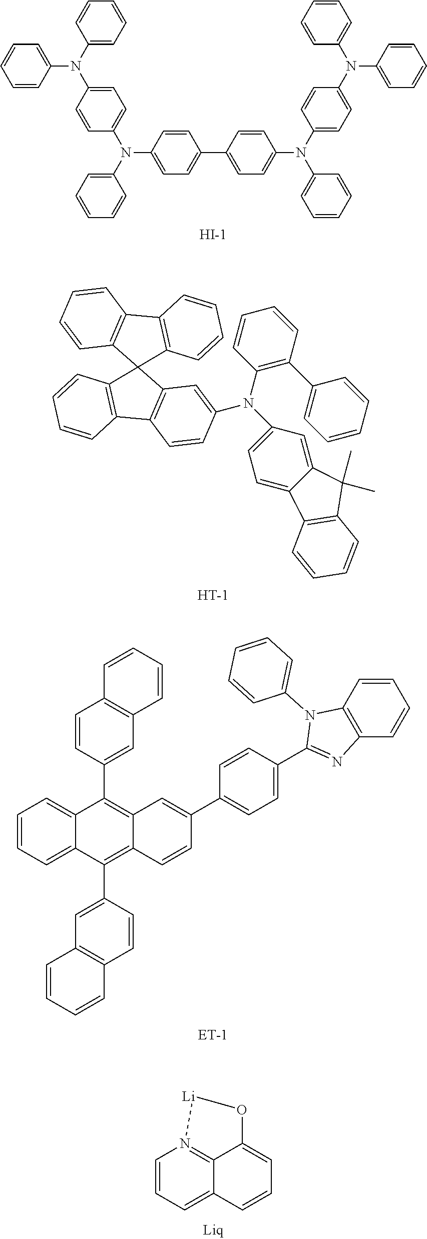

In the above materials, HI-1 is NPNPB, and ET-1 is ZADN.

### Comparative Examples 1 to 5 and Examples 2 to 200

Organic light emitting diodes of Comparative Examples 1 to 5 and Examples 2 to 100 were manufactured in the same manner as Example 1, except that the dopant materials and host materials shown in Tables 1 to 15 below were used. Comparative Examples 1 to 5 each used “CBP” with a structure below as the host of the emission layer.

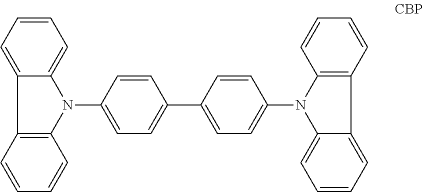 [SMILES: c1ccc2c(c1)c1ccccc1n2-c1ccc(-c2ccc(-n3c4ccccc4c4ccccc43)cc2)cc1]

### Experimental Example

The organic light emitting diodes manufactured in Examples 1 to 200 and Comparative Examples 1 to 5 were each connected to an external power source, and element characteristics were evaluated at room temperature using a current source and a photometer.

Driving voltage (V), external quantum efficiency (EQE), and lifetime (LT95) characteristics were measured with a current of 10 mA/cm², and measured values of Examples 1 to 200 were calculated as values (percentage, %) relative to the indicated comparative example among Comparative Examples 1 to 5, and the results are shown in Tables 1 to 15 below.

LT95 lifetime indicates the time it takes for an organic light emitting diode to lose 5% of an initial brightness. LT95 is the most difficult element characteristic specification to meet, and whether an image burn-in phenomenon occurs in an organic light emitting diode is determined using LT95.

TABLE 1

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD1 | CBP | | 4.30 | 100 | 100 |
| Example 1 | | | | | | |
| Example 1 | GD1 | GHH1 | GEH1 | 4.29 | 127 | 132 |
| Example 2 | GD1 | GHH1 | GEH2 | 4.19 | 125 | 131 |
| Example 3 | GD1 | GHH1 | GEH3 | 4.28 | 118 | 128 |
| Example 4 | GD1 | GHH1 | GEH4 | 4.17 | 121 | 126 |
| Example 5 | GD1 | GHH1 | GEH5 | 4.18 | 125 | 127 |
| Example 6 | GD1 | GHH1 | GEH6 | 4.25 | 125 | 128 |
| Example 7 | GD1 | GHH1 | GEH7 | 4.25 | 114 | 131 |
| Example 8 | GD1 | GHH1 | GEH8 | 4.25 | 116 | 131 |
| Example 9 | GD1 | GHH1 | GEH9 | 4.26 | 119 | 131 |
| Example 10 | GD1 | GHH1 | GEH10 | 4.21 | 119 | 128 |
| Example 11 | GD1 | GHH2 | GEH1 | 4.21 | 137 | 142 |
| Example 12 | GD1 | GHH2 | GEH2 | 4.19 | 130 | 143 |
| Example 13 | GD1 | GHH2 | GEH3 | 4.26 | 125 | 136 |
| Example 14 | GD1 | GHH2 | GEH4 | 4.19 | 129 | 134 |
| Example 15 | GD1 | GHH2 | GEH5 | 4.25 | 129 | 135 |

TABLE 2

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD1 | CBP | | 4.30 | 100 | 100 |
| Example 1 | | | | | | |
| Example 16 | GD1 | GHH2 | GEH6 | 4.22 | 132 | 135 |
| Example 17 | GD1 | GHH2 | GEH7 | 4.27 | 121 | 139 |
| Example 18 | GD1 | GHH2 | GEH8 | 4.26 | 119 | 140 |
| Example 19 | GD1 | GHH2 | GEH9 | 4.21 | 125 | 137 |
| Example 20 | GD1 | GHH2 | GEH10 | 4.25 | 124 | 134 |
| Example 21 | GD1 | GHH3 | GEH1 | 4.24 | 132 | 139 |
| Example 22 | GD1 | GHH3 | GEH2 | 4.20 | 132 | 140 |
| Example 23 | GD1 | GHH3 | GEH3 | 4.24 | 124 | 136 |
| Example 24 | GD1 | GHH3 | GEH4 | 4.24 | 126 | 133 |
| Example 25 | GD1 | GHH3 | GEH5 | 4.22 | 129 | 136 |
| Example 26 | GD1 | GHH3 | GEH6 | 4.23 | 130 | 135 |
| Example 27 | GD1 | GHH3 | GEH7 | 4.25 | 120 | 142 |
| Example 28 | GD1 | GHH3 | GEH8 | 4.18 | 117 | 139 |
| Example 29 | GD1 | GHH3 | GEH9 | 4.30 | 121 | 140 |
| Example 30 | GD1 | GHH3 | GEH10 | 4.29 | 124 | 137 |

TABLE 3

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD1 | CBP | | 4.30 | 100 | 100 |
| Example 1 | | | | | | |
| Example 31 | GD1 | GHH4 | GEH1 | 4.20 | 129 | 139 |
| Example 32 | GD1 | GHH4 | GEH2 | 4.28 | 128 | 139 |
| Example 33 | GD1 | GHH4 | GEH3 | 4.18 | 120 | 138 |
| Example 34 | GD1 | GHH4 | GEH4 | 4.20 | 122 | 133 |
| Example 35 | GD1 | GHH4 | GEH5 | 4.25 | 126 | 135 |
| Example 36 | GD1 | GHH4 | GEH6 | 4.20 | 128 | 132 |
| Example 37 | GD1 | GHH4 | GEH7 | 4.35 | 117 | 140 |
| Example 38 | GD1 | GHH4 | GEH8 | 4.18 | 115 | 134 |
| Example 39 | GD1 | GHH4 | GEH9 | 4.13 | 119 | 135 |
| Example 40 | GD1 | GHH4 | GEH10 | 4.23 | 122 | 135 |
| Example 41 | GD1 | GHH5 | GEH1 | 4.27 | 129 | 139 |
| Example 42 | GD1 | GHH5 | GEH2 | 4.29 | 126 | 137 |
| Example 43 | GD1 | GHH5 | GEH3 | 4.19 | 118 | 139 |
| Example 44 | GD1 | GHH5 | GEH4 | 4.21 | 122 | 132 |
| Example 45 | GD1 | GHH5 | GEH5 | 4.24 | 124 | 135 |

TABLE 4

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD1 | CBP | | 4.30 | 100 | 100 |
| Example 1 | | | | | | |
| Example 46 | GD1 | GHH5 | GEH6 | 4.22 | 124 | 133 |
| Example 47 | GD1 | GHH5 | GEH7 | 4.24 | 117 | 137 |
| Example 48 | GD1 | GHH5 | GEH8 | 4.29 | 112 | 138 |
| Example 49 | GD1 | GHH5 | GEH9 | 4.30 | 115 | 136 |
| Example 50 | GD1 | GHH5 | GEH10 | 4.18 | 120 | 135 |
| Example 51 | GD1 | GHH6 | GEH1 | 4.20 | 119 | 139 |
| Example 52 | GD1 | GHH6 | GEH2 | 4.22 | 122 | 138 |
| Example 53 | GD1 | GHH6 | GEH3 | 4.15 | 113 | 133 |
| Example 54 | GD1 | GHH6 | GEH4 | 4.24 | 118 | 132 |
| Example 55 | GD1 | GHH6 | GEH5 | 4.25 | 118 | 133 |
| Example 56 | GD1 | GHH6 | GEH6 | 4.22 | 121 | 133 |
| Example 57 | GD1 | GHH6 | GEH7 | 4.34 | 110 | 139 |
| Example 58 | GD1 | GHH6 | GEH8 | 4.28 | 110 | 135 |
| Example 59 | GD1 | GHH6 | GEH9 | 4.31 | 111 | 134 |
| Example 60 | GD1 | GHH6 | GEH10 | 4.26 | 114 | 130 |

TABLE 5

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD1 | CBP | | 4.30 | 100 | 100 |
| Example 1 | | | | | | |
| Example 61 | GD1 | GHH7 | GEH1 | 4.26 | 115 | 134 |
| Example 62 | GD1 | GHH7 | GEH2 | 4.18 | 118 | 134 |
| Example 63 | GD1 | GHH7 | GEH3 | 4.25 | 109 | 133 |
| Example 64 | GD1 | GHH7 | GEH4 | 4.25 | 113 | 127 |
| Example 65 | GD1 | GHH7 | GEH5 | 4.15 | 113 | 130 |
| Example 66 | GD1 | GHH7 | GEH6 | 4.22 | 114 | 130 |
| Example 67 | GD1 | GHH7 | GEH7 | 4.28 | 104 | 134 |
| Example 68 | GD1 | GHH7 | GEH8 | 4.22 | 104 | 133 |
| Example 69 | GD1 | GHH7 | GEH9 | 4.24 | 108 | 131 |
| Example 70 | GD1 | GHH7 | GEH10 | 4.22 | 110 | 127 |
| Example 71 | GD1 | GHH8 | GEH1 | 4.16 | 120 | 136 |
| Example 72 | GD1 | GHH8 | GEH2 | 4.22 | 117 | 136 |
| Example 73 | GD1 | GHH8 | GEH3 | 4.23 | 111 | 135 |
| Example 74 | GD1 | GHH8 | GEH4 | 4.29 | 113 | 130 |
| Example 75 | GD1 | GHH8 | GEH5 | 4.28 | 115 | 136 |

TABLE 6

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD1 | CBP | | 4.30 | 100 | 100 |
| Example 1 | | | | | | |
| Example 76 | GD1 | GHH8 | GEH6 | 4.22 | 116 | 134 |
| Example 77 | GD1 | GHH8 | GEH7 | 4.22 | 111 | 138 |
| Example 78 | GD1 | GHH8 | GEH8 | 4.25 | 107 | 136 |
| Example 79 | GD1 | GHH8 | GEH9 | 4.27 | 110 | 134 |
| Example 80 | GD1 | GHH8 | GEH10 | 4.30 | 111 | 133 |
| Example 81 | GD1 | GHH9 | GEH1 | 4.28 | 126 | 133 |
| Example 82 | GD1 | GHH9 | GEH2 | 4.26 | 121 | 129 |
| Example 83 | GD1 | GHH9 | GEH3 | 4.20 | 114 | 131 |
| Example 84 | GD1 | GHH9 | GEH4 | 4.12 | 118 | 126 |
| Example 85 | GD1 | GHH9 | GEH5 | 4.26 | 120 | 129 |
| Example 86 | GD1 | GHH9 | GEH6 | 4.23 | 122 | 126 |
| Example 87 | GD1 | GHH9 | GEH7 | 4.34 | 113 | 131 |
| Example 88 | GD1 | GHH9 | GEH8 | 4.16 | 112 | 131 |
| Example 89 | GD1 | GHH9 | GEH9 | 4.27 | 113 | 129 |
| Example 90 | GD1 | GHH9 | GEH10 | 4.27 | 115 | 126 |

TABLE 7

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD1 | CBP | | 4.30 | 100 | 100 |
| Example 1 | | | | | | |
| Example 91 | GD1 | GHH10 | GEH1 | 4.28 | 115 | 129 |
| Example 92 | GD1 | GHH10 | GEH2 | 4.25 | 115 | 127 |
| Example 93 | GD1 | GHH10 | GEH3 | 4.26 | 108 | 128 |
| Example 94 | GD1 | GHH10 | GEH4 | 4.34 | 114 | 124 |
| Example 95 | GD1 | GHH10 | GEH5 | 4.34 | 114 | 124 |
| Example 94 | GD1 | GHH10 | GEH6 | 4.28 | 116 | 125 |
| Example 97 | GD1 | GHH10 | GEH7 | 4.30 | 109 | 131 |
| Example 98 | GD1 | GHH10 | GEH8 | 4.22 | 105 | 128 |
| Example 99 | GD1 | GHH10 | GEH9 | 4.16 | 107 | 128 |
| Example 100 | GD1 | GHH10 | GEH10 | 4.35 | 110 | 125 |

TABLE 8

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD2 | CBP | | 4.31 | 100 | 100 |
| Example 2 | | | | | | |
| Example 101 | GD2 | GHH1 | GEH1 | 4.20 | 128 | 133 |
| Example 102 | GD2 | GHH1 | GEH2 | 4.21 | 126 | 129 |
| Example 103 | GD2 | GHH1 | GEH3 | 4.23 | 121 | 129 |
| Example 104 | GD2 | GHH1 | GEH4 | 4.28 | 123 | 125 |
| Example 105 | GD2 | GHH1 | GEH5 | 4.23 | 124 | 128 |
| Example 106 | GD2 | GHH2 | GEH1 | 4.27 | 134 | 139 |
| Example 107 | GD2 | GHH2 | GEH2 | 4.27 | 130 | 137 |
| Example 108 | GD2 | GHH2 | GEH3 | 4.19 | 126 | 137 |
| Example 109 | GD2 | GHH2 | GEH4 | 4.23 | 128 | 134 |
| Example 110 | GD2 | GHH2 | GEH5 | 4.23 | 132 | 138 |
| Example 111 | GD2 | GHH3 | GEH1 | 4.29 | 132 | 141 |
| Example 112 | GD2 | GHH3 | GEH2 | 4.24 | 131 | 140 |
| Example 113 | GD2 | GHH3 | GEH3 | 4.26 | 125 | 136 |
| Example 114 | GD2 | GHH3 | GEH4 | 4.21 | 129 | 135 |
| Example 115 | GD2 | GHH3 | GEH5 | 4.24 | 128 | 139 |

TABLE 9

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD2 | CBP | | 4.31 | 100 | 100 |
| Example 2 | | | | | | |
| Example 116 | GD2 | GHH4 | GEH1 | 4.24 | 130 | 138 |
| Example 117 | GD2 | GHH4 | GEH2 | 4.25 | 127 | 137 |
| Example 118 | GD2 | GHH4 | GEH3 | 4.26 | 121 | 137 |
| Example 119 | GD2 | GHH4 | GEH4 | 4.24 | 124 | 131 |
| Example 120 | GD2 | GHH4 | GEH5 | 4.17 | 126 | 134 |
| Example 121 | GD2 | GHH5 | GEH1 | 4.23 | 127 | 141 |
| Example 122 | GD2 | GHH5 | GEH2 | 4.27 | 127 | 137 |
| Example 123 | GD2 | GHH5 | GEH3 | 4.24 | 117 | 136 |
| Example 124 | GD2 | GHH5 | GEH4 | 4.22 | 122 | 132 |
| Example 125 | GD2 | GHH5 | GEH5 | 4.24 | 122 | 134 |

TABLE 10

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD3 | CBP | | 4.32 | 100 | 100 |
| Example 3 | | | | | | |
| Example 126 | GD3 | GHH1 | GEH1 | 4.23 | 127 | 133 |
| Example 127 | GD3 | GHH1 | GEH2 | 4.21 | 123 | 131 |
| Example 128 | GD3 | GHH1 | GEH3 | 4.15 | 120 | 127 |
| Example 129 | GD3 | GHH1 | GEH4 | 4.18 | 123 | 127 |
| Example 130 | GD3 | GHH1 | GEH5 | 4.15 | 123 | 129 |
| Example 131 | GD3 | GHH2 | GEH1 | 4.17 | 134 | 140 |
| Example 132 | GD3 | GHH2 | GEH2 | 4.25 | 135 | 140 |
| Example 133 | GD3 | GHH2 | GEH3 | 4.24 | 125 | 140 |
| Example 134 | GD3 | GHH2 | GEH4 | 4.20 | 127 | 133 |
| Example 135 | GD3 | GHH2 | GEH5 | 4.15 | 131 | 134 |
| Example 136 | GD3 | GHH3 | GEH1 | 4.17 | 133 | 139 |
| Example 137 | GD3 | GHH3 | GEH2 | 4.17 | 132 | 142 |
| Example 138 | GD3 | GHH3 | GEH3 | 4.21 | 124 | 140 |
| Example 139 | GD3 | GHH3 | GEH4 | 4.21 | 127 | 134 |
| Example 140 | GD3 | GHH3 | GEH5 | 4.23 | 128 | 138 |

TABLE 11

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD3 | CBP | | 4.32 | 100 | 100 |
| Example 3 | | | | | | |
| Example 141 | GD3 | GHH4 | GEH1 | 4.16 | 129 | 135 |
| Example 142 | GD3 | GHH4 | GEH2 | 4.15 | 129 | 139 |
| Example 143 | GD3 | GHH4 | GEH3 | 4.18 | 120 | 134 |
| Example 144 | GD3 | GHH4 | GEH4 | 4.23 | 124 | 130 |
| Example 145 | GD3 | GHH4 | GEH5 | 4.19 | 125 | 134 |
| Example 146 | GD3 | GHH5 | GEH1 | 4.22 | 127 | 141 |
| Example 147 | GD3 | GHH5 | GEH2 | 4.17 | 125 | 140 |
| Example 148 | GD3 | GHH5 | GEH3 | 4.29 | 117 | 136 |
| Example 149 | GD3 | GHH5 | GEH4 | 4.18 | 120 | 132 |
| Example 150 | GD3 | GHH5 | GEH5 | 4.32 | 125 | 135 |

TABLE 12

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD4 | CBP | | 4.32 | 100 | 100 |
| Example 4 | | | | | | |
| Example 151 | GD4 | GHH1 | GEH1 | 4.19 | 128 | 134 |
| Example 152 | GD4 | GHH1 | GEH2 | 4.20 | 126 | 133 |
| Example 153 | GD4 | GHH1 | GEH3 | 4.21 | 120 | 126 |
| Example 154 | GD4 | GHH1 | GEH4 | 4.16 | 122 | 127 |
| Example 155 | GD4 | GHH1 | GEH5 | 4.26 | 124 | 130 |
| Example 156 | GD4 | GHH2 | GEH1 | 4.22 | 134 | 136 |
| Example 157 | GD4 | GHH2 | GEH2 | 4.20 | 131 | 139 |
| Example 158 | GD4 | GHH2 | GEH3 | 4.25 | 126 | 139 |
| Example 159 | GD4 | GHH2 | GEH4 | 4.21 | 129 | 135 |
| Example 160 | GD4 | GHH2 | GEH5 | 4.26 | 132 | 137 |
| Example 161 | GD4 | GHH3 | GEH1 | 4.23 | 132 | 138 |
| Example 162 | GD4 | GHH3 | GEH2 | 4.19 | 132 | 142 |
| Example 163 | GD4 | GHH3 | GEH3 | 4.16 | 121 | 138 |
| Example 164 | GD4 | GHH3 | GEH4 | 4.15 | 125 | 133 |
| Example 165 | GD4 | GHH3 | GEH5 | 4.11 | 129 | 137 |

TABLE 13

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD4 | CBP | | 4.32 | 100 | 100 |
| Example 4 | | | | | | |
| Example 166 | GD4 | GHH4 | GEH1 | 4.15 | 130 | 139 |
| Example 167 | GD4 | GHH4 | GEH2 | 4.20 | 126 | 136 |
| Example 168 | GD4 | GHH4 | GEH3 | 4.25 | 118 | 136 |
| Example 169 | GD4 | GHH4 | GEH4 | 4.16 | 125 | 132 |
| Example 170 | GD4 | GHH4 | GEH5 | 4.14 | 125 | 136 |
| Example 171 | GD4 | GHH5 | GEH1 | 4.17 | 128 | 140 |
| Example 172 | GD4 | GHH5 | GEH2 | 4.20 | 124 | 140 |
| Example 173 | GD4 | GHH5 | GEH3 | 4.25 | 118 | 135 |
| Example 174 | GD4 | GHH5 | GEH4 | 4.30 | 121 | 134 |
| Example 175 | GD4 | GHH5 | GEH5 | 4.25 | 123 | 135 |

TABLE 14

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD5 | CBP | | 4.32 | 100 | 100 |
| Example 5 | | | | | | |
| Example 176 | GD5 | GHH1 | GEH1 | 4.21 | 128 | 132 |
| Example 177 | GD5 | GHH1 | GEH2 | 4.19 | 127 | 133 |
| Example 178 | GD5 | GHH1 | GEH3 | 4.20 | 120 | 130 |
| Example 179 | GD5 | GHH1 | GEH4 | 4.27 | 120 | 125 |
| Example 180 | GD5 | GHH1 | GEH5 | 4.17 | 122 | 128 |
| Example 181 | GD5 | GHH2 | GEH1 | 4.22 | 134 | 142 |
| Example 182 | GD5 | GHH2 | GEH2 | 4.18 | 132 | 141 |
| Example 183 | GD5 | GHH2 | GEH3 | 4.21 | 124 | 138 |
| Example 184 | GD5 | GHH2 | GEH4 | 4.17 | 129 | 134 |
| Example 185 | GD5 | GHH2 | GEH5 | 4.20 | 130 | 138 |
| Example 186 | GD5 | GHH3 | GEH1 | 4.20 | 131 | 141 |
| Example 187 | GD5 | GHH3 | GEH2 | 4.18 | 130 | 141 |
| Example 188 | GD5 | GHH3 | GEH3 | 4.18 | 123 | 136 |
| Example 189 | GD5 | GHH3 | GEH4 | 4.18 | 125 | 136 |
| Example 190 | GD5 | GHH3 | GEH5 | 4.33 | 126 | 138 |

TABLE 15

| | | | | | EQE | LT95 |
|---|---|---|---|---|---|---|
| | | | | driving | (%, | (%, |
| | emission layer | | | voltage | relative | relative |
| | dopant | host | | (V) | value) | value) |
| Comparative | GD5 | CBP | | 4.32 | 100 | 100 |
| Example 5 | | | | | | |
| Example 191 | GD5 | GHH4 | GEH1 | 4.20 | 130 | 137 |
| Example 192 | GD5 | GHH4 | GEH2 | 4.18 | 131 | 137 |
| Example 193 | GD5 | GHH4 | GEH3 | 4.12 | 119 | 135 |
| Example 194 | GD5 | GHH4 | GEH4 | 4.18 | 123 | 132 |
| Example 195 | GD5 | GHH4 | GEH5 | 4.20 | 125 | 134 |
| Example 196 | GD5 | GHH5 | GEH1 | 4.27 | 127 | 141 |
| Example 197 | GD5 | GHH5 | GEH2 | 4.21 | 127 | 137 |
| Example 198 | GD5 | GHH5 | GEH3 | 4.21 | 119 | 135 |
| Example 199 | GD5 | GHH5 | GEH4 | 4.22 | 122 | 133 |
| Example 200 | GD5 | GHH5 | GEH5 | 4.17 | 123 | 135 |

As can be seen from the results of Tables 1 to 15, the organic light emitting diodes in Examples 1 to 200 that included (i) the organometallic compound satisfying the structure represented by Chemical Formula 1 of the present disclosure used as the dopant of the emission layer, and (ii) the mixture of the compound represented by Chemical Formula 2 and the compound represented by Chemical Formula 3 as the hosts, had low driving voltages and increased external quantum efficiency (EQE) and lifetime (LT95) compared to the organic light emitting diodes of Comparative Examples 1 to 5 that used a single material as the host.

In the organic light emitting diode according to some example embodiments of the present disclosure, by including the organometallic compound represented by Chemical Formula 1 as the phosphorous dopant and a mixture of a compound represented by Chemical Formula 2 and a compound represented by Chemical Formula 3 as the phosphorous host, it may be possible to improve the efficiency and lifetime characteristics and secure the low-power characteristics by decreasing the driving voltage.

The effects obtainable from the present disclosure are not limited to the above-described effects, and other effects that are not mentioned will be clearly understood by those skilled in the art to which the present disclosure pertains from the following description.

Although embodiments of the present disclosure have been described with reference to the accompanying drawings, the present disclosure is not limited to the above embodiments and may be modified in a various manner within the scope of the technical spirit of the present disclosure. Accordingly, the embodiments as disclosed in the present disclosure are intended to describe rather than limit the technical idea of the present disclosure, and the scope of the technical idea of the present disclosure is not limited by these embodiments. Therefore, it should be appreciated that the embodiments as described above is not restrictive but illustrative in all aspects.

### DESCRIPTION OF REFERENCE NUMERALS

100, 4000: organic light emitting diode
110, 4100: first electrode
120, 4200: second electrode
130, 230, 330, 4300: intermediate layer
140: hole injection layer
150: hole transport layer, 251: first hole transport layer, 252: second hole transport layer, 253: third hole transport layer
160: emission layer, 261: first emission layer, 262: second emission layer, 263: third emission layer
160′, 262′: dopant
160″, 262″: hole transport type host
160″′, 262′″: electron transport type host
170: electron transport layer, 271: first electron transport layer, 272: second electron transport layer, 273: third electron transport layer
180: electron injection layer
3000: organic light emitting diode display device
3010: substrate
3100: semiconductor layer
3200: gate insulating film
3300: gate electrode
3400: interlayer insulating film
3420, 3440: first and second semiconductor contact holes
3520: source electrode
3540: drain electrode
3600: color filter
3700: planarization layer
3720: drain contact hole
3800: bank layer
3900: encapsulation film

What is claimed is:

1. An organic light emitting diode, comprising:
a first electrode;
a second electrode facing the first electrode; and
an intermediate layer disposed between the first electrode and the second electrode, the intermediate layer including an emission layer including:
a dopant material including an organometallic compound represented by Chemical Formula 1, and
a host material including a mixture including a compound represented by Chemical Formula 2 and a compound represented by Chemical Formula 3: 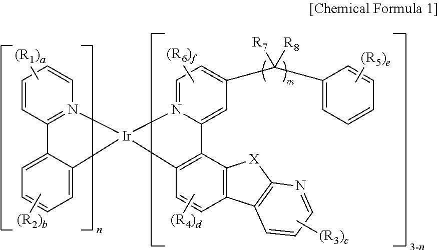
wherein in Chemical Formula 1,
X is one selected from oxygen (O), sulfur(S), and selenium (Se),
each R₁ to R₆ is independently one selected from deuterium, halogen, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a a carboxylic acid group, a nitrile group, an isonitrile group, a sulfanyl group, and a phosphino group, and combinations thereof, where the alkyl group, the cycloalkyl group, the heteroalkyl group, the arylalkyl group, the alkoxy group, the aryloxy group, the amino group, the silyl group, the alkenyl group, the cycloalkenyl group, the heteroalkenyl group, the alkynyl group, the aryl group, the heteroaryl group, the acyl group, and the phosphino group are optionally partially deuterated or optionally entirely deuterated,
each R₇ and R₈ is independently one selected from hydrogen, deuterium, a C1-C6 linear alkyl group, a C3-C6 branched alkyl group, and a C3-C6 cycloalkyl group, where the C1-C6 linear alkyl group, the C3-C6 branched alkyl group, and the C3-C6 cycloalkyl group are optionally partially deuterated or optionally entirely deuterated,
a and b are, each independently, an integer from 0 to 4, and when a and b are each independently an integer from 2 to 4, a plurality of R₁ or a plurality of R₂ are the same or different from each other,
c and f are, each independently, an integer from 0 to 3, and when c and f are each independently an integer of 2 or 3, a plurality of R₃ or a plurality of R₆ are the same or different from each other,
d is an integer from 0 to 2, and when d is an integer of 2, a plurality of R₄ are the same or different from each other,
e is an integer from 0 to 5, and when e is an integer from 2 to 5, a plurality of R₅ are the same or different from each other, and
m is an integer selected from 1 to 8, and n is an integer selected from 0 to 2, 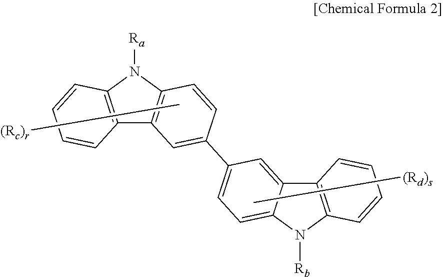
in Chemical Formula 2,
Rₐ and R_{b} are each independently one selected from an aryl group and a heteroaryl group, where the aryl group and the heteroaryl group are optionally substituted with one or more substituents selected from an alkyl group, an aryl group, a nitrile group, an alkylsilyl group, and an arylsilyl group, and Rₐ and R_{b} are optionally partially deuterated or optionally entirely deuterated,
each R_{c} and Rₐ is independently one selected from hydrogen, deuterium, halogen, nitrile group, and alkyl group, and R_{c} and Rₐ are optionally partially deuterated or optionally entirely deuterated, and
r and s each independently denotes an integer selected from 0 to 7, and when r is an integer selected from 2 to 7, each R_{c} is the same as or different from each other, and when s is an integer selected from 2 to 7, each Rₐ is the same as or different from each other, 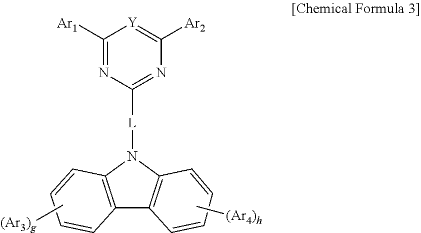
in Chemical Formula 3,
L is one selected from a single bond, a C6-C50 arylene group, and a C5-C50 heteroarylene group,
Y is N or CH,
each Ar₁, Ar₂, Ar₃, and Ar₄ is independently one selected from hydrogen, deuterium, halogen, a C1-C30 alkyl group, a C6-C50 aryl group, a C3-C50 heteroaryl group, and a C3-C30 cycloalkyl group,
g and h are each independently an integer selected from 1 to 4,
when g is an integer selected from 2 to 4, any two adjacent Ar₃ are optionally bonded to form a fused ring structure including a C6-C30 monocyclic or polycyclic aromatic group, or a C3-C30 heteroaromatic group, and one or more of hydrogens attached to the fused ring structure are optionally substituted by a substituent selected from deuterium, a C1-C10 alkyl group, a C6-C20 aryl group, and a C3-C20 heteroaryl group, and
when h is an integer selected from 2 to 4, any two adjacent Ar₄ are optionally bonded to form a fused ring structure including a C6-C30 monocyclic or polycyclic aromatic group, or a C3-C30 heteroaromatic group, and one or more of hydrogens attached to the fused ring structure are optionally substituted by a substituent selected from deuterium, a C1-C10 alkyl group, a C6-C20 aryl group, and a C3-C20 heteroaryl group.

2. The organic light emitting diode of claim 1, wherein n in Chemical Formula 1 is 2.

3. The organic light emitting diode of claim 1, wherein X in Chemical Formula 1 is oxygen (O).

4. The organic light emitting diode of claim 1, wherein m is an integer of 1 to 3.

5. The organic light emitting diode of claim 1, wherein the organometallic compound represented by Chemical Formula 1 includes one of Compounds GD1 to GD20:

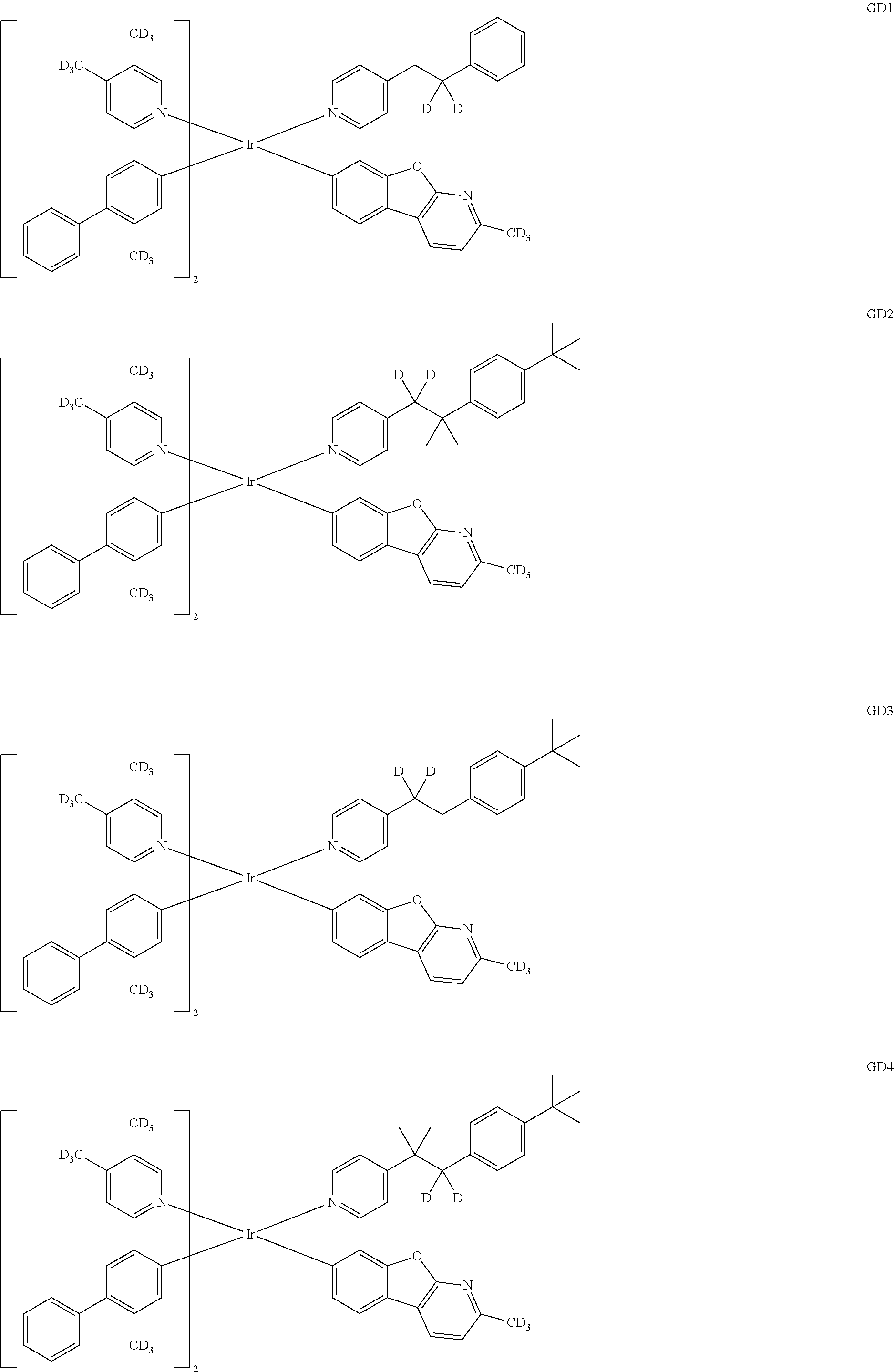

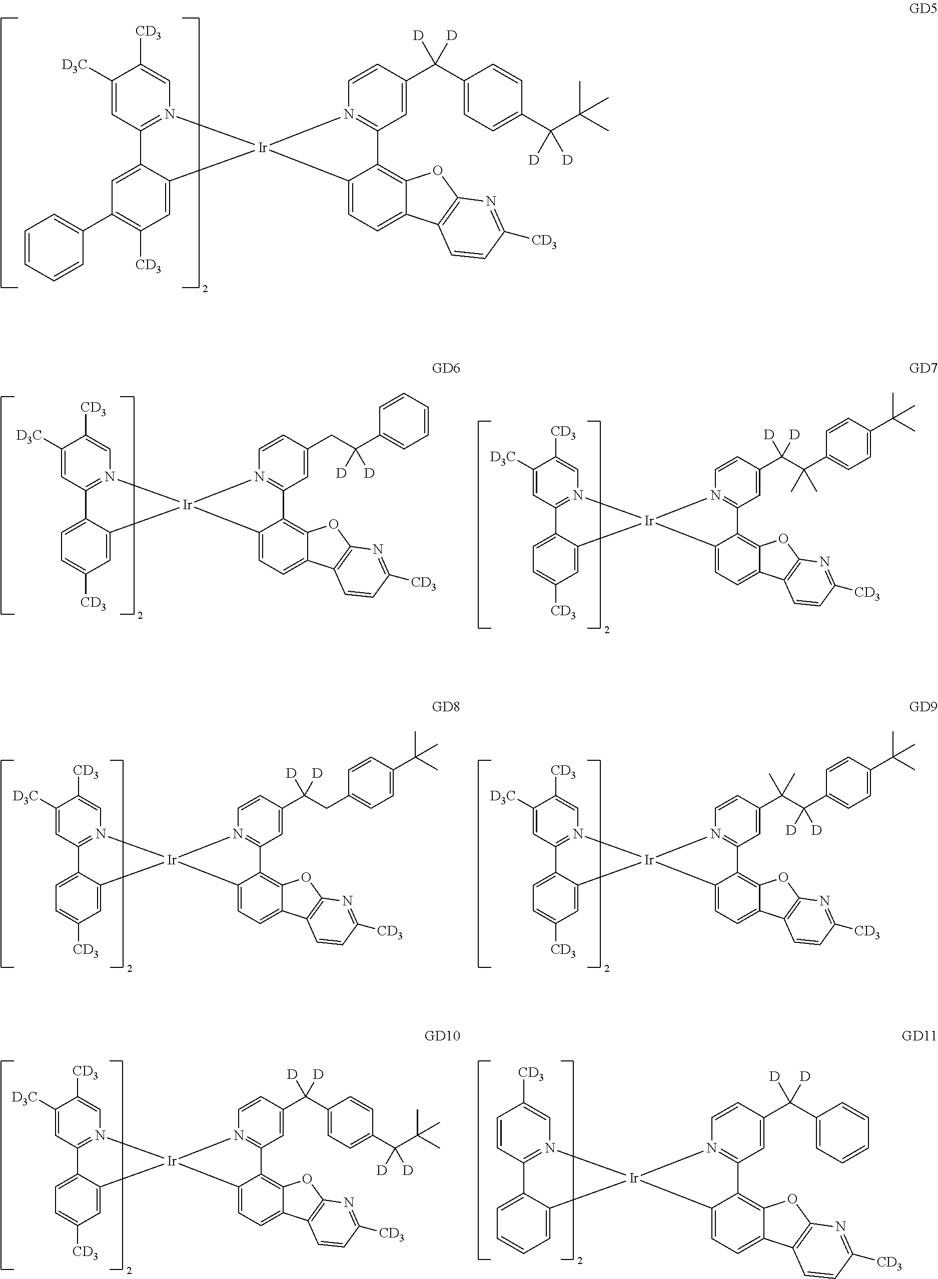

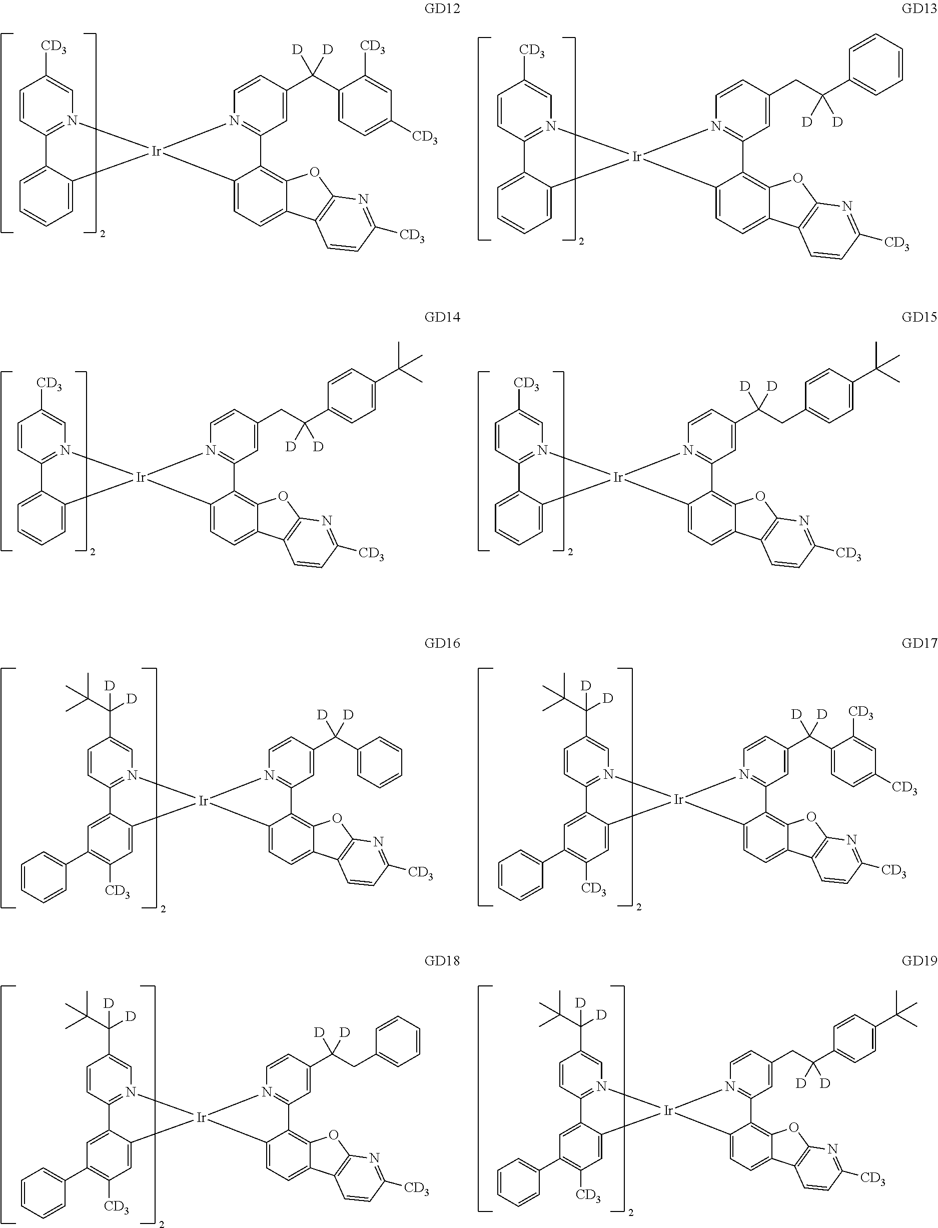

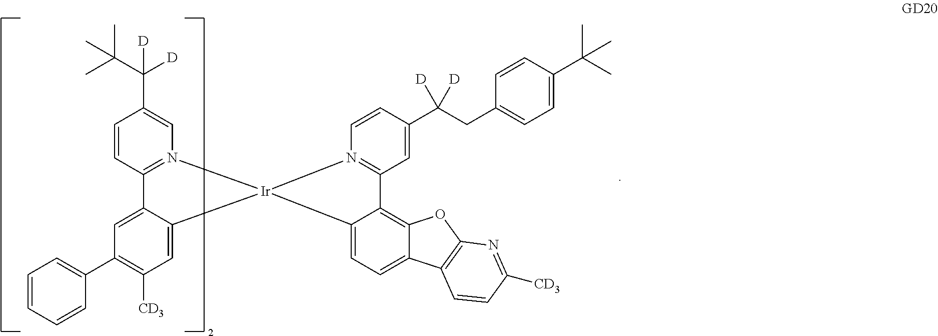

6. The organic light emitting diode of claim 1, wherein Ra and R_{b} in Chemical Formula 2 are each independently one selected from a phenyl group, a biphenyl group, a terphenyl group, a naphthyl group, an anthracene group, a chrysene group, a pyrene group, a phenanthrene group, a triphenylene group, a fluorene group, a 9,9′-dimethylfluorene group, a 9,9′-diphenylfluorene group, and a 9,9′-spirofluorene group.

7. The organic light emitting diode of claim 1, wherein the compound represented by Chemical Formula 2 includes one of Compounds GHH1 to GHH30:

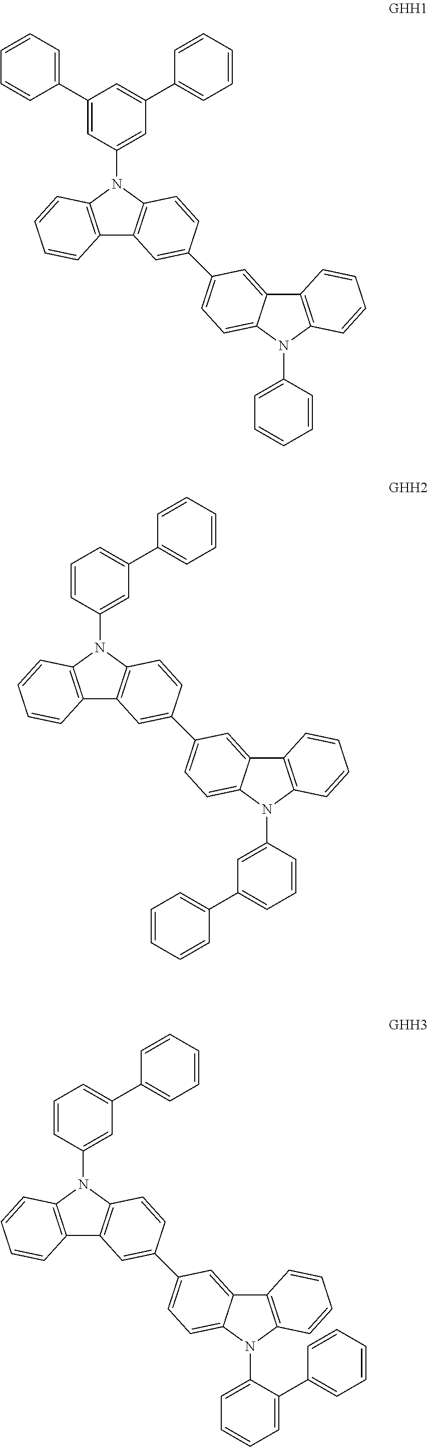 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]

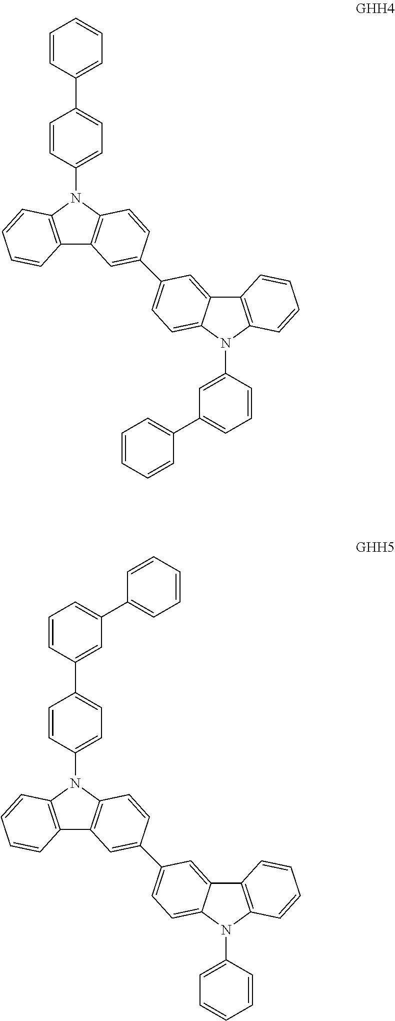 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-c3ccc(-n4c5ccccc5c5cc(-c6ccc7c(c6)c6ccccc6n7-c6ccccc6)ccc54)cc3)c2)cc1]

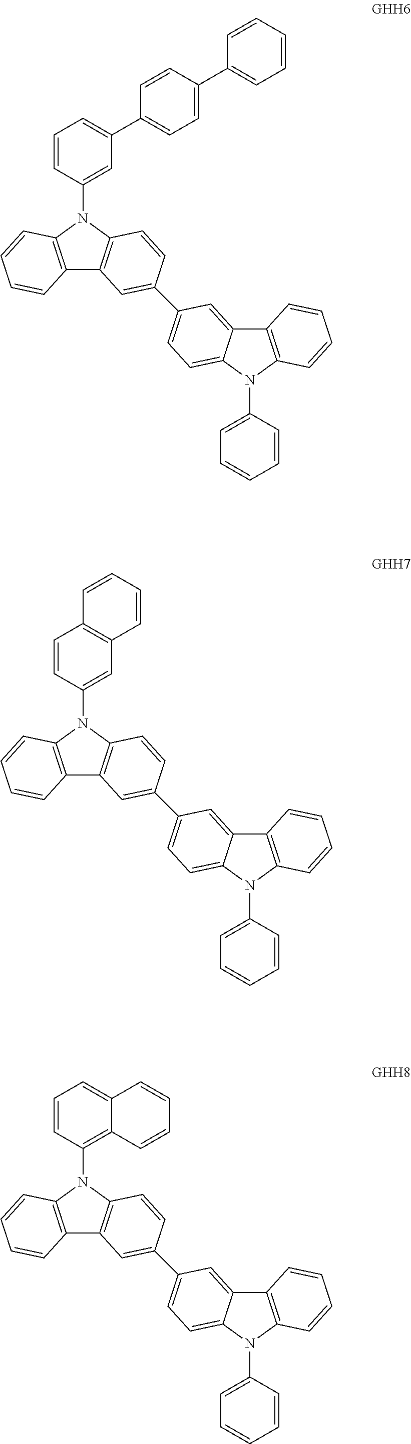 [SMILES: c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1]

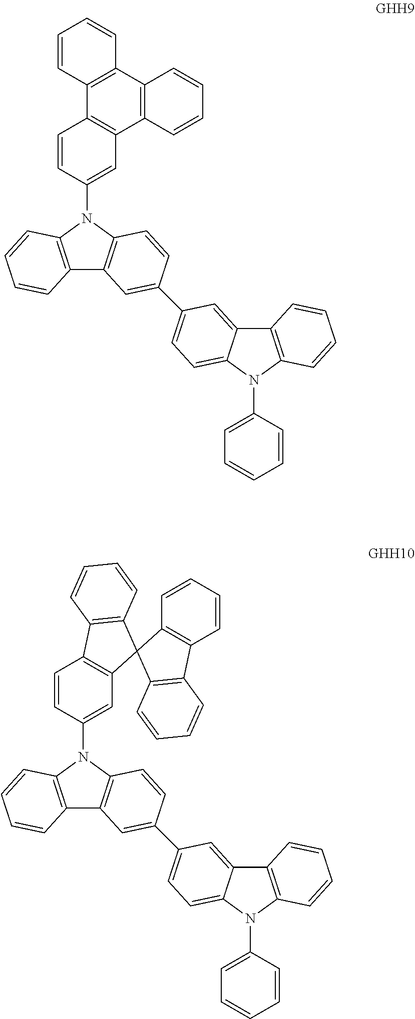 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1]

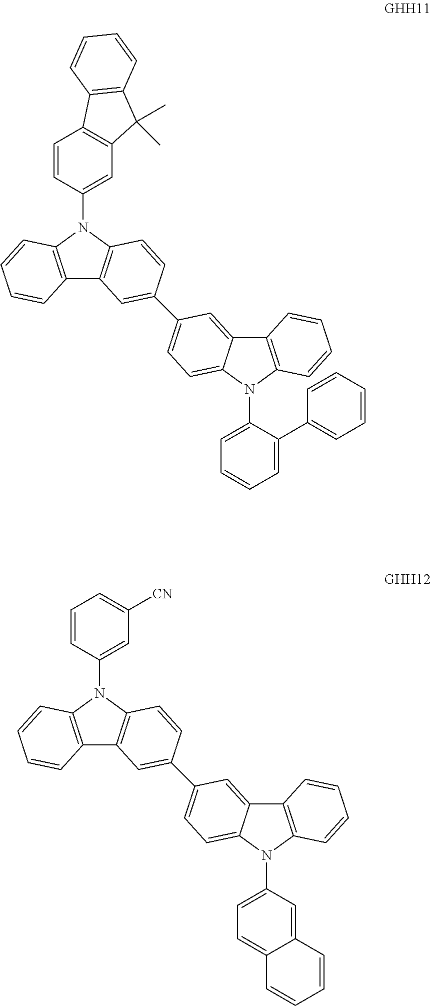 [SMILES: CC1(C)c2ccccc2-c2ccc(-n3c4ccccc4c4cc(-c5ccc6c(c5)c5ccccc5n6-c5ccccc5-c5ccccc5)ccc43)cc21 ; N#Cc1cccc(-n2c3ccccc3c3cc(-c4ccc5c(c4)c4ccccc4n5-c4ccc5ccccc5c4)ccc32)c1]

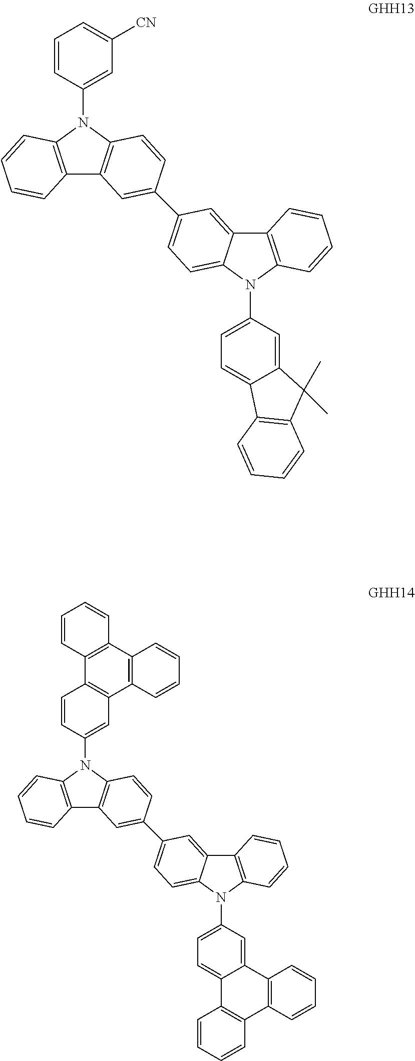 [SMILES: CC1(C)c2ccccc2-c2ccc(-n3c4ccccc4c4cc(-c5ccc6c(c5)c5ccccc5n6-c5cccc(C#N)c5)ccc43)cc21 ; c1ccc2c(c1)c1ccccc1c1cc(-n3c4ccccc4c4cc(-c5ccc6c(c5)c5ccccc5n6-c5ccc6c7ccccc7c7ccccc7c6c5)ccc43)ccc21]

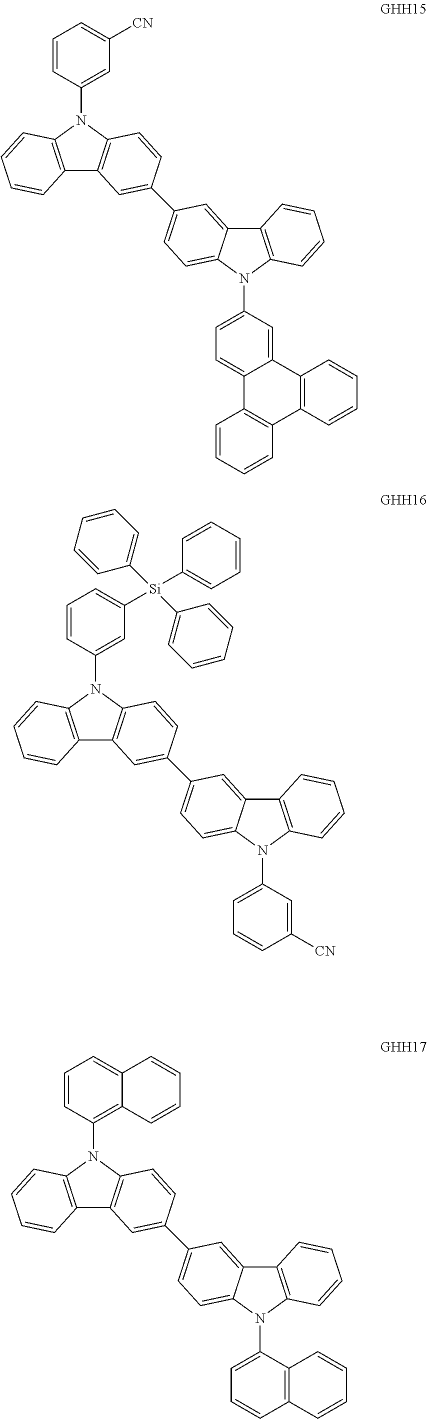 [SMILES: N#Cc1cccc(-n2c3ccccc3c3cc(-c4ccc5c(c4)c4ccccc4n5-c4ccc5c6ccccc6c6ccccc6c5c4)ccc32)c1 ; N#Cc1cccc(-n2c3ccccc3c3cc(-c4ccc5c(c4)c4ccccc4n5-c4cccc([Si](c5ccccc5)(c5ccccc5)c5ccccc5)c4)ccc32)c1 ; c1ccc2c(-n3c4ccccc4c4cc(-c5ccc6c(c5)c5ccccc5n6-c5cccc6ccccc56)ccc43)cccc2c1]

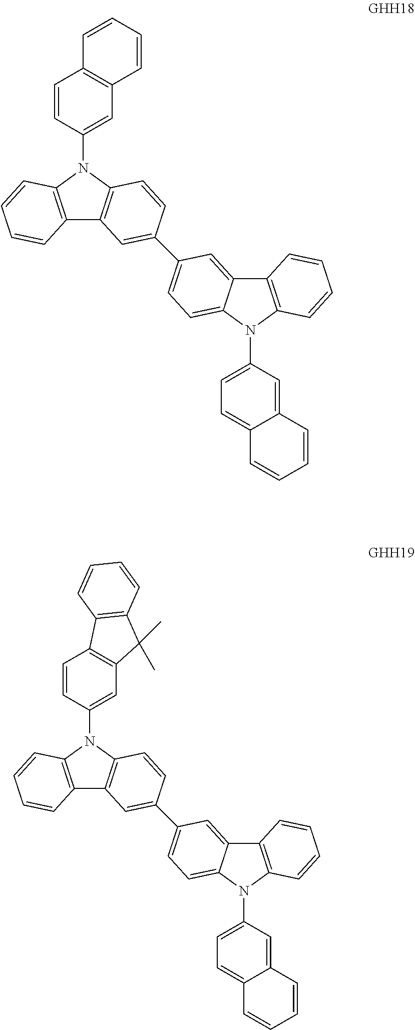 [SMILES: c1ccc2cc(-n3c4ccccc4c4cc(-c5ccc6c(c5)c5ccccc5n6-c5ccc6ccccc6c5)ccc43)ccc2c1 ; CC1(C)c2ccccc2-c2ccc(-n3c4ccccc4c4cc(-c5ccc6c(c5)c5ccccc5n6-c5ccc6ccccc6c5)ccc43)cc21]

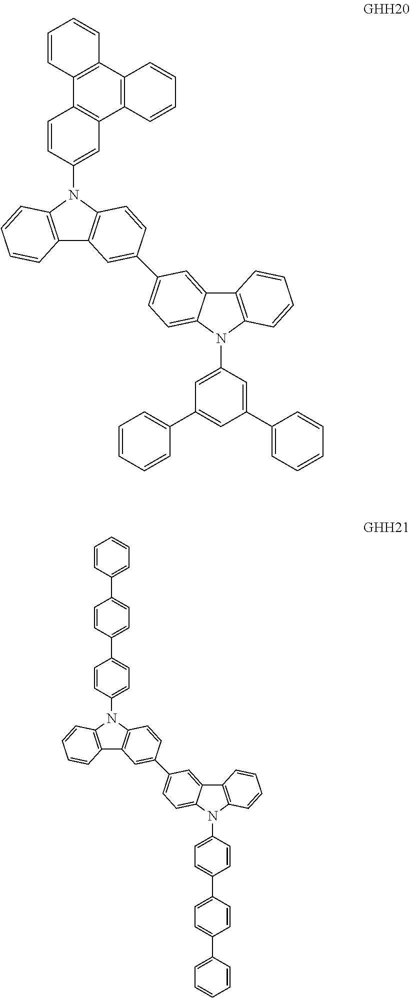 [SMILES: c1ccc(-c2cc(-c3ccccc3)cc(-n3c4ccccc4c4cc(-c5ccc6c(c5)c5ccccc5n6-c5ccc6c7ccccc7c7ccccc7c6c5)ccc43)c2)cc1 ; c1ccc(-c2ccc(-c3ccc(-n4c5ccccc5c5cc(-c6ccc7c(c6)c6ccccc6n7-c6ccc(-c7ccc(-c8ccccc8)cc7)cc6)ccc54)cc3)cc2)cc1]

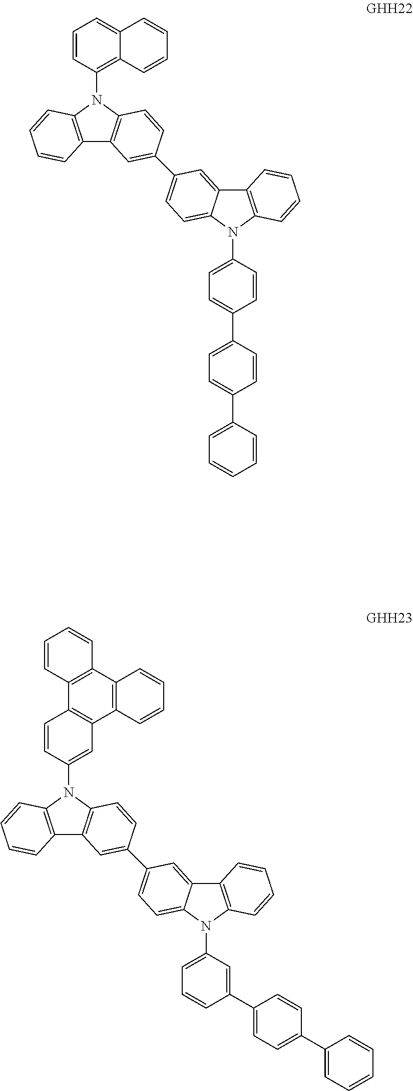 [SMILES: c1ccc(-c2ccc(-c3ccc(-n4c5ccccc5c5cc(-c6ccc7c(c6)c6ccccc6n7-c6cccc7ccccc67)ccc54)cc3)cc2)cc1 ; c1ccc(-c2ccc(-c3cccc(-n4c5ccccc5c5cc(-c6ccc7c(c6)c6ccccc6n7-c6ccc7c8ccccc8c8ccccc8c7c6)ccc54)c3)cc2)cc1]

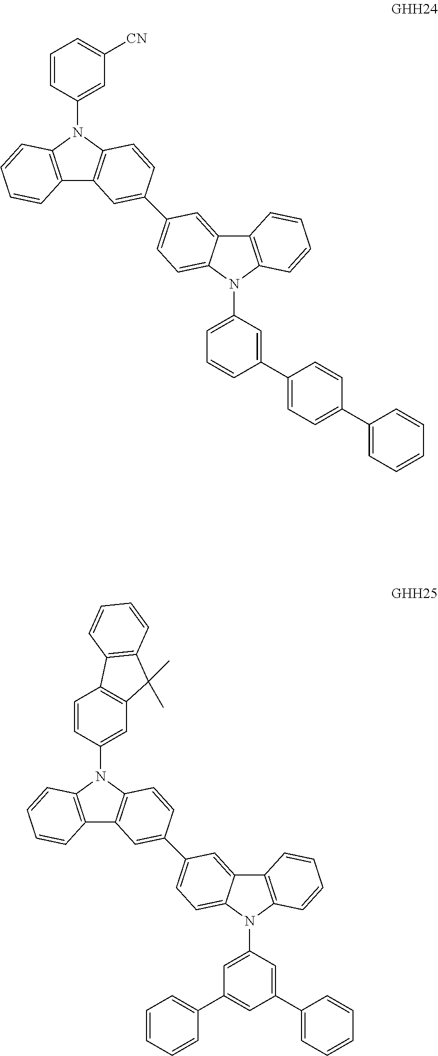 [SMILES: N#Cc1cccc(-n2c3ccccc3c3cc(-c4ccc5c(c4)c4ccccc4n5-c4cccc(-c5ccc(-c6ccccc6)cc5)c4)ccc32)c1 ; CC1(C)c2ccccc2-c2ccc(-n3c4ccccc4c4cc(-c5ccc6c(c5)c5ccccc5n6-c5cc(-c6ccccc6)cc(-c6ccccc6)c5)ccc43)cc21]

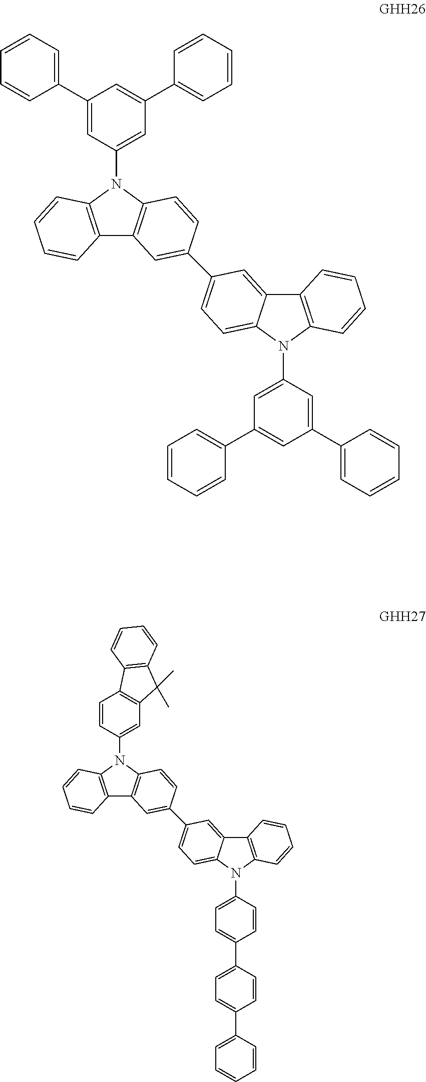 [SMILES: c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1 ; CC1(C)c2ccccc2-c2ccc(-n3c4ccccc4c4cc(-c5ccc6c(c5)c5ccccc5n6-c5ccc(-c6ccc(-c7ccccc7)cc6)cc5)ccc43)cc21]

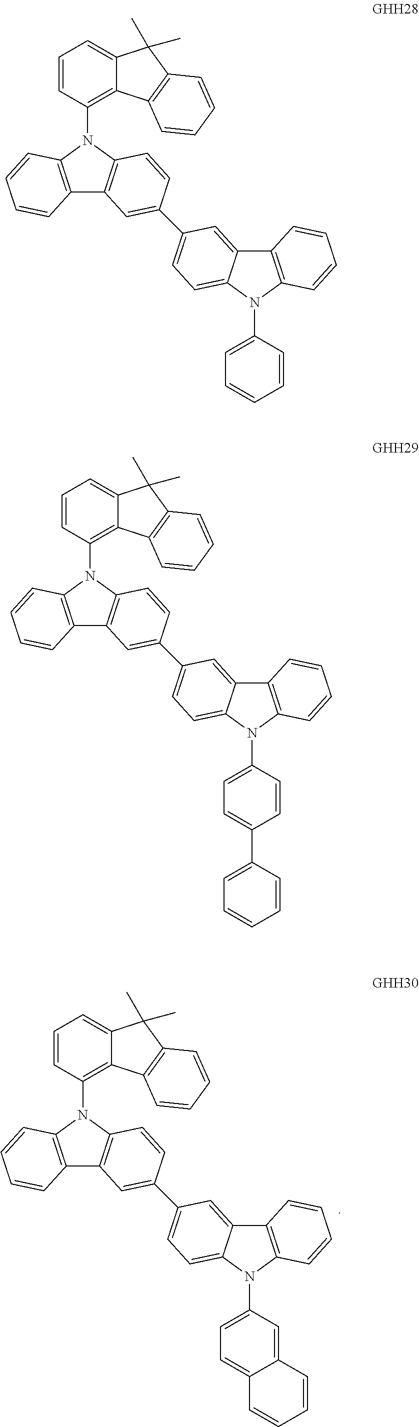 [SMILES: CC1(C)c2ccccc2-c2c(-n3c4ccccc4c4cc(-c5ccc6c(c5)c5ccccc5n6-c5ccccc5)ccc43)cccc21 ; CC1(C)c2ccccc2-c2c(-n3c4ccccc4c4cc(-c5ccc6c(c5)c5ccccc5n6-c5ccc(-c6ccccc6)cc5)ccc43)cccc21 ; CC1(C)c2ccccc2-c2c(-n3c4ccccc4c4cc(-c5ccc6c(c5)c5ccccc5n6-c5ccc6ccccc6c5)ccc43)cccc21]

8. The organic light emitting diode of claim 1, wherein Y in Chemical Formula 3 is N.

9. The organic light emitting diode of claim 1, wherein Ar₁ and Ar₂ in Chemical Formula 3 are each independently one selected from a C6-C50 aryl group and a C3-C50 heteroaryl group.

10. The organic light emitting diode of claim 1, wherein Ar₁ and Ar₂ in Chemical Formula 3 are each independently one selected from a phenyl group, a biphenyl group, a naphthyl group, a dibenzofuran group, a carbazole group, an indole group, a dibenzothiophene group, a chrysene group, a benzochrysene group, a phenanthrene group, a benzophenanthrene group, a benzonaphthothiophene group, and a benzonaphthofuran group.

11. The organic light emitting diode of claim 1, wherein the compound represented by Chemical Formula 3 includes one of Compounds GEH1 to GEH30:

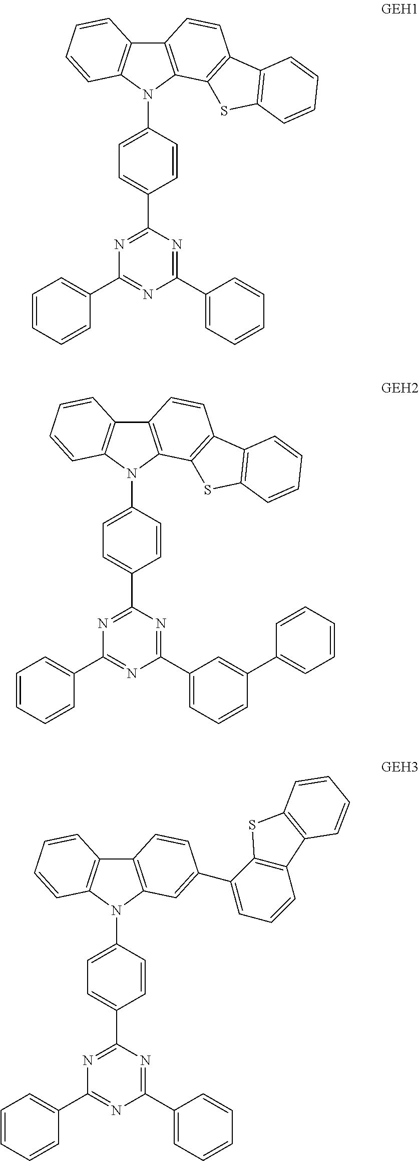 [SMILES: c1ccc(-c2nc(-c3ccccc3)nc(-c3ccc(-n4c5ccccc5c5ccc6c7ccccc7sc6c54)cc3)n2)cc1 ; c1ccc(-c2cccc(-c3nc(-c4ccccc4)nc(-c4ccc(-n5c6ccccc6c6ccc7c8ccccc8sc7c65)cc4)n3)c2)cc1 ; c1ccc(-c2nc(-c3ccccc3)nc(-c3ccc(-n4c5ccccc5c5ccc(-c6cccc7c6sc6ccccc67)cc54)cc3)n2)cc1]

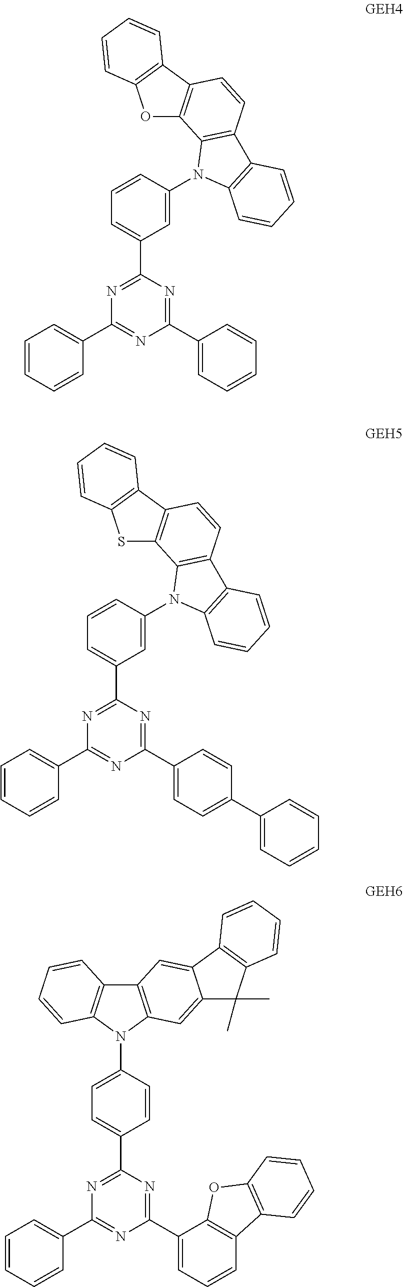 [SMILES: c1ccc(-c2nc(-c3ccccc3)nc(-c3cccc(-n4c5ccccc5c5ccc6c7ccccc7oc6c54)c3)n2)cc1 ; c1ccc(-c2ccc(-c3nc(-c4ccccc4)nc(-c4cccc(-n5c6ccccc6c6ccc7c8ccccc8sc7c65)c4)n3)cc2)cc1 ; CC1(C)c2ccccc2-c2cc3c4ccccc4n(-c4ccc(-c5nc(-c6ccccc6)nc(-c6cccc7c6oc6ccccc67)n5)cc4)c3cc21]

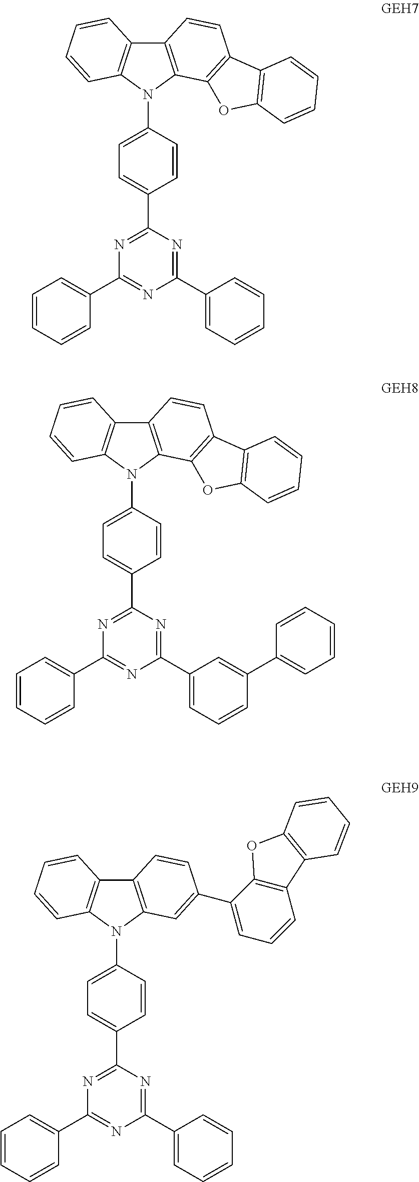 [SMILES: c1ccc(-c2nc(-c3ccccc3)nc(-c3ccc(-n4c5ccccc5c5ccc6c7ccccc7oc6c54)cc3)n2)cc1 ; c1ccc(-c2cccc(-c3nc(-c4ccccc4)nc(-c4ccc(-n5c6ccccc6c6ccc7c8ccccc8oc7c65)cc4)n3)c2)cc1 ; c1ccc(-c2nc(-c3ccccc3)nc(-c3ccc(-n4c5ccccc5c5ccc(-c6cccc7c6oc6ccccc67)cc54)cc3)n2)cc1]

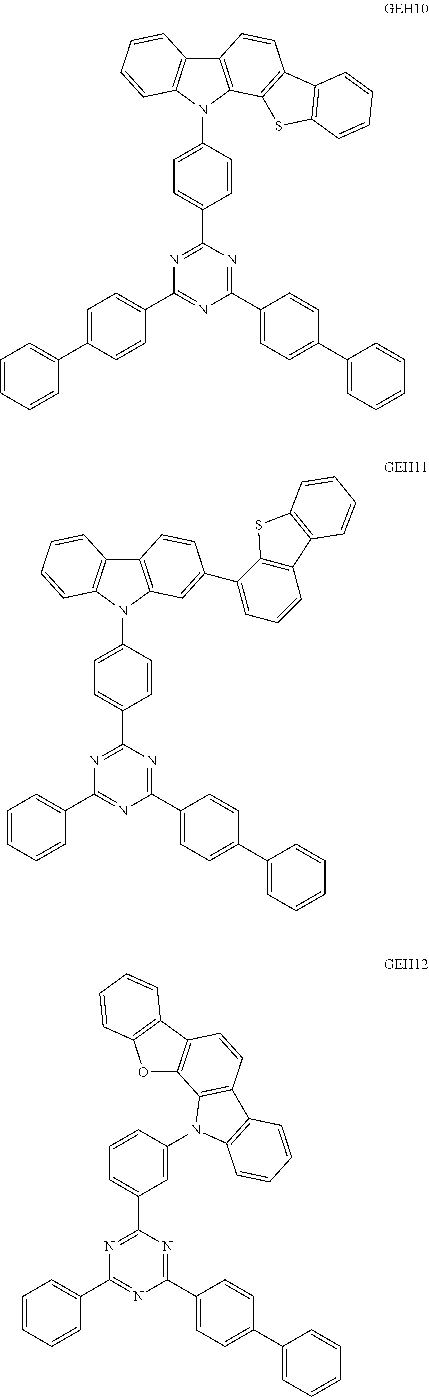 [SMILES: c1ccc(-c2ccc(-c3nc(-c4ccc(-c5ccccc5)cc4)nc(-c4ccc(-n5c6ccccc6c6ccc7c8ccccc8sc7c65)cc4)n3)cc2)cc1 ; c1ccc(-c2ccc(-c3nc(-c4ccccc4)nc(-c4ccc(-n5c6ccccc6c6ccc(-c7cccc8c7sc7ccccc78)cc65)cc4)n3)cc2)cc1 ; c1ccc(-c2ccc(-c3nc(-c4ccccc4)nc(-c4cccc(-n5c6ccccc6c6ccc7c8ccccc8oc7c65)c4)n3)cc2)cc1]

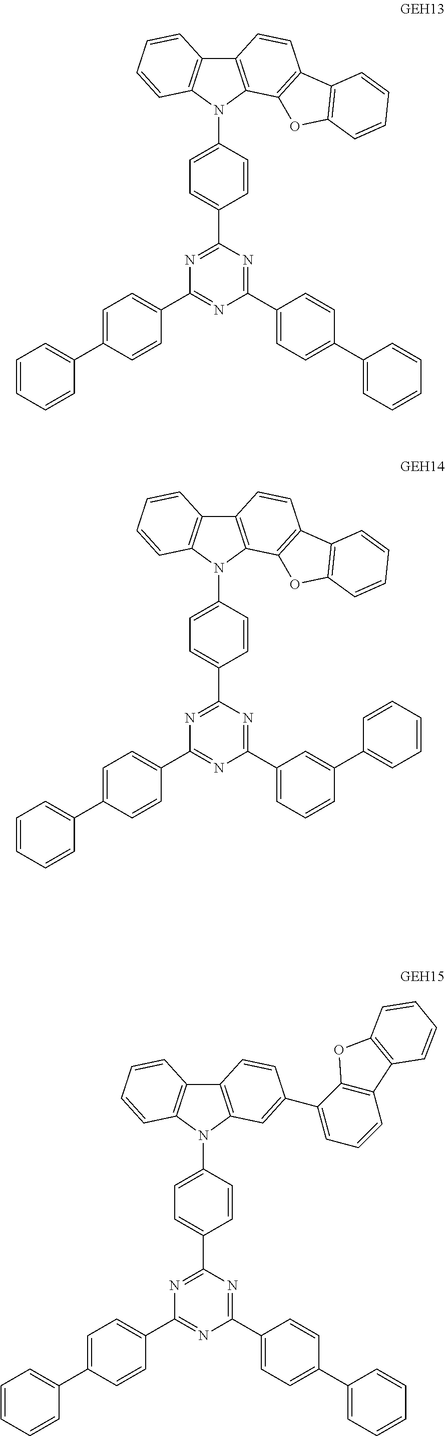 [SMILES: c1ccc(-c2ccc(-c3nc(-c4ccc(-c5ccccc5)cc4)nc(-c4ccc(-n5c6ccccc6c6ccc7c8ccccc8oc7c65)cc4)n3)cc2)cc1 ; c1ccc(-c2ccc(-c3nc(-c4ccc(-n5c6ccccc6c6ccc7c8ccccc8oc7c65)cc4)nc(-c4cccc(-c5ccccc5)c4)n3)cc2)cc1 ; c1ccc(-c2ccc(-c3nc(-c4ccc(-c5ccccc5)cc4)nc(-c4ccc(-n5c6ccccc6c6ccc(-c7cccc8c7oc7ccccc78)cc65)cc4)n3)cc2)cc1]

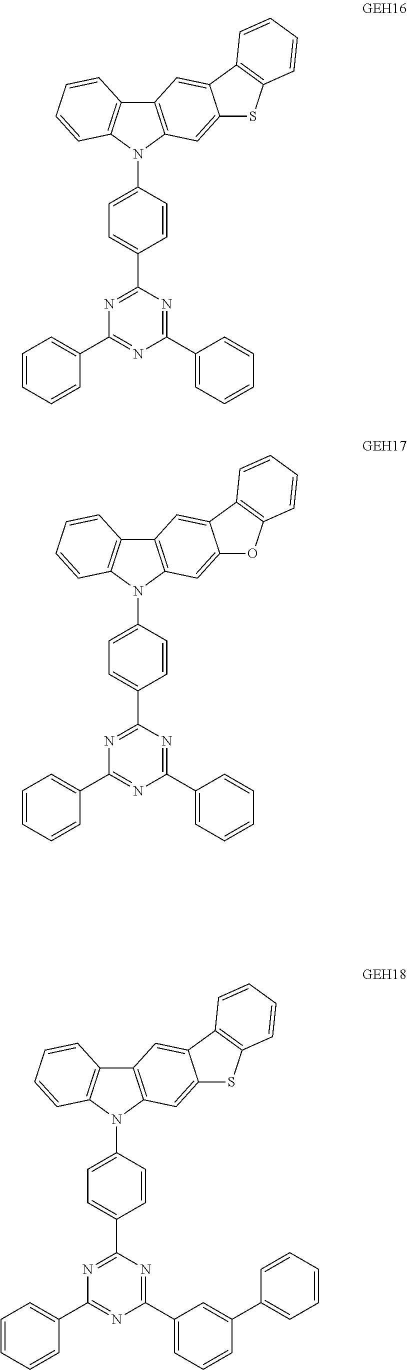 [SMILES: c1ccc(-c2nc(-c3ccccc3)nc(-c3ccc(-n4c5ccccc5c5cc6c(cc54)sc4ccccc46)cc3)n2)cc1 ; c1ccc(-c2nc(-c3ccccc3)nc(-c3ccc(-n4c5ccccc5c5cc6c(cc54)oc4ccccc46)cc3)n2)cc1 ; c1ccc(-c2cccc(-c3nc(-c4ccccc4)nc(-c4ccc(-n5c6ccccc6c6cc7c(cc65)sc5ccccc57)cc4)n3)c2)cc1]

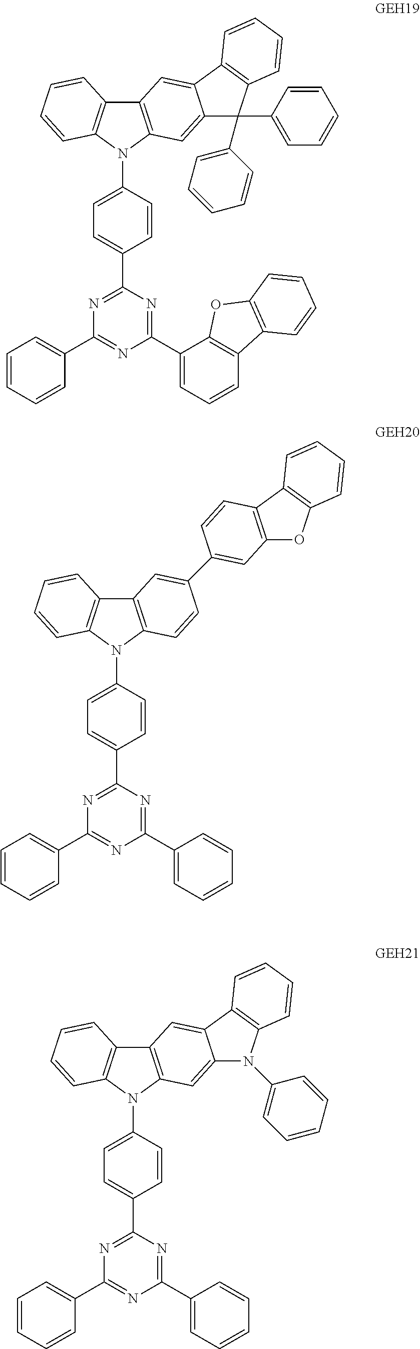 [SMILES: c1ccc(-c2nc(-c3ccc(-n4c5ccccc5c5cc6c(cc54)C(c4ccccc4)(c4ccccc4)c4ccccc4-6)cc3)nc(-c3cccc4c3oc3ccccc34)n2)cc1 ; c1ccc(-c2nc(-c3ccccc3)nc(-c3ccc(-n4c5ccccc5c5cc(-c6ccc7c(c6)oc6ccccc67)ccc54)cc3)n2)cc1 ; c1ccc(-c2nc(-c3ccccc3)nc(-c3ccc(-n4c5ccccc5c5cc6c7ccccc7n(-c7ccccc7)c6cc54)cc3)n2)cc1]

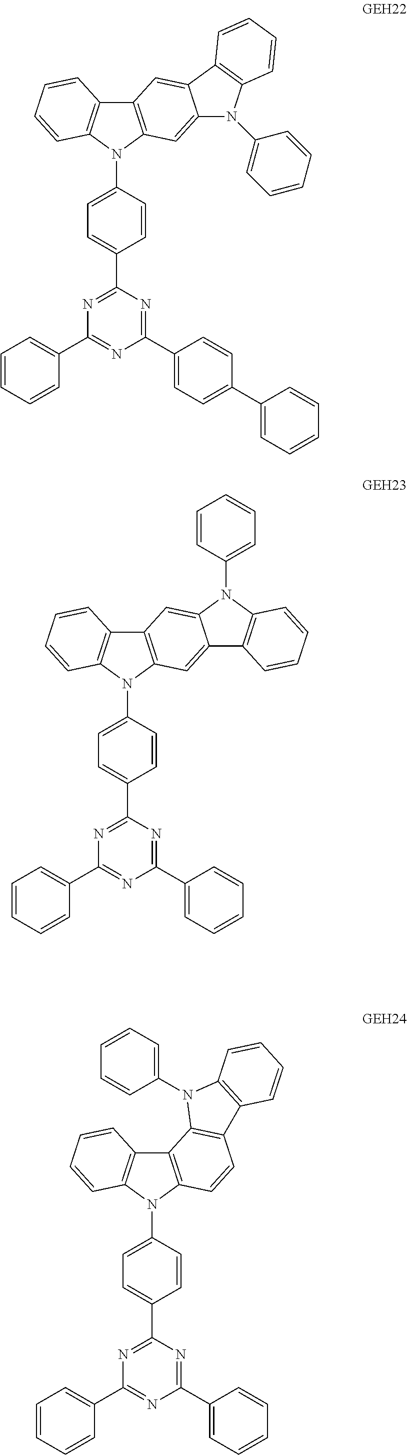 [SMILES: c1ccc(-c2ccc(-c3nc(-c4ccccc4)nc(-c4ccc(-n5c6ccccc6c6cc7c8ccccc8n(-c8ccccc8)c7cc65)cc4)n3)cc2)cc1 ; c1ccc(-c2nc(-c3ccccc3)nc(-c3ccc(-n4c5ccccc5c5cc6c(cc54)c4ccccc4n6-c4ccccc4)cc3)n2)cc1 ; c1ccc(-c2nc(-c3ccccc3)nc(-c3ccc(-n4c5ccccc5c5c4ccc4c6ccccc6n(-c6ccccc6)c45)cc3)n2)cc1]

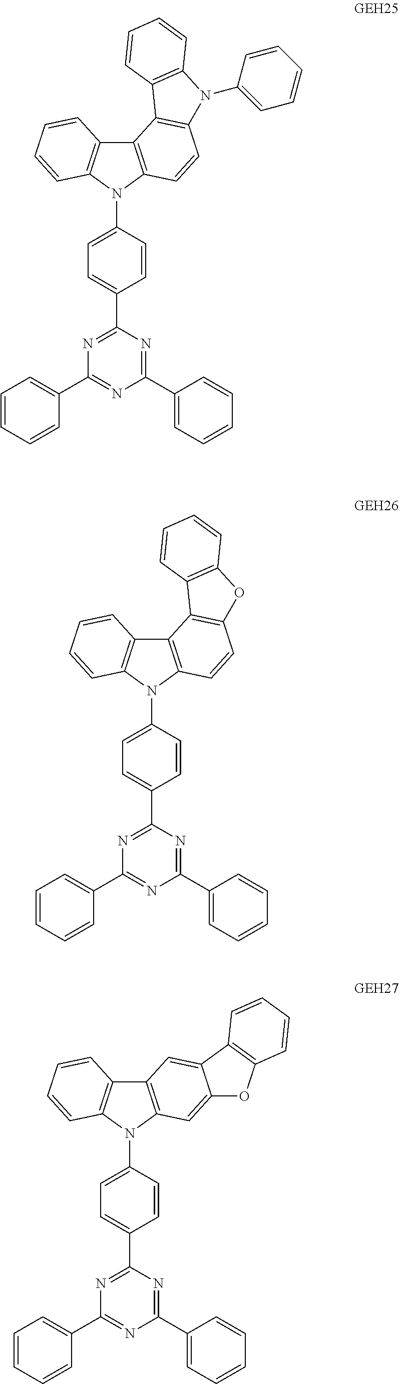 [SMILES: c1ccc(-c2nc(-c3ccccc3)nc(-c3ccc(-n4c5ccccc5c5c6c7ccccc7n(-c7ccccc7)c6ccc54)cc3)n2)cc1 ; c1ccc(-c2nc(-c3ccccc3)nc(-c3ccc(-n4c5ccccc5c5c6c(ccc54)oc4ccccc46)cc3)n2)cc1 ; c1ccc(-c2nc(-c3ccccc3)nc(-c3ccc(-n4c5ccccc5c5cc6c(cc54)oc4ccccc46)cc3)n2)cc1]

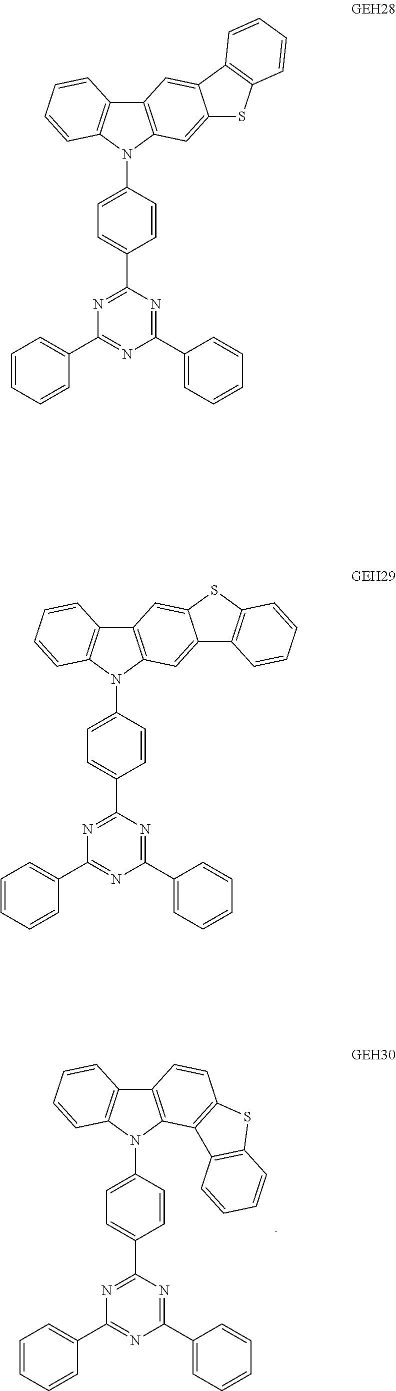 [SMILES: c1ccc(-c2nc(-c3ccccc3)nc(-c3ccc(-n4c5ccccc5c5cc6c(cc54)sc4ccccc46)cc3)n2)cc1 ; c1ccc(-c2nc(-c3ccccc3)nc(-c3ccc(-n4c5ccccc5c5cc6sc7ccccc7c6cc54)cc3)n2)cc1 ; c1ccc(-c2nc(-c3ccccc3)nc(-c3ccc(-n4c5ccccc5c5ccc6sc7ccccc7c6c54)cc3)n2)cc1]

12. The organic light emitting diode of claim 1, wherein the intermediate layer further includes any one or more selected from a hole injection layer, a hole transport layer, an electron transport layer, and an electron injection layer.

13. An organic light emitting diode, comprising:
a first electrode;
a second electrode facing the first electrode; and
one or more light emitting parts positioned between the first electrode and the second electrode,
at least one of the one or more light emitting parts including a green phosphorescent light emission layer including:
a dopant material including an organometallic compound represented by Chemical Formula 1, and
a host material including a compound represented by Chemical Formula 2 and a compound represented by Chemical Formula 3: 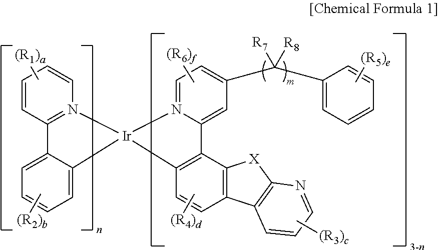
wherein in Chemical Formula 1,
X is one selected from oxygen (O), sulfur(S), and selenium (Se),
each R₁ to R₆ is independently one selected from deuterium, halogen, an alkyl group, a cycloalkyl group, a heteroalkyl group, an arylalkyl group, an alkoxy group, an aryloxy group, an amino group, a silyl group, an alkenyl group, a cycloalkenyl group, a heteroalkenyl group, an alkynyl group, an aryl group, a heteroaryl group, an acyl group, a a carboxylic acid group, a nitrile group, an isonitrile group, a sulfanyl group, and a phosphino group, and combinations thereof, where the alkyl group, the cycloalkyl group, the heteroalkyl group, the arylalkyl group, the alkoxy group, the aryloxy group, the amino group, the silyl group, the alkenyl group, the cycloalkenyl group, the heteroalkenyl group, the alkynyl group, the aryl group, the heteroaryl group, the acyl group, and the phosphino group are optionally partially deuterated or optionally entirely deuterated,
each R₇ and R₈ is independently one selected from hydrogen, deuterium, a C1-C6 linear alkyl group, a C3-C6 branched alkyl group, and a C3-C6 cycloalkyl group, where the C1-C6 linear alkyl group, the C3-C6 branched alkyl group, and the C3-C6 cycloalkyl group are optionally partially deuterated or optionally entirely deuterated,
a and b are, each independently, an integer from 0 to 4, and when a and b are each independently an integer from 2 to 4, a plurality of R₁ or a plurality of R₂ are the same or different from each other,
c and f are, each independently, an integer from 0 to 3, and when c and f are each independently an integer of 2 or 3, a plurality of R₃ or a plurality of R₆ are the same or different from each other,
d is an integer from 0 to 2, and when d is an integer of 2, a plurality of R₄ are the same or different from each other,
e is an integer from 0 to 5, and when e is an integer from 2 to 5, a plurality of R₅ are the same or different from each other, and
m is an integer selected from 1 to 8, and n is an integer selected from 0 to 2, 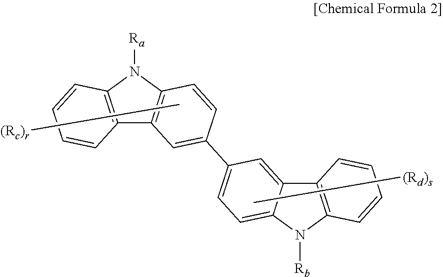
in Chemical Formula 2,
Rₐ and R_{b} are each independently one selected from an aryl group and a heteroaryl group, where the aryl group and the heteroaryl group are optionally substituted with one or more substituents selected from an alkyl group, an aryl group, a nitrile group, an alkylsilyl group, and an arylsilyl group, and Rₐ and R_{b} are optionally partially deuterated or optionally entirely deuterated,
each R_{c} and Rₐ is independently one selected from hydrogen, deuterium, halogen, nitrile group, and alkyl group, and R_{c} and Rₐ are optionally partially deuterated or optionally entirely deuterated, and
r and s each independently denotes an integer selected from 0 to 7, and when r is an integer selected from 2 to 7, each R_{c} is the same as or different from each other, and when s is an integer selected from 2 to 7, each Rₐ is the same as or different from each other, 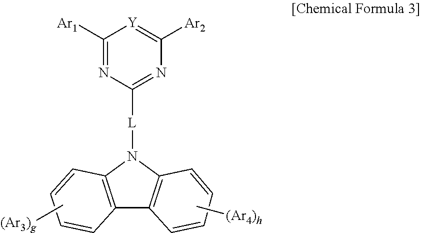
in Chemical Formula 3,
L is one selected from a single bond, a C6-C50 arylene group, and a C5-C50 heteroarylene group,
Y is N or CH,
each Ar₁, Ar₂, Ar₃, and Ar₄ is independently one selected from hydrogen, deuterium, halogen, a C1-C30 alkyl group, a C6-C50 aryl group, a C3-C50 heteroaryl group, and a C3-C30 cycloalkyl group,
g and h are each independently an integer selected from 1 to 4,
when g is an integer selected from 2 to 4, any two adjacent Ar₃ are optionally bonded to form a fused ring structure including a C6-C30 monocyclic or polycyclic aromatic group, or a C3-C30 heteroaromatic group, and one or more of hydrogens attached to the fused ring structure are optionally substituted by a substituent selected from deuterium, a C1-C10 alkyl group, a C6-C20 aryl group, and a C3-C20 heteroaryl group, and
when h is an integer selected from 2 to 4, any two adjacent Ar₄ are optionally bonded to form a fused ring structure including a C6-C30 monocyclic or polycyclic aromatic group, or a C3-C30 heteroaromatic group, and one or more of hydrogens attached to the fused ring structure are optionally substituted by a substituent selected from deuterium, a C1-C10 alkyl group, a C6-C20 aryl group, and a C3-C20 heteroaryl group.

14. The organic light emitting diode of claim 13, wherein the organometallic compound represented by Chemical Formula 1 includes one of Compounds GD1 to GD20:

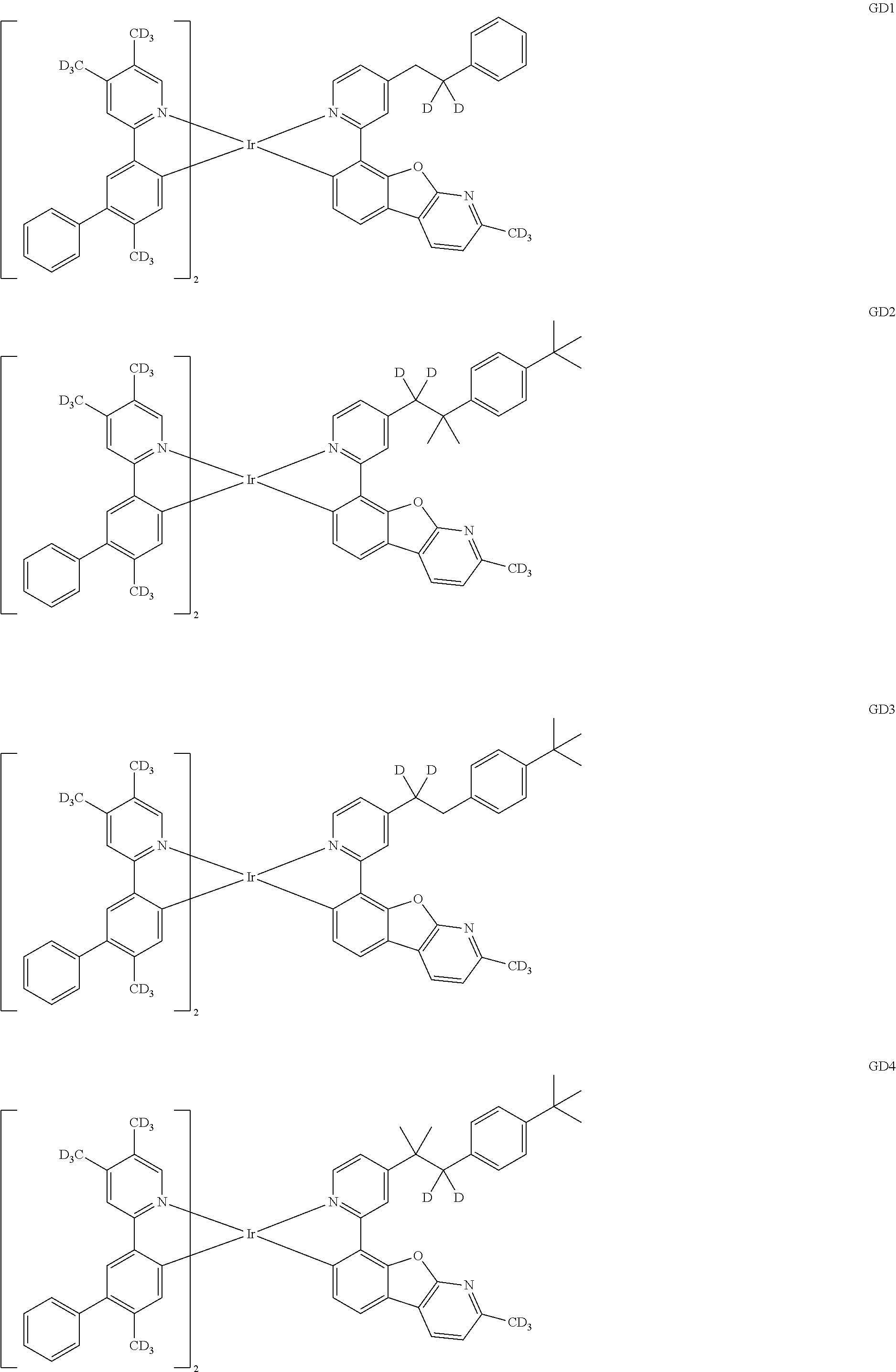

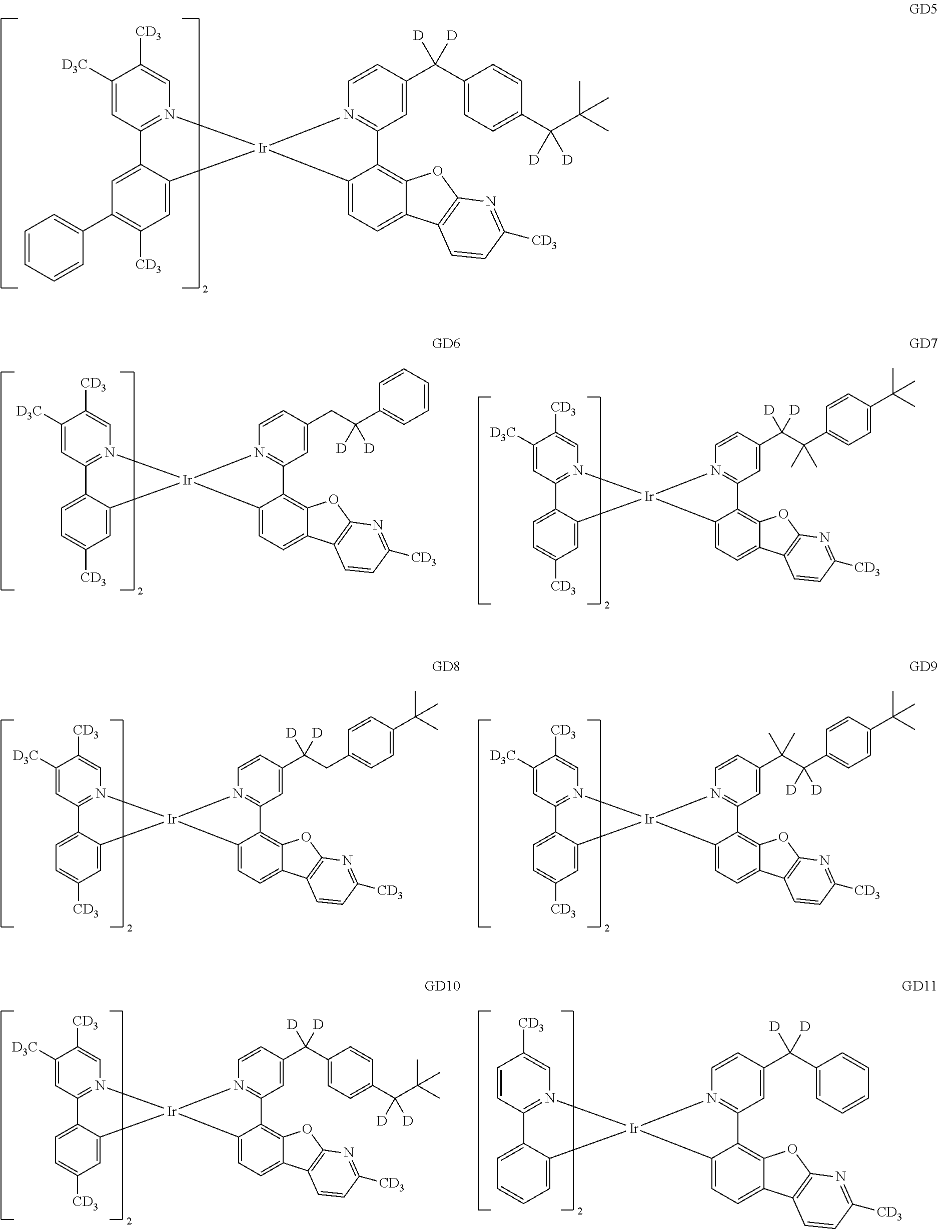

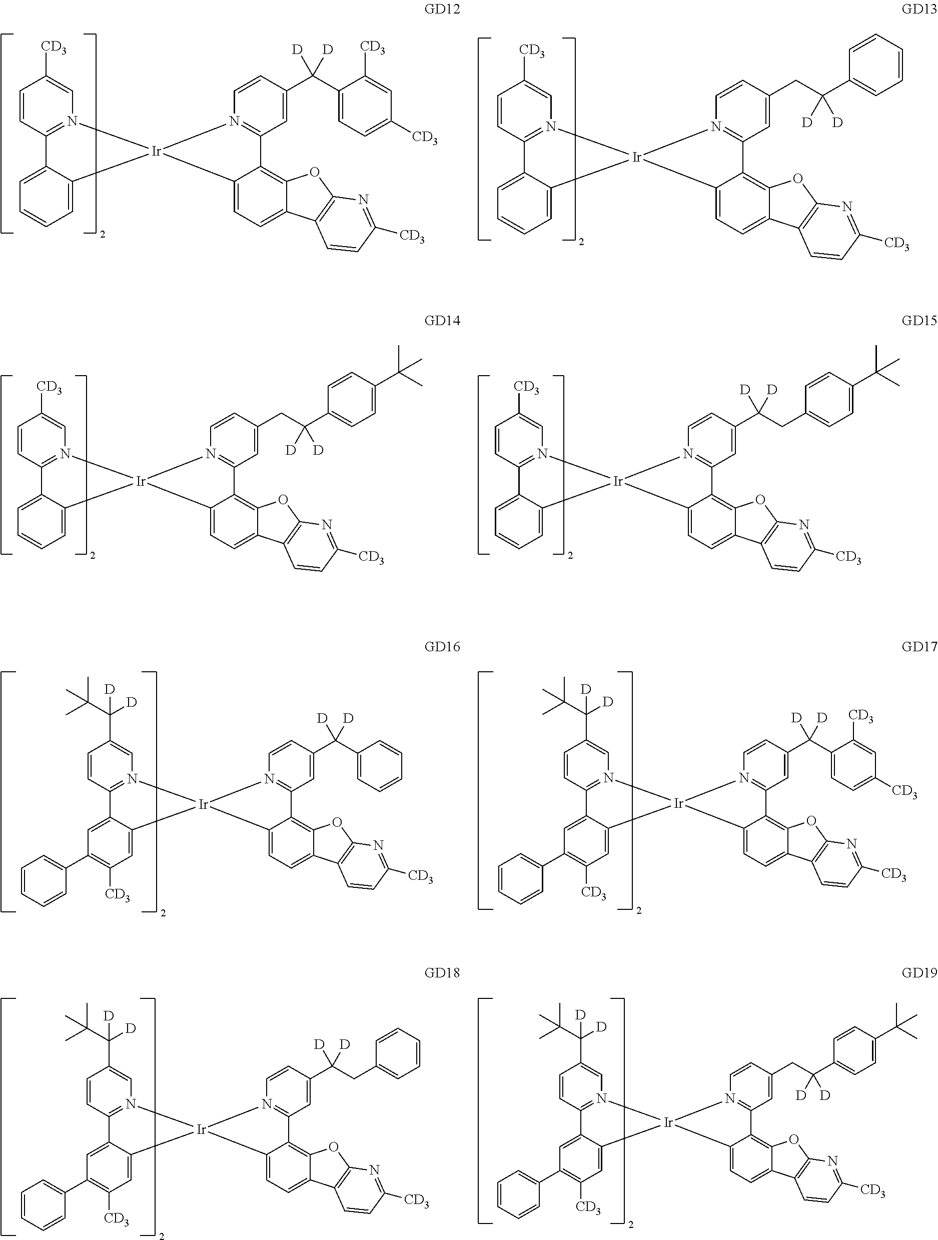

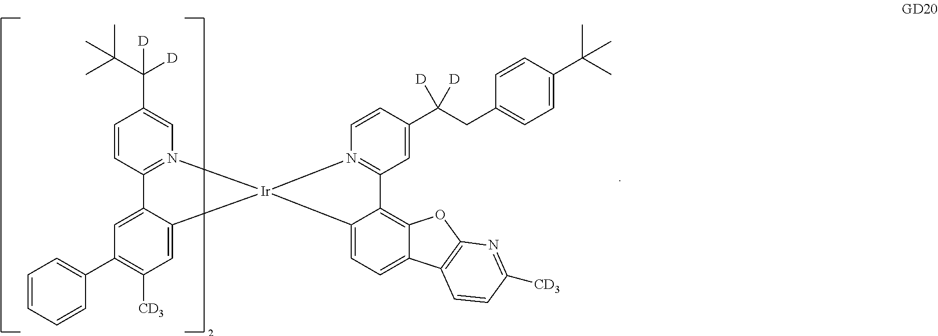

15. The organic light emitting diode of claim 13, wherein the compound represented by Chemical Formula 2 includes one of Compounds GHH1 to GHH30:

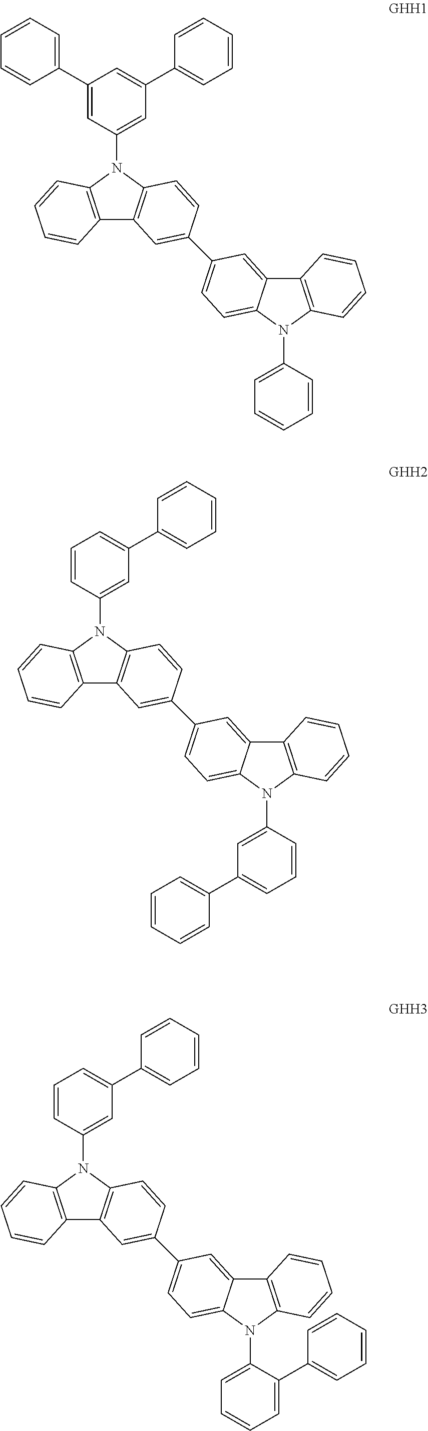 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]

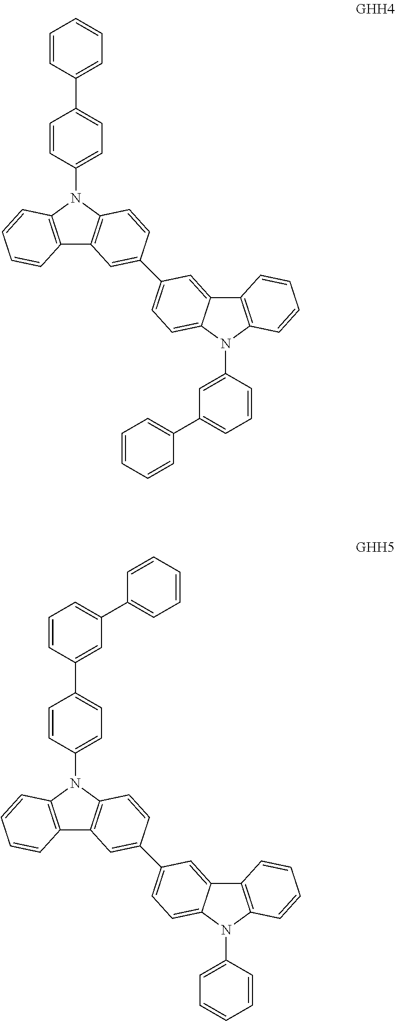 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-c3ccc(-n4c5ccccc5c5cc(-c6ccc7c(c6)c6ccccc6n7-c6ccccc6)ccc54)cc3)c2)cc1]

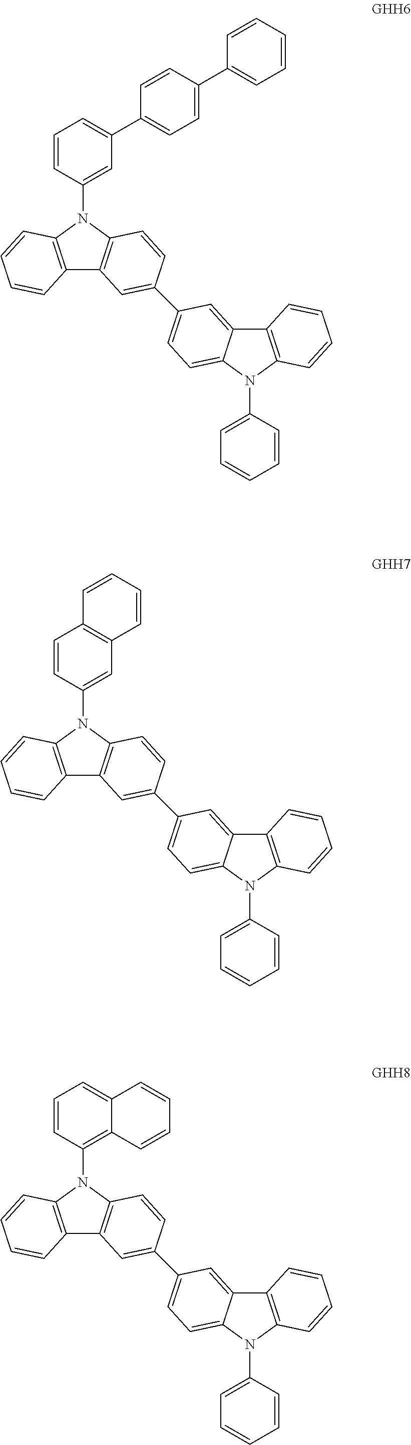 [SMILES: c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-n2c3ccccc3c3cc(-c4ccc5c(c4)c4ccccc4n5-c4ccc5ccccc5c4)ccc32)cc1 ; c1ccc(-n2c3ccccc3c3cc(-c4ccc5c(c4)c4ccccc4n5-c4cccc5ccccc45)ccc32)cc1]

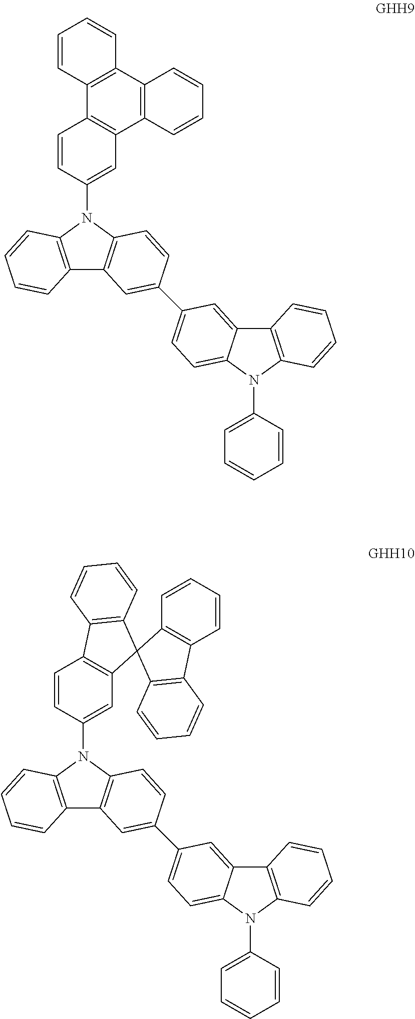 [SMILES: c1ccc(-n2c3ccccc3c3cc(-c4ccc5c(c4)c4ccccc4n5-c4ccc5c6ccccc6c6ccccc6c5c4)ccc32)cc1 ; c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1]

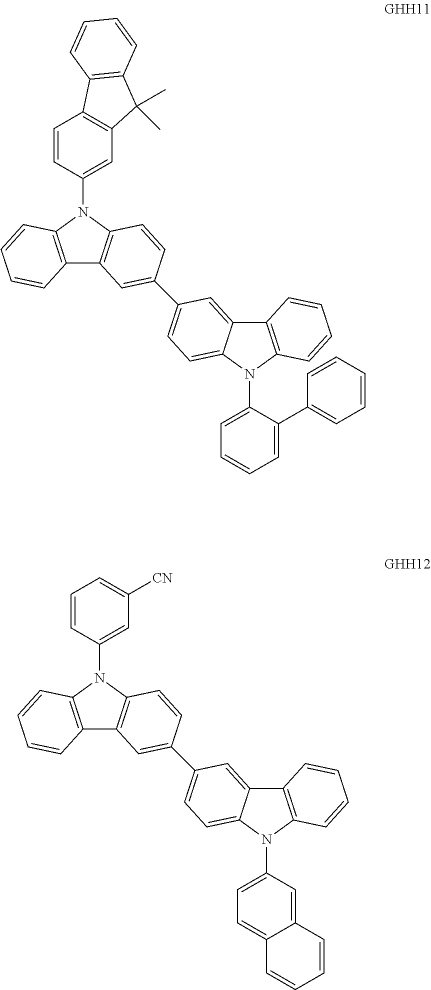 [SMILES: CC1(C)c2ccccc2-c2ccc(-n3c4ccccc4c4cc(-c5ccc6c(c5)c5ccccc5n6-c5ccccc5-c5ccccc5)ccc43)cc21 ; N#Cc1cccc(-n2c3ccccc3c3cc(-c4ccc5c(c4)c4ccccc4n5-c4ccc5ccccc5c4)ccc32)c1]

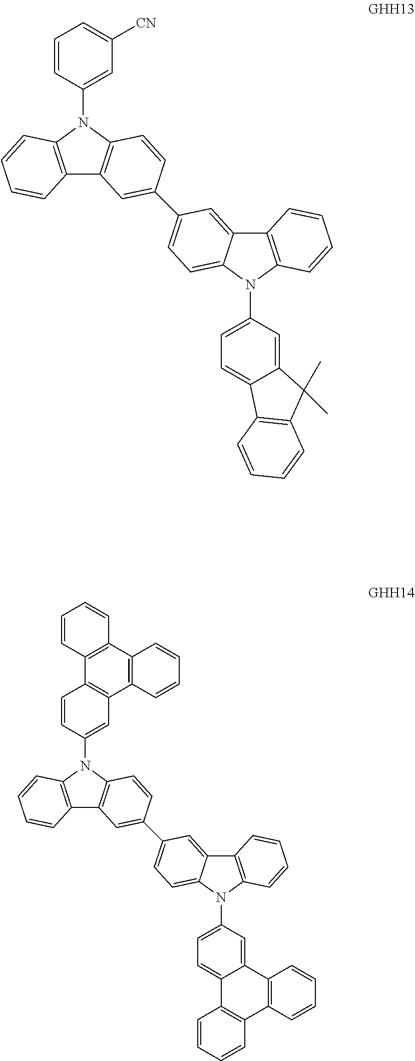 [SMILES: CC1(C)c2ccccc2-c2ccc(-n3c4ccccc4c4cc(-c5ccc6c(c5)c5ccccc5n6-c5cccc(C#N)c5)ccc43)cc21 ; c1ccc2c(c1)c1ccccc1c1cc(-n3c4ccccc4c4cc(-c5ccc6c(c5)c5ccccc5n6-c5ccc6c7ccccc7c7ccccc7c6c5)ccc43)ccc21]

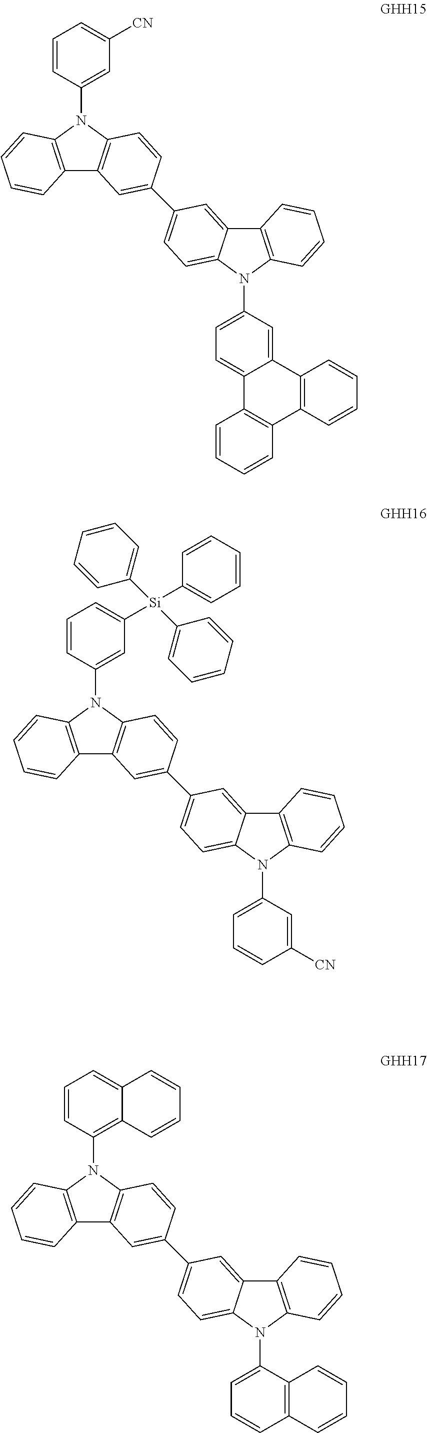 [SMILES: N#Cc1cccc(-n2c3ccccc3c3cc(-c4ccc5c(c4)c4ccccc4n5-c4ccc5c6ccccc6c6ccccc6c5c4)ccc32)c1 ; N#Cc1cccc(-n2c3ccccc3c3cc(-c4ccc5c(c4)c4ccccc4n5-c4cccc([Si](c5ccccc5)(c5ccccc5)c5ccccc5)c4)ccc32)c1 ; c1ccc2c(-n3c4ccccc4c4cc(-c5ccc6c(c5)c5ccccc5n6-c5cccc6ccccc56)ccc43)cccc2c1]

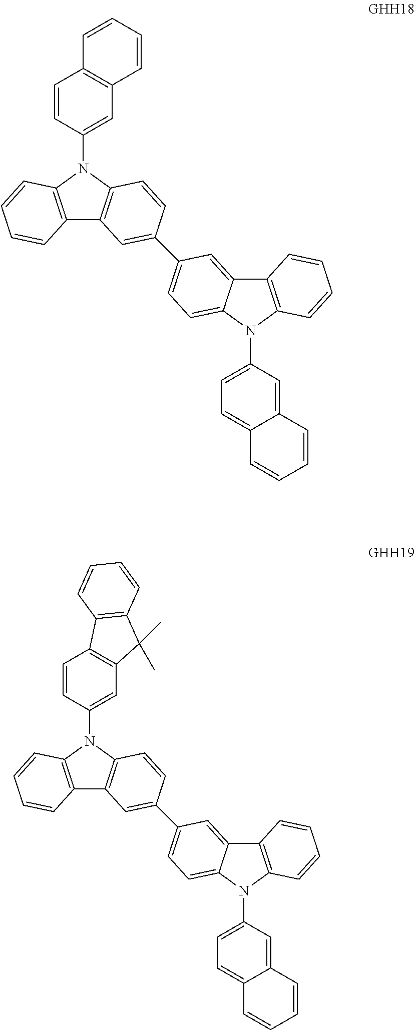 [SMILES: c1ccc2cc(-n3c4ccccc4c4cc(-c5ccc6c(c5)c5ccccc5n6-c5ccc6ccccc6c5)ccc43)ccc2c1 ; CC1(C)c2ccccc2-c2ccc(-n3c4ccccc4c4cc(-c5ccc6c(c5)c5ccccc5n6-c5ccc6ccccc6c5)ccc43)cc21]

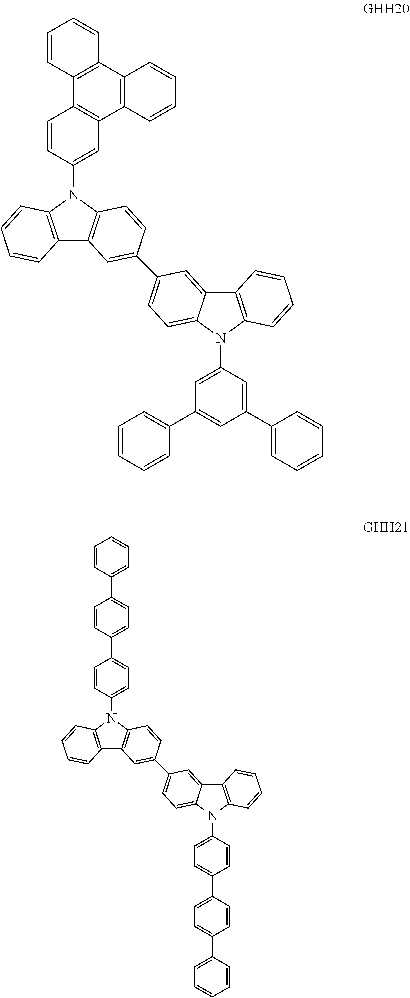 [SMILES: c1ccc(-c2cc(-c3ccccc3)cc(-n3c4ccccc4c4cc(-c5ccc6c(c5)c5ccccc5n6-c5ccc6c7ccccc7c7ccccc7c6c5)ccc43)c2)cc1 ; c1ccc(-c2ccc(-c3ccc(-n4c5ccccc5c5cc(-c6ccc7c(c6)c6ccccc6n7-c6ccc(-c7ccc(-c8ccccc8)cc7)cc6)ccc54)cc3)cc2)cc1]

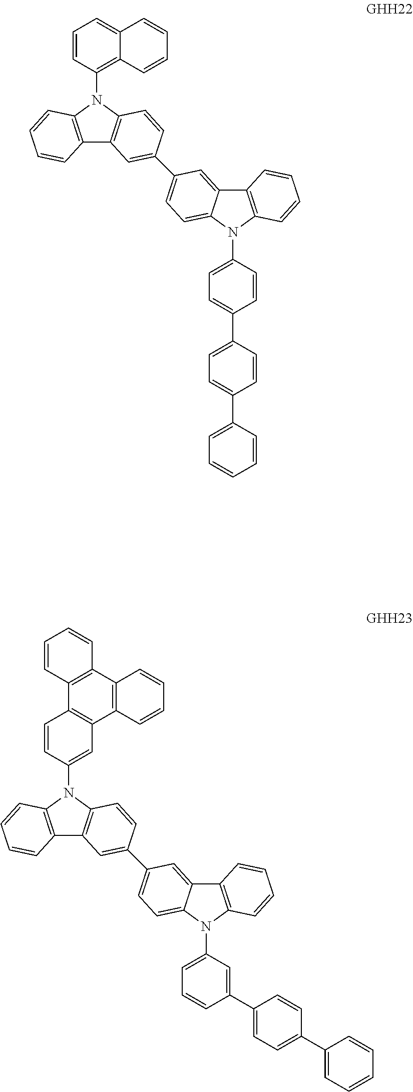 [SMILES: c1ccc(-c2ccc(-c3ccc(-n4c5ccccc5c5cc(-c6ccc7c(c6)c6ccccc6n7-c6cccc7ccccc67)ccc54)cc3)cc2)cc1 ; c1ccc(-c2ccc(-c3cccc(-n4c5ccccc5c5cc(-c6ccc7c(c6)c6ccccc6n7-c6ccc7c8ccccc8c8ccccc8c7c6)ccc54)c3)cc2)cc1]

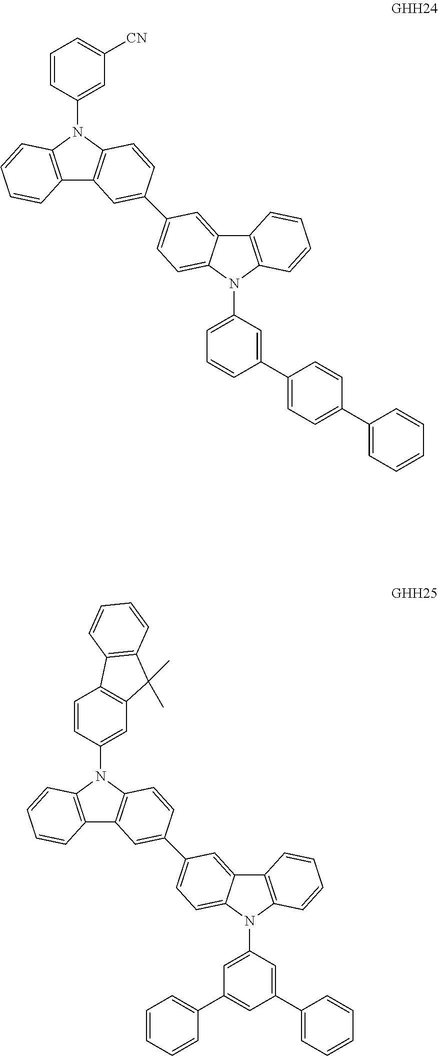 [SMILES: N#Cc1cccc(-n2c3ccccc3c3cc(-c4ccc5c(c4)c4ccccc4n5-c4cccc(-c5ccc(-c6ccccc6)cc5)c4)ccc32)c1 ; CC1(C)c2ccccc2-c2ccc(-n3c4ccccc4c4cc(-c5ccc6c(c5)c5ccccc5n6-c5cc(-c6ccccc6)cc(-c6ccccc6)c5)ccc43)cc21]

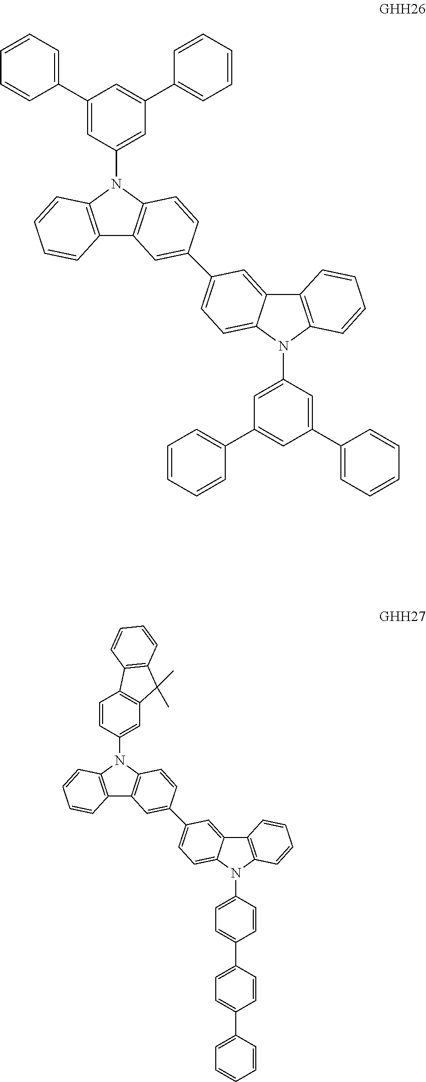 [SMILES: c1ccc(-c2cc(-c3ccccc3)cc(-n3c4ccccc4c4cc(-c5ccc6c(c5)c5ccccc5n6-c5cc(-c6ccccc6)cc(-c6ccccc6)c5)ccc43)c2)cc1 ; CC1(C)c2ccccc2-c2ccc(-n3c4ccccc4c4cc(-c5ccc6c(c5)c5ccccc5n6-c5ccc(-c6ccc(-c7ccccc7)cc6)cc5)ccc43)cc21]

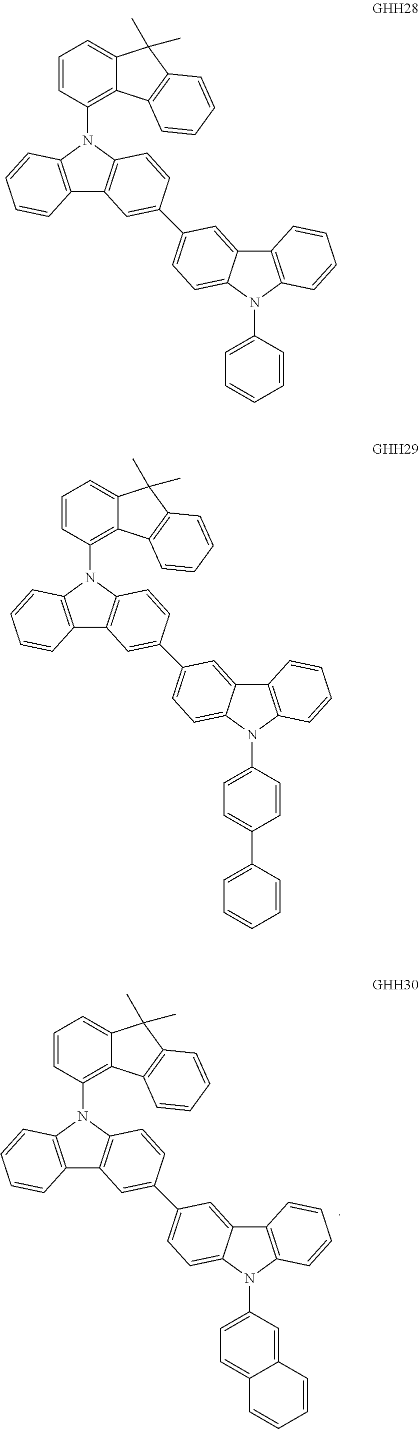 [SMILES: CC1(C)c2ccccc2-c2c(-n3c4ccccc4c4cc(-c5ccc6c(c5)c5ccccc5n6-c5ccccc5)ccc43)cccc21 ; CC1(C)c2ccccc2-c2c(-n3c4ccccc4c4cc(-c5ccc6c(c5)c5ccccc5n6-c5ccc(-c6ccccc6)cc5)ccc43)cccc21 ; CC1(C)c2ccccc2-c2c(-n3c4ccccc4c4cc(-c5ccc6c(c5)c5ccccc5n6-c5ccc6ccccc6c5)ccc43)cccc21]

16. The organic light emitting diode of claim 13, wherein the compound represented by Chemical Formula 3 includes one of Compounds GEH1 to GEH30:

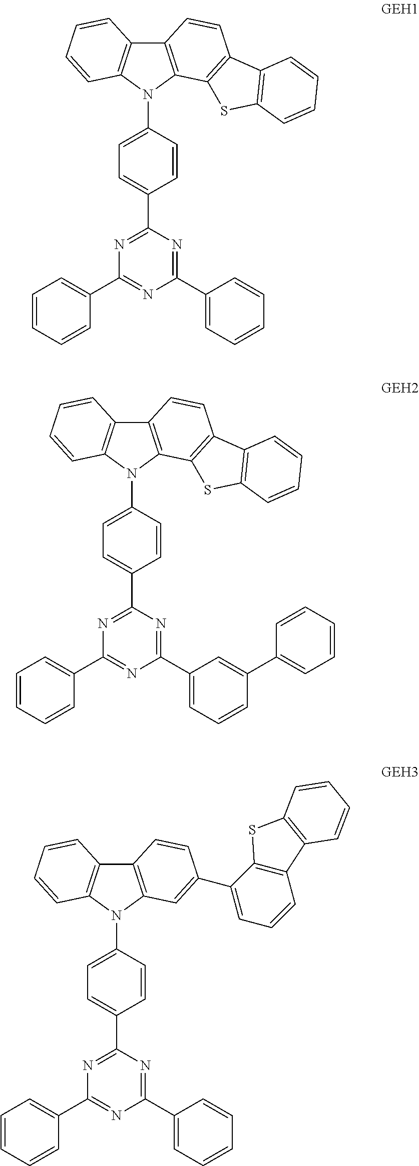 [SMILES: c1ccc(-c2nc(-c3ccccc3)nc(-c3ccc(-n4c5ccccc5c5ccc6c7ccccc7sc6c54)cc3)n2)cc1 ; c1ccc(-c2cccc(-c3nc(-c4ccccc4)nc(-c4ccc(-n5c6ccccc6c6ccc7c8ccccc8sc7c65)cc4)n3)c2)cc1 ; c1ccc(-c2nc(-c3ccccc3)nc(-c3ccc(-n4c5ccccc5c5ccc(-c6cccc7c6sc6ccccc67)cc54)cc3)n2)cc1]

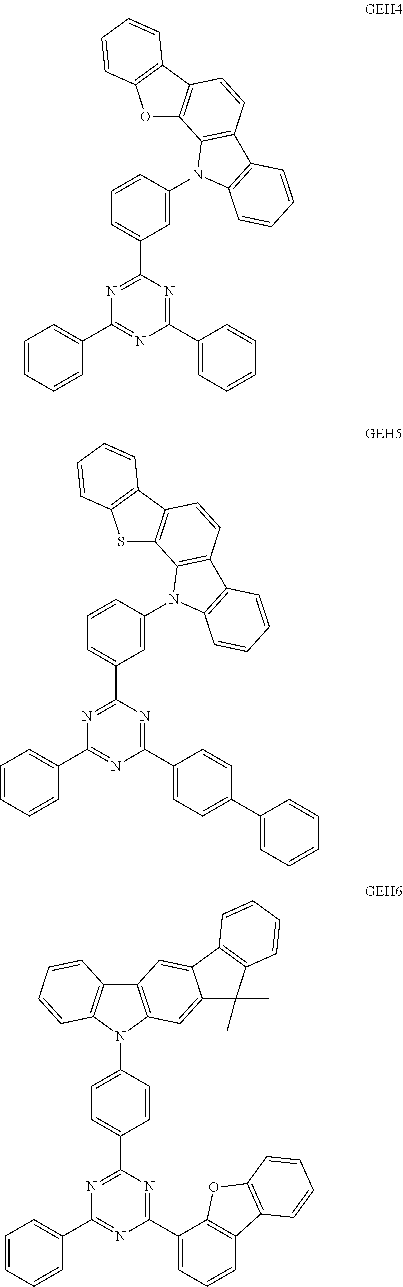 [SMILES: c1ccc(-c2nc(-c3ccccc3)nc(-c3cccc(-n4c5ccccc5c5ccc6c7ccccc7oc6c54)c3)n2)cc1 ; c1ccc(-c2ccc(-c3nc(-c4ccccc4)nc(-c4cccc(-n5c6ccccc6c6ccc7c8ccccc8sc7c65)c4)n3)cc2)cc1 ; CC1(C)c2ccccc2-c2cc3c4ccccc4n(-c4ccc(-c5nc(-c6ccccc6)nc(-c6cccc7c6oc6ccccc67)n5)cc4)c3cc21]

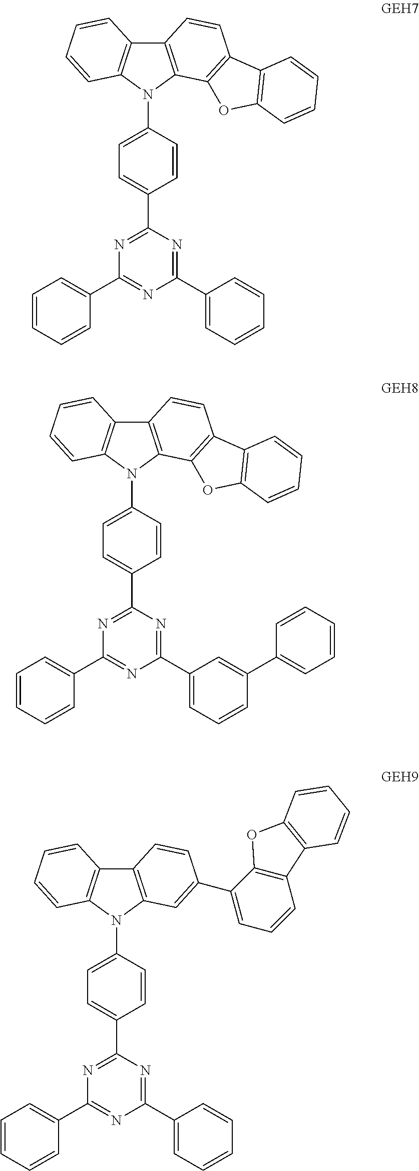 [SMILES: c1ccc(-c2nc(-c3ccccc3)nc(-c3ccc(-n4c5ccccc5c5ccc6c7ccccc7oc6c54)cc3)n2)cc1 ; c1ccc(-c2cccc(-c3nc(-c4ccccc4)nc(-c4ccc(-n5c6ccccc6c6ccc7c8ccccc8oc7c65)cc4)n3)c2)cc1 ; c1ccc(-c2nc(-c3ccccc3)nc(-c3ccc(-n4c5ccccc5c5ccc(-c6cccc7c6oc6ccccc67)cc54)cc3)n2)cc1]

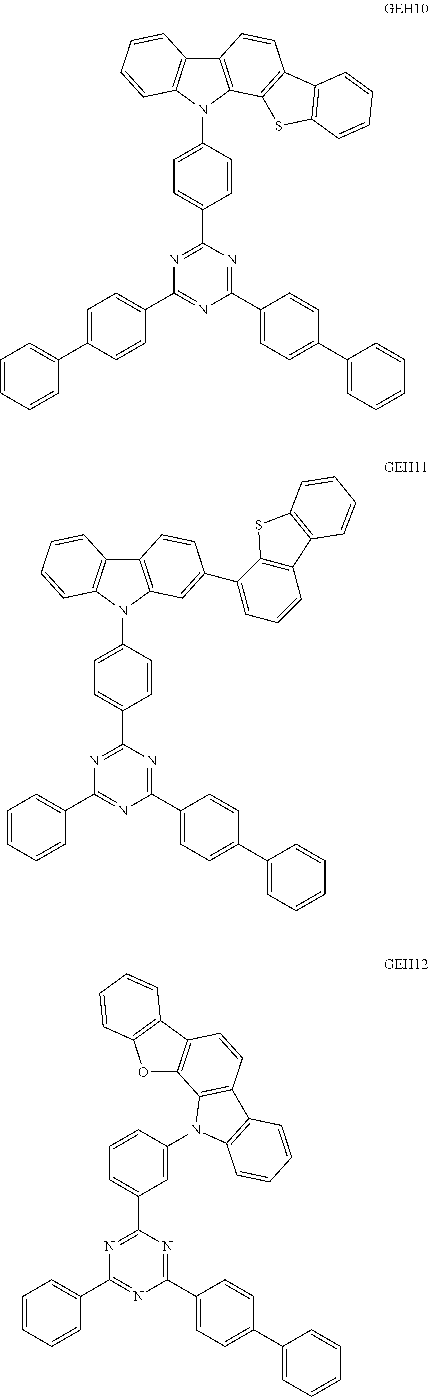 [SMILES: c1ccc(-c2ccc(-c3nc(-c4ccc(-c5ccccc5)cc4)nc(-c4ccc(-n5c6ccccc6c6ccc7c8ccccc8sc7c65)cc4)n3)cc2)cc1 ; c1ccc(-c2ccc(-c3nc(-c4ccccc4)nc(-c4ccc(-n5c6ccccc6c6ccc(-c7cccc8c7sc7ccccc78)cc65)cc4)n3)cc2)cc1 ; c1ccc(-c2ccc(-c3nc(-c4ccccc4)nc(-c4cccc(-n5c6ccccc6c6ccc7c8ccccc8oc7c65)c4)n3)cc2)cc1]

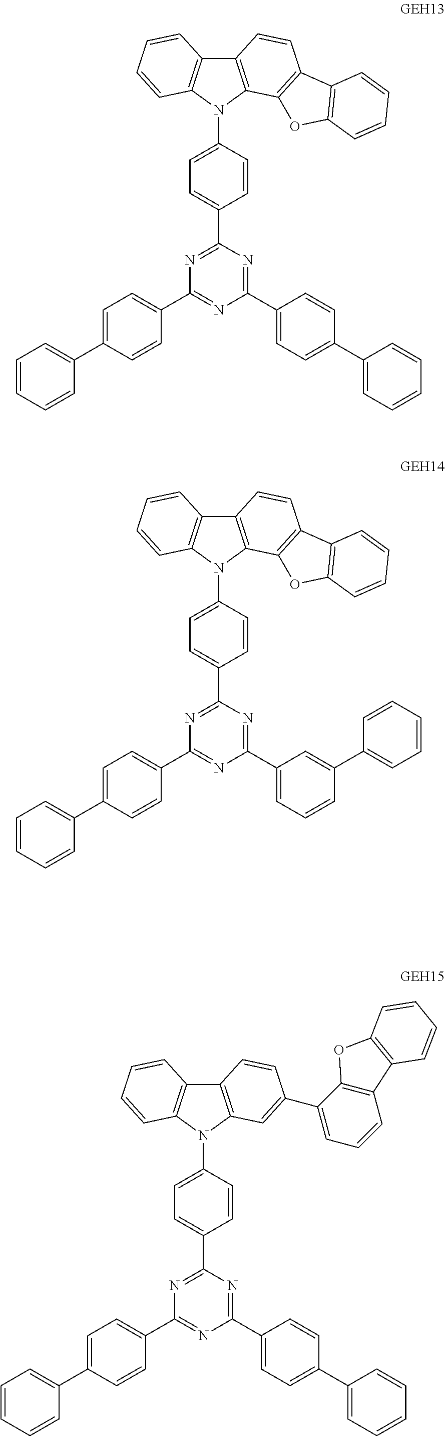 [SMILES: c1ccc(-c2ccc(-c3nc(-c4ccc(-c5ccccc5)cc4)nc(-c4ccc(-n5c6ccccc6c6ccc7c8ccccc8oc7c65)cc4)n3)cc2)cc1 ; c1ccc(-c2ccc(-c3nc(-c4ccc(-n5c6ccccc6c6ccc7c8ccccc8oc7c65)cc4)nc(-c4cccc(-c5ccccc5)c4)n3)cc2)cc1 ; c1ccc(-c2ccc(-c3nc(-c4ccc(-c5ccccc5)cc4)nc(-c4ccc(-n5c6ccccc6c6ccc(-c7cccc8c7oc7ccccc78)cc65)cc4)n3)cc2)cc1]

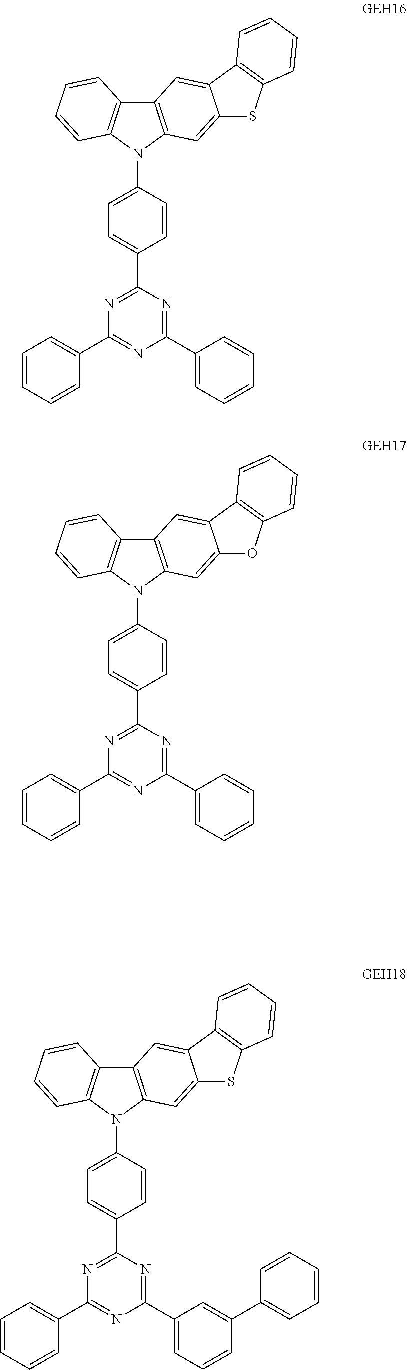 [SMILES: c1ccc(-c2nc(-c3ccccc3)nc(-c3ccc(-n4c5ccccc5c5cc6c(cc54)sc4ccccc46)cc3)n2)cc1 ; c1ccc(-c2nc(-c3ccccc3)nc(-c3ccc(-n4c5ccccc5c5cc6c(cc54)oc4ccccc46)cc3)n2)cc1 ; c1ccc(-c2cccc(-c3nc(-c4ccccc4)nc(-c4ccc(-n5c6ccccc6c6cc7c(cc65)sc5ccccc57)cc4)n3)c2)cc1]

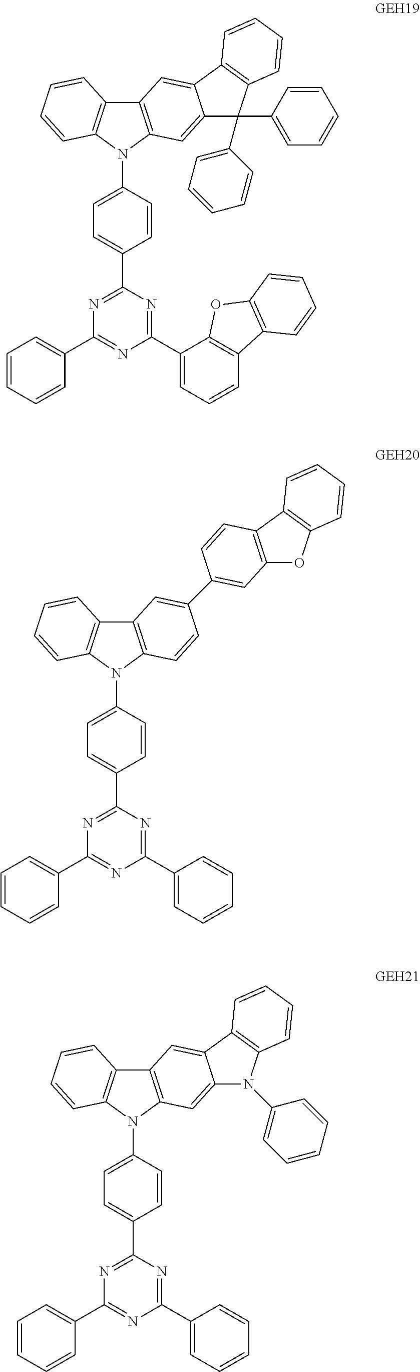 [SMILES: c1ccc(-c2nc(-c3ccc(-n4c5ccccc5c5cc6c(cc54)C(c4ccccc4)(c4ccccc4)c4ccccc4-6)cc3)nc(-c3cccc4c3oc3ccccc34)n2)cc1 ; c1ccc(-c2nc(-c3ccccc3)nc(-c3ccc(-n4c5ccccc5c5cc(-c6ccc7c(c6)oc6ccccc67)ccc54)cc3)n2)cc1 ; c1ccc(-c2nc(-c3ccccc3)nc(-c3ccc(-n4c5ccccc5c5cc6c7ccccc7n(-c7ccccc7)c6cc54)cc3)n2)cc1]

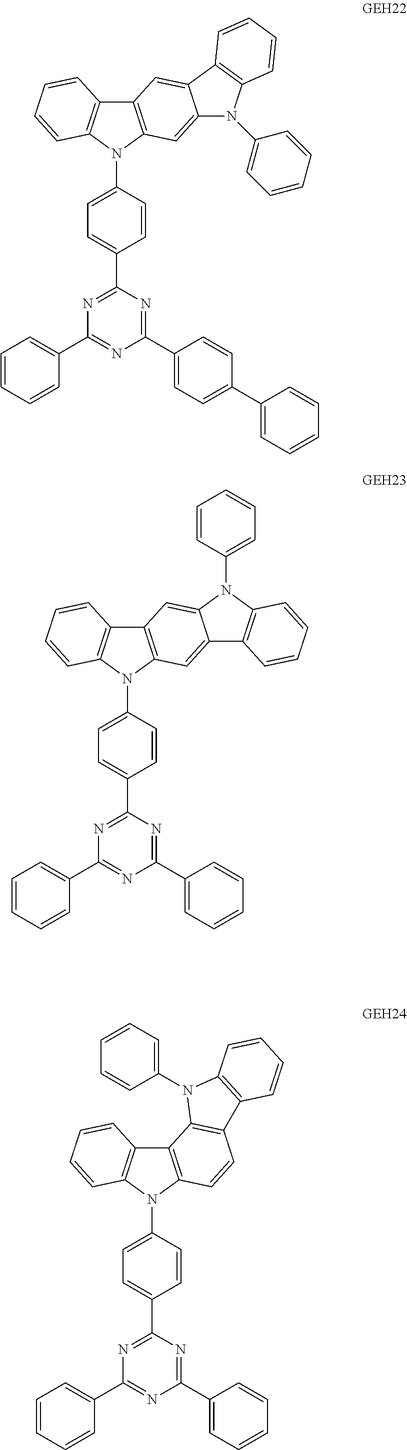 [SMILES: c1ccc(-c2ccc(-c3nc(-c4ccccc4)nc(-c4ccc(-n5c6ccccc6c6cc7c8ccccc8n(-c8ccccc8)c7cc65)cc4)n3)cc2)cc1 ; c1ccc(-c2nc(-c3ccccc3)nc(-c3ccc(-n4c5ccccc5c5cc6c(cc54)c4ccccc4n6-c4ccccc4)cc3)n2)cc1 ; c1ccc(-c2nc(-c3ccccc3)nc(-c3ccc(-n4c5ccccc5c5c4ccc4c6ccccc6n(-c6ccccc6)c45)cc3)n2)cc1]

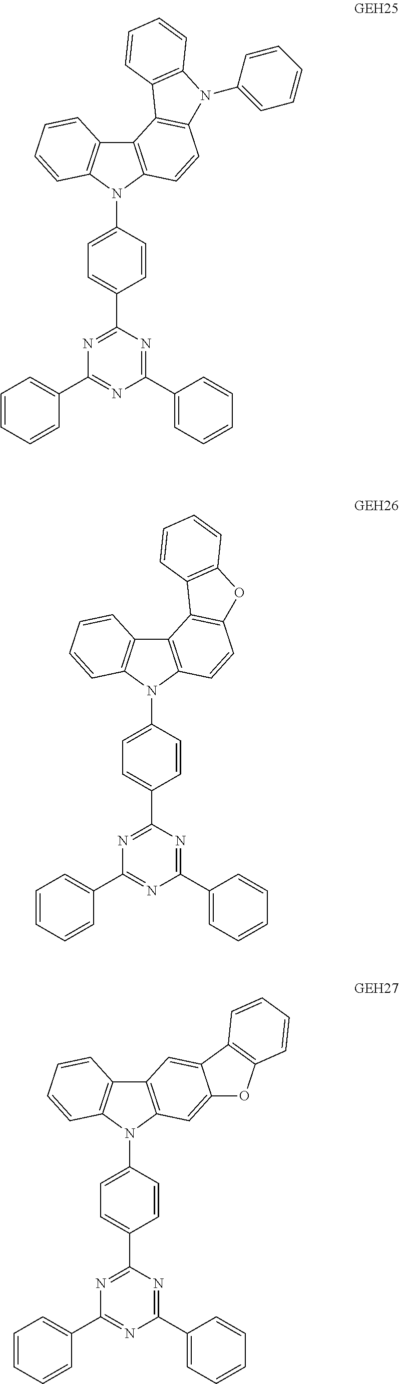 [SMILES: c1ccc(-c2nc(-c3ccccc3)nc(-c3ccc(-n4c5ccccc5c5c6c7ccccc7n(-c7ccccc7)c6ccc54)cc3)n2)cc1 ; c1ccc(-c2nc(-c3ccccc3)nc(-c3ccc(-n4c5ccccc5c5c6c(ccc54)oc4ccccc46)cc3)n2)cc1 ; c1ccc(-c2nc(-c3ccccc3)nc(-c3ccc(-n4c5ccccc5c5cc6c(cc54)oc4ccccc46)cc3)n2)cc1]

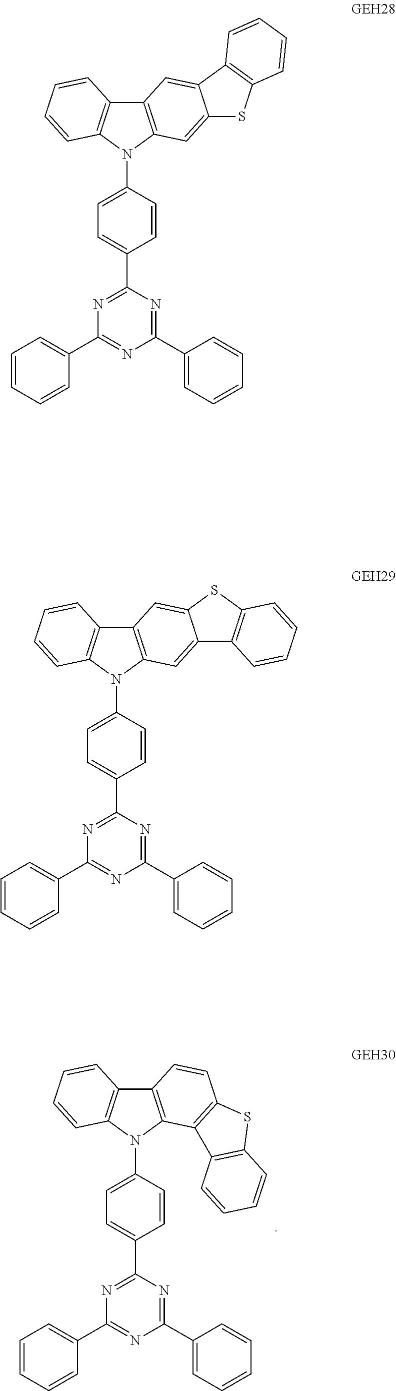 [SMILES: c1ccc(-c2nc(-c3ccccc3)nc(-c3ccc(-n4c5ccccc5c5cc6c(cc54)sc4ccccc46)cc3)n2)cc1 ; c1ccc(-c2nc(-c3ccccc3)nc(-c3ccc(-n4c5ccccc5c5cc6sc7ccccc7c6cc54)cc3)n2)cc1 ; c1ccc(-c2nc(-c3ccccc3)nc(-c3ccc(-n4c5ccccc5c5ccc6sc7ccccc7c6c54)cc3)n2)cc1]

17. The organic light emitting diode of claim 13, further comprising a charge generation layer,
wherein a plurality of light emitting parts are present between the first electrode and the second electrode,
wherein the charge generation layer is disposed between the plurality of light emitting parts.

18. An organic light emitting diode display device, comprising:
a substrate;
a driving element positioned on the substrate; and
the organic light emitting diode according to claim 1, which is positioned on the substrate and connected to the driving element.

19. An organic light emitting diode, comprising:
a first electrode;
a second electrode facing the first electrode; and
an intermediate layer disposed between the first electrode and the second electrode, the intermediate layer including an emission layer including:
a dopant material including an organometallic compound represented by Chemical Formula 1, and
a host material including a mixture including a compound represented by Chemical Formula 2 and a compound represented by Chemical Formula 3: 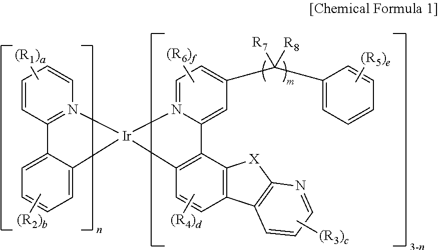
wherein in Chemical Formula 1,
X is one selected from oxygen (O),
each R₁ to R₆ is independently one selected from alkyl and aryl, where alkyl and aryl are optionally partially deuterated or optionally entirely deuterated,
each R₇ and R₈ is independently one selected from hydrogen, deuterium, and a C1-C6 linear alkyl group, where the C1-C6 linear alkyl group is optionally partially deuterated or optionally entirely deuterated,
a and b are, each independently, an integer from 0 to 4, and when a and b are each independently an integer from 2 to 4, a plurality of R₁ or a plurality of R₂ are the same or different from each other,
c and f are, each independently, an integer from 0 to 3, and when c and f are each independently an integer of 2 or 3, a plurality of R₃ or a plurality of R₆ are the same or different from each other,
d is an integer from 0 to 2, and when d is an integer of 2, a plurality of R₄ are the same or different from each other,
e is an integer from 0 to 5, and when e is an integer from 2 to 5, a plurality of R₅ are the same or different from each other, and
m is an integer selected from 1 to 8, and n is an integer selected from 0 to 2, 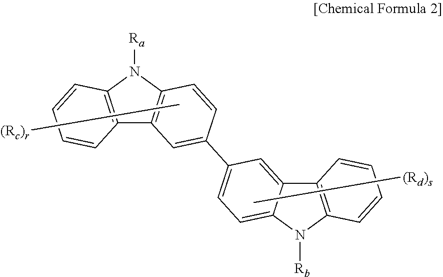
in Chemical Formula 2,
Rₐ and R_{b} are each independently one selected from an aryl group that is optionally substituted with one or more substituents selected from an alkyl group, an aryl group, a nitrile group, an alkylsilyl group, and an arylsilyl group, and Rₐ and R_{b} are optionally partially deuterated or optionally entirely deuterated,
each R_{c} and Rₐ is hydrogen or deuterium, and
r and s are each an integer of 7, 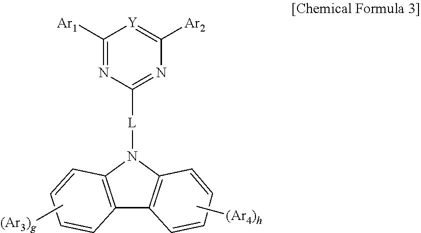
in Chemical Formula 3,
L is a C6-C50 arylene group, 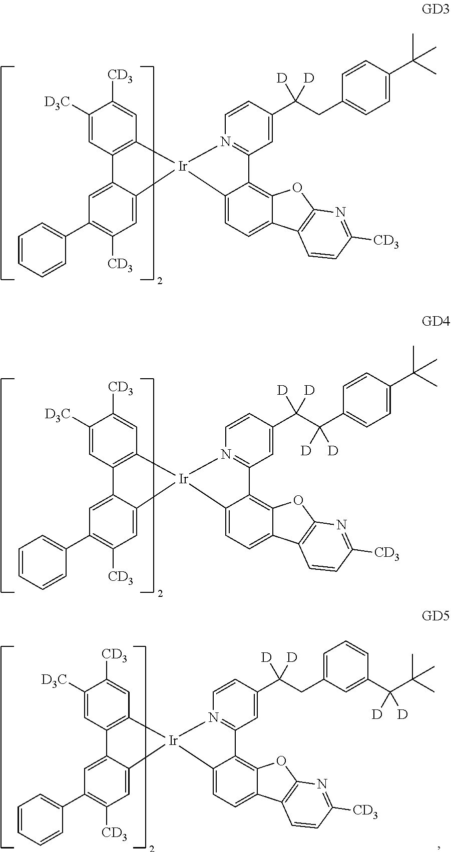
wherein the compound represented by Chemical Formula 2 includes one of Compounds GHH1 to GHH10: 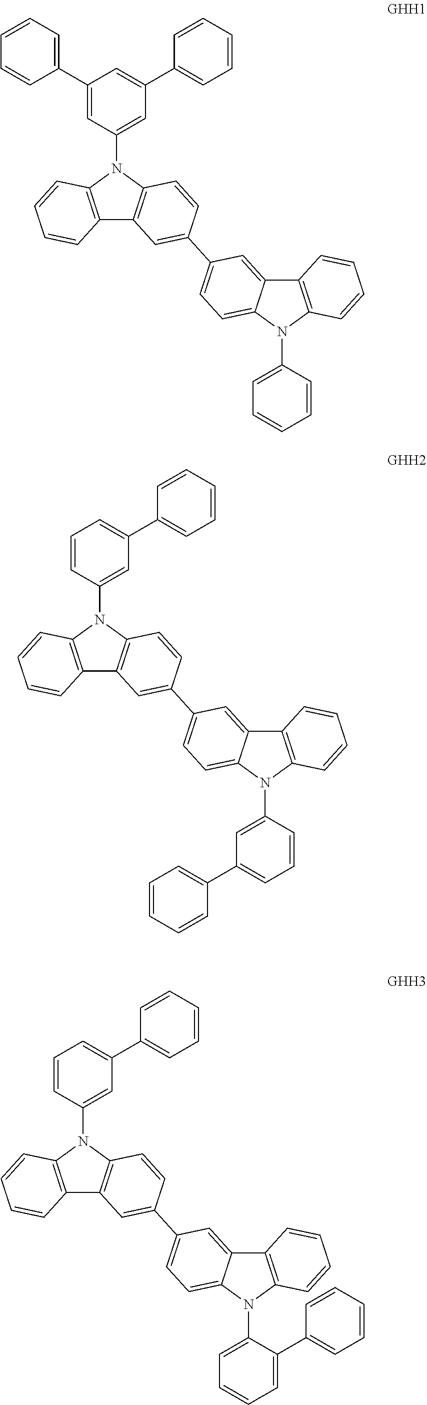 [SMILES: c1ccc(-c2cc(-c3ccccc3)cc(-n3c4ccccc4c4cc(-c5ccc6c(c5)c5ccccc5n6-c5ccccc5)ccc43)c2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2cccc(-n3c4ccccc4c4cc(-c5ccc6c(c5)c5ccccc5n6-c5ccccc5-c5ccccc5)ccc43)c2)cc1]
Y is N,
each Ar₁, Ar₂, Ar₃, and Ar₄ is independently one selected from hydrogen, a C6-C50 aryl group, and a C3-C50 heteroaryl group,
g and h are each independently an integer selected from 1 to 4,
when g is an integer selected from 2 to 4, any two adjacent Ar₃ are optionally bonded to form a fused ring structure including a C6-C30 monocyclic or polycyclic aromatic group, or a C3-C30 heteroaromatic group, and one or more of hydrogens attached to the fused ring structure are optionally substituted by a C1-C10 alkyl group, and
when h is an integer selected from 2 to 4, any two adjacent Ar₄ are optionally bonded to form a fused ring structure including a C6-C30 monocyclic or polycyclic aromatic group, or a C3-C30 heteroaromatic group, and one or more of hydrogens attached to the fused ring structure are optionally substituted by a substituent selected from deuterium, a C1-C10 alkyl group, a C6-C20 aryl group, and a C3-C20 heteroaryl group.

20. The organic light emitting diode of claim 19, wherein the organometallic compound represented by Chemical Formula 1 includes one of Compounds GD1 to GD5: 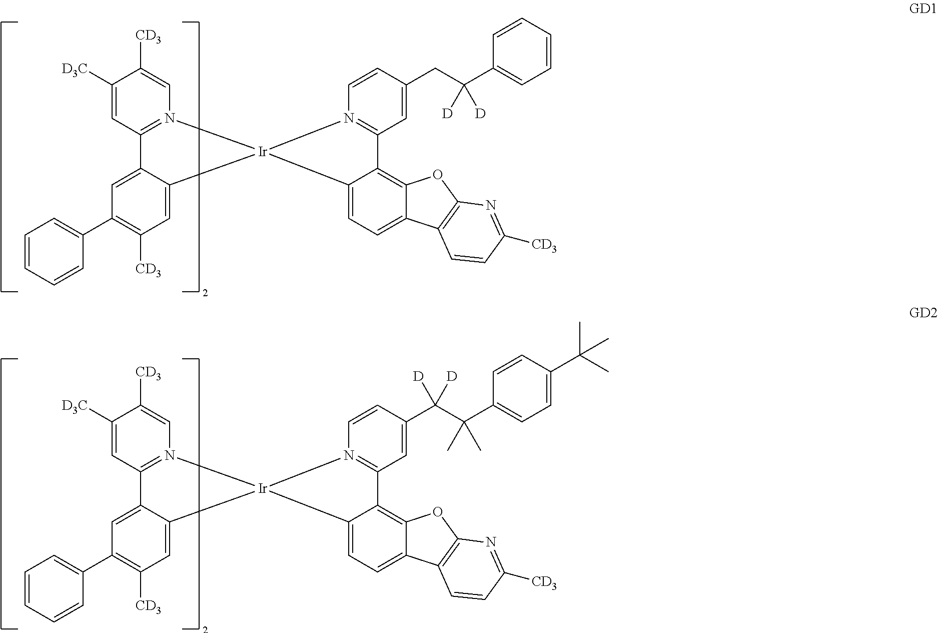 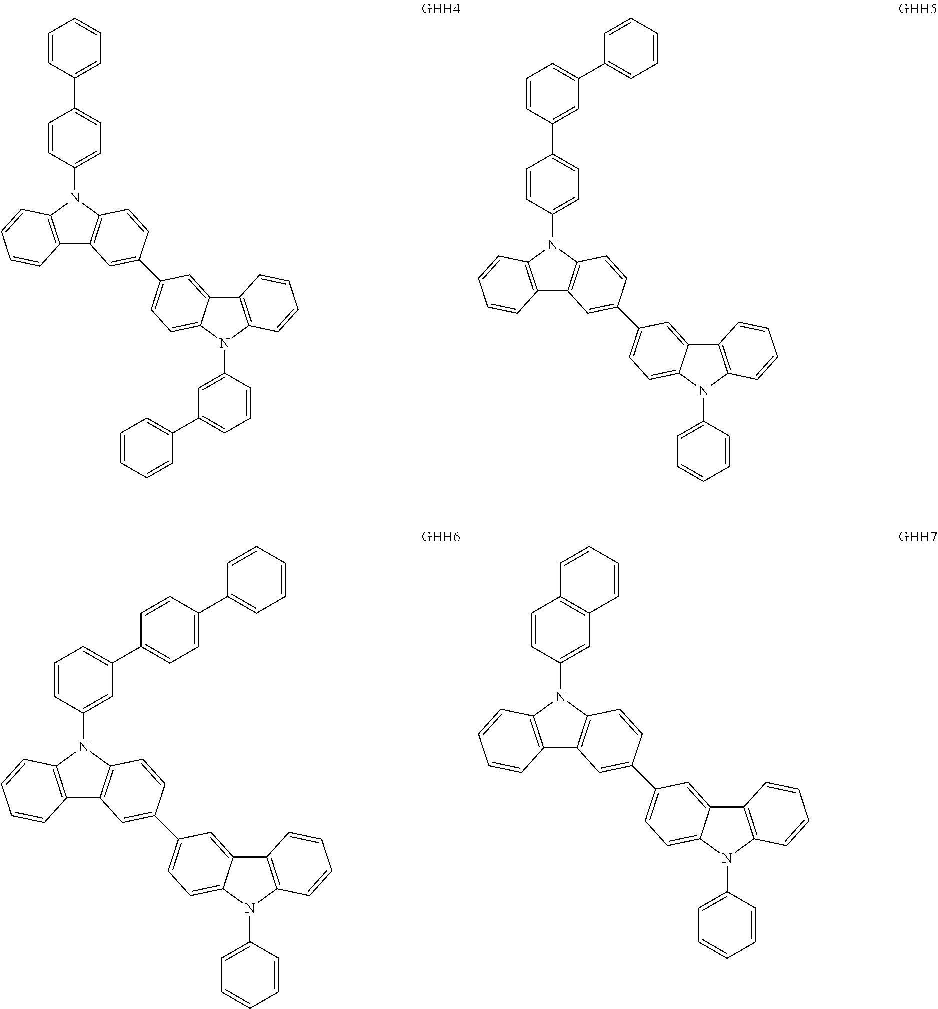 [SMILES: c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2cccc(-c3ccc(-n4c5ccccc5c5cc(-c6ccc7c(c6)c6ccccc6n7-c6ccccc6)ccc54)cc3)c2)cc1 ; c1ccc(-c2ccc(-c3cccc(-n4c5ccccc5c5cc(-c6ccc7c(c6)c6ccccc6n7-c6ccccc6)ccc54)c3)cc2)cc1 ; c1ccc(-n2c3ccccc3c3cc(-c4ccc5c(c4)c4ccccc4n5-c4ccc5ccccc5c4)ccc32)cc1] 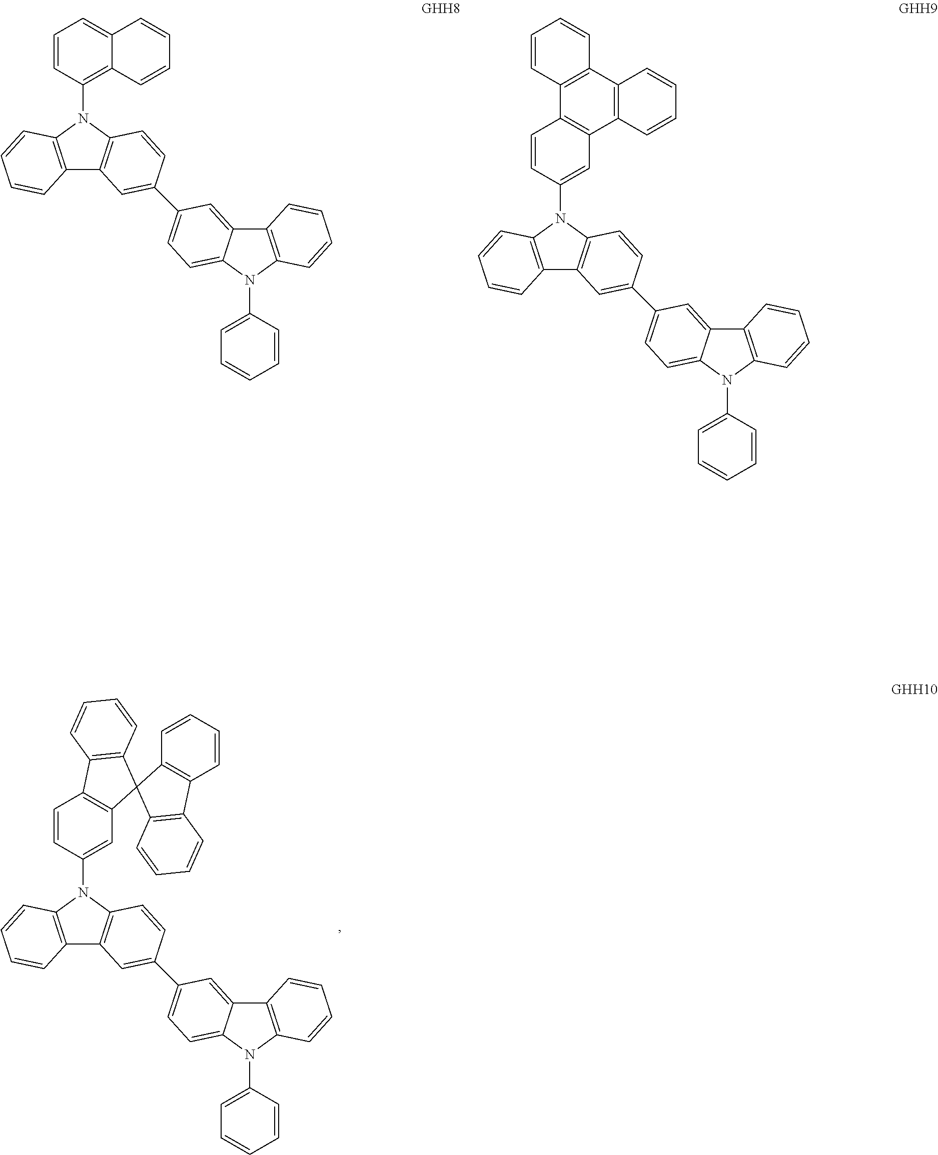 [SMILES: c1ccc(-n2c3ccccc3c3cc(-c4ccc5c(c4)c4ccccc4n5-c4cccc5ccccc45)ccc32)cc1 ; c1ccc(-n2c3ccccc3c3cc(-c4ccc5c(c4)c4ccccc4n5-c4ccc5c6ccccc6c6ccccc6c5c4)ccc32)cc1 ; c1ccc(-n2c3ccccc3c3cc(-c4ccc5c(c4)c4ccccc4n5-c4ccc5c(c4)C4(c6ccccc6-c6ccccc64)c4ccccc4-5)ccc32)cc1]
wherein the compound represented by Chemical Formula 3 includes one of Compounds GEH1 to GEH10: 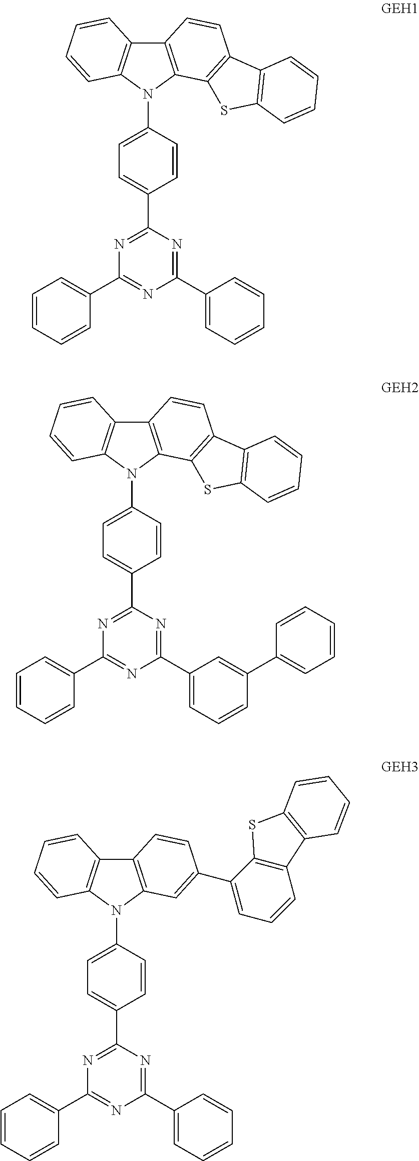 [SMILES: c1ccc(-c2nc(-c3ccccc3)nc(-c3ccc(-n4c5ccccc5c5ccc6c7ccccc7sc6c54)cc3)n2)cc1 ; c1ccc(-c2cccc(-c3nc(-c4ccccc4)nc(-c4ccc(-n5c6ccccc6c6ccc7c8ccccc8sc7c65)cc4)n3)c2)cc1 ; c1ccc(-c2nc(-c3ccccc3)nc(-c3ccc(-n4c5ccccc5c5ccc(-c6cccc7c6sc6ccccc67)cc54)cc3)n2)cc1] 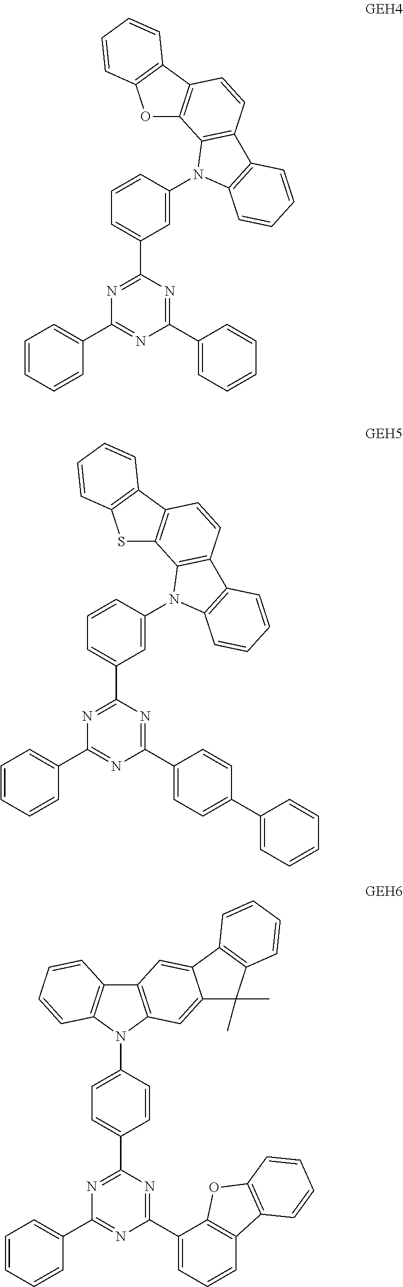 [SMILES: c1ccc(-c2nc(-c3ccccc3)nc(-c3cccc(-n4c5ccccc5c5ccc6c7ccccc7oc6c54)c3)n2)cc1 ; c1ccc(-c2ccc(-c3nc(-c4ccccc4)nc(-c4cccc(-n5c6ccccc6c6ccc7c8ccccc8sc7c65)c4)n3)cc2)cc1 ; CC1(C)c2ccccc2-c2cc3c4ccccc4n(-c4ccc(-c5nc(-c6ccccc6)nc(-c6cccc7c6oc6ccccc67)n5)cc4)c3cc21] 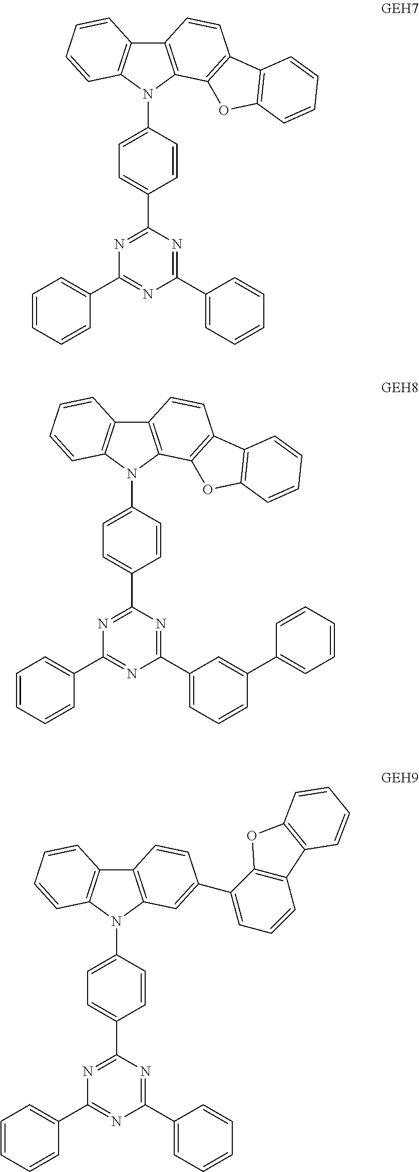 [SMILES: c1ccc(-c2nc(-c3ccccc3)nc(-c3ccc(-n4c5ccccc5c5ccc6c7ccccc7oc6c54)cc3)n2)cc1 ; c1ccc(-c2cccc(-c3nc(-c4ccccc4)nc(-c4ccc(-n5c6ccccc6c6ccc7c8ccccc8oc7c65)cc4)n3)c2)cc1 ; c1ccc(-c2nc(-c3ccccc3)nc(-c3ccc(-n4c5ccccc5c5ccc(-c6cccc7c6oc6ccccc67)cc54)cc3)n2)cc1] 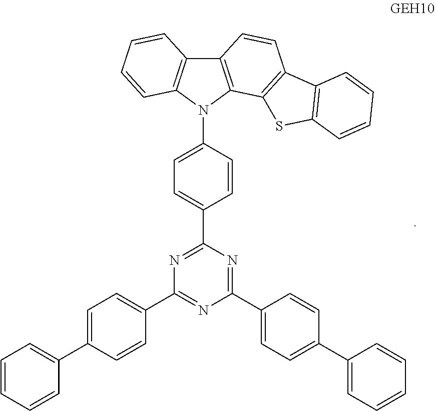 [SMILES: c1ccc(-c2ccc(-c3nc(-c4ccc(-c5ccccc5)cc4)nc(-c4ccc(-n5c6ccccc6c6ccc7c8ccccc8sc7c65)cc4)n3)cc2)cc1]
